(19) United States
(12) Patent Application Publication
(10) Pub. No.: US 2024/0341164 A1
(43) Pub. Date: Oct. 10, 2024

(54) ORGANIC LIGHT-EMITTING DEVICE

(71) Applicant: CANON KABUSHIKI KAISHA, Tokyo (JP)

(72) Inventors: YOSUKE NISHIDE, Kanagawa (JP); JUN KAMATANI, Tokyo (JP); NAOKI YAMADA, Tokyo (JP); HIROKI OHRUI, Tokyo (JP); HIRONOBU IWAWAKI, Kanagawa (JP); HIROKAZU MIYASHITA, Miyagi (JP)

(21) Appl. No.: 18/657,200

(22) Filed: May 7, 2024

Related U.S. Application Data
(63) Continuation of application No. PCT/JP2022/039315, filed on Oct. 21, 2022.

(30) Foreign Application Priority Data
Nov. 9, 2021 (JP) 2021-182574

(51) Int. Cl. H10K 85/30; H10K 85/60

(52) U.S. Cl. CPC H10K 85/342; H10K 85/6574

(57) ABSTRACT

The present disclosure provides an organic light-emitting device including a pair of electrodes, and a light-emitting layer in which the light-emitting layer contains a guest molecule and a host molecule represented by the following general formula [1], and the guest molecule is an organometallic complex represented by the following general formula [2]:

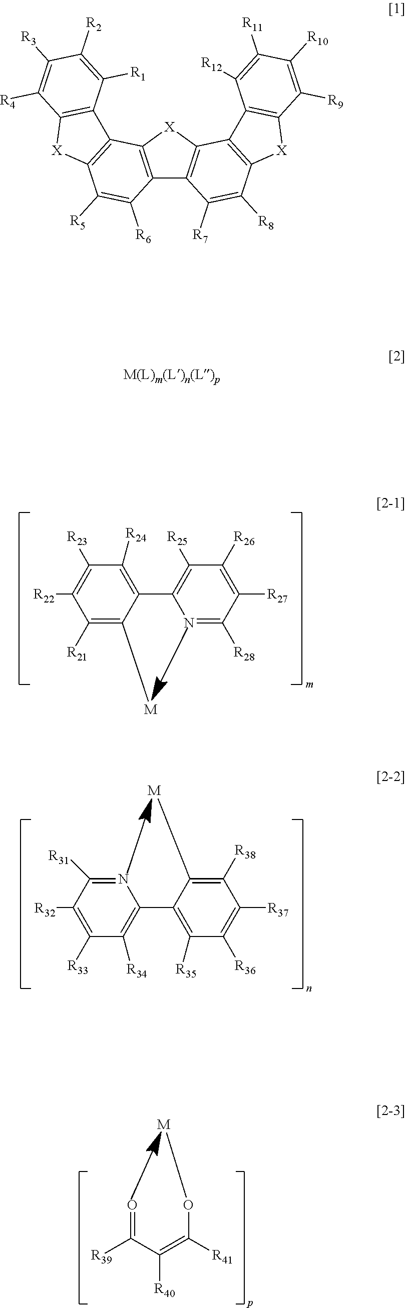

where in formula [1], R₁ to R₁₂ are each a hydrogen atom or a substituent, at least one of them is a substituent, each X is selected from an oxygen atom and so forth L, L′, and L″ are each a different bidentate ligand, each of m, n and p is an integer, m+n+p=3, and a partial structure ML is selected from the foregoing general formulae [2-1] to [2-3], where in the formulae, R₂₁ to R₄₁ are each a hydrogen atom or a substituent.

### CROSS-REFERENCE TO RELATED APPLICATIONS

This application is a Continuation of International Patent Application No. PCT/JP2022/039315, filed Oct. 21, 2022, which claims the benefit of Japanese Patent Application No. 2021-182574, filed Nov. 9, 2021, both of which are hereby incorporated by reference herein in their entirety.

### TECHNICAL FIELD

The present invention relates to an organic light-emitting device.

### BACKGROUND ART

An organic light-emitting device (hereinafter, also referred to as an “organic electroluminescent device” or “organic EL device”) is an electronic device including a pair of electrodes and an organic compound layer disposed between these electrodes. The injection of electrons and holes from these pairs of electrodes generates excitons of the light-emitting organic compound in the organic compound layer, and when the excitons return to the ground state, the organic light-emitting device emits light. Recently, organic light-emitting devices have made remarkable progress and have achieved low-driving voltage, various emission wavelengths, and fast response time. The use thereof has enabled the development of thinner and lighter light-emitting apparatuses.

To date, the creation of compounds suitable for organic light-emitting devices has been actively pursued. This is because the creation of a compound with excellent device life characteristics is important in providing a high-performance organic light-emitting device. As a compound that has been created so far, fused polycyclic compound 1-a containing chalcogenophene is described in Patent Literature 1.

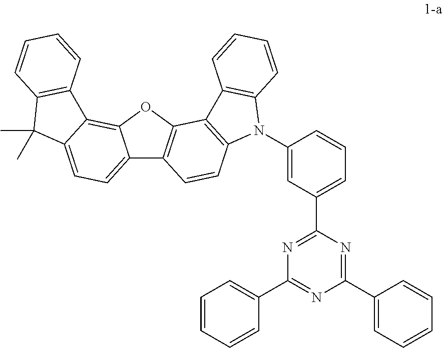 [SMILES: CC1(C)c2ccccc2-c2c1ccc1c2oc2c1ccc1c2c2ccccc2n1-c1cccc(-c2nc(-c3ccccc3)nc(-c3ccccc3)n2)c1]

### CITATION LIST

### Patent Literature

PTL 1 U.S. Patent Application Publication No. 2015/0034914

Patent Literature 1 discloses an example of a green light-emitting device using compound 1-a, but further improvements in luminous efficiency and durability characteristics are desired.

### SUMMARY OF INVENTION

The present invention has been made in view of the above problems, and an object of the present invention is to provide an organic light-emitting device having excellent luminous efficiency and durability characteristics.

An organic light-emitting device of the present invention includes a pair of electrodes, and a light-emitting layer disposed between the pair of electrodes, in which the light-emitting layer contains at least a guest molecule and a host molecule, the host molecule is an organic compound represented by the following general formula [1], and the guest molecule is an organometallic complex represented by the following general formula [2].

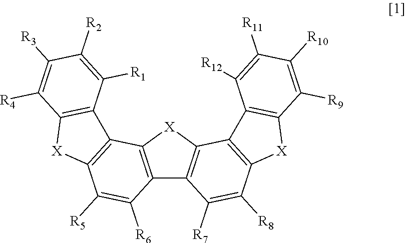

M(L)m(L′)n(L″)p [2]

In formula [1], R₁ to R₁₂ are each independently selected from a hydrogen atom, a deuterium atom, a substituted or unsubstituted aryl group, and a substituted or unsubstituted heterocyclic group, provided that at least one of R₁ to R₁₂ is selected from a substituted or unsubstituted aryl group and a substituted or unsubstituted heterocyclic group.

Each X is selected from an oxygen atom, a sulfur atom, a selenium atom, and a tellurium atom.

In formula [2], M is selected from iridium and platinum.

L, L′, and L″ are each a different bidentate ligand.

m is selected from integers of 1 or more and 3 or less, and n and p are each selected from integers of 0 or more and 2 or less, provided that m+n+p=3.

A partial structure M(L)m is represented by the following general formula [2-1].

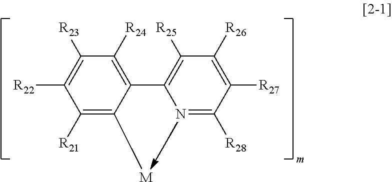

In formula [2-1], R₂₁ to R₂₈ are each independently selected from a hydrogen atom, a deuterium atom, a halogen atom, a substituted or unsubstituted alkyl group, a substituted or unsubstituted alkoxy group, a substituted or unsubstituted silyl group, a substituted or unsubstituted aryl group, a substituted or unsubstituted heterocyclic group, a substituted or unsubstituted amino group, a substituted or unsubstituted aryloxy group, a substituted or unsubstituted heteroaryloxy group, and a cyano group, provided that at least one of R₂₁ to R₂₈ is selected from a substituted or unsubstituted aryl group and a substituted or unsubstituted heterocyclic group. Adjacent groups of R₂₁ to R₂₈ may be taken together to form a ring.

A partial structure M(L′)n is represented by the following general formula [2-2].

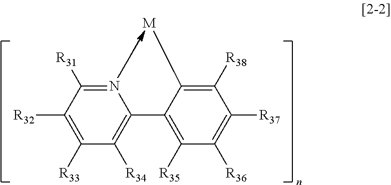

In formula [2-2], R₃₁ to R₃₈ are each independently selected from a hydrogen atom, a deuterium atom, a halogen atom, a substituted or unsubstituted alkyl group, a substituted or unsubstituted alkoxy group, a substituted or unsubstituted silyl group, a substituted or unsubstituted aryl group, a substituted or unsubstituted heterocyclic group, a substituted or unsubstituted amino group, a substituted or unsubstituted aryloxy group, a substituted or unsubstituted heteroaryloxy group, and a cyano group. Adjacent groups of R₃₁ to R₃₈ may be taken together to form a ring.

A partial structure M(L″)p is represented by the following general formula [2-3].

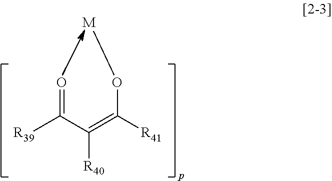

In formula [2-3], R₃₉ to R₄₁ are each independently selected from a hydrogen atom, a deuterium atom, a halogen atom, a substituted or unsubstituted alkyl group, a substituted or unsubstituted alkoxy group, a substituted or unsubstituted silyl group, a substituted or unsubstituted aryl group, a substituted or unsubstituted heterocyclic group, a substituted or unsubstituted amino group, a substituted or unsubstituted aryloxy group, a substituted or unsubstituted heteroaryloxy group, and a cyano group.

Further features of the present invention will become apparent from the following description of exemplary embodiments with reference to the attached drawings.

### BRIEF DESCRIPTION OF DRAWINGS

FIG. 1 illustrates the effects of host molecules and guest molecules.

FIG. 2A is a schematic cross-sectional view of an example of a pixel of a display apparatus according to an embodiment of the present invention.

FIG. 2B is a schematic cross-sectional view of an example of a display apparatus including organic light-emitting devices according to an embodiment of the present invention.

FIG. 3 is a schematic view of an example of a display apparatus according to an embodiment of the present invention.

FIG. 4A is a schematic view of an example of an image pickup apparatus according to an embodiment of the present invention.

FIG. 4B is a schematic view of an example of an electronic apparatus according to an embodiment of the present invention.

FIG. 5A is a schematic view of an example of a display apparatus according to an embodiment of the present invention.

FIG. 5B is a schematic view of an example of a foldable display apparatus.

FIG. 6A is a schematic view of an example of a lighting apparatus according to an embodiment of the present invention.

FIG. 6B is a schematic view of an example of a moving object including an automotive lighting unit according to an embodiment of the present invention.

FIG. 7A is a schematic view of an example of a wearable device according to an embodiment of the present invention.

FIG. 7B is a schematic view of another example of a wearable device according to an embodiment of the present invention.

FIG. 8A is a schematic view of an example of an image-forming apparatus according to an embodiment of the present invention.

FIG. 8B is a schematic view of an example of an exposure light source of an image-forming apparatus according to an embodiment of the present invention.

FIG. 8C is a schematic view of an example of an exposure light source of an image-forming apparatus according to an embodiment of the present invention.

### DESCRIPTION OF EMBODIMENTS

### (1) Organic Light-Emitting Device

An organic light-emitting device of the present embodiment includes a pair of electrodes, and a light-emitting layer disposed between the pair of electrodes, the light-emitting layer containing at least a guest molecule and a host molecule. The host molecule is an organic compound represented by general formula [1], and the guest molecule is an organometallic complex represented by general formula [2].

The specific device configuration of the organic light-emitting device of the present embodiment includes multilayer device configurations described in (1) to (6) below, in which electrode layers and an organic compound layers are sequentially stacked on a substrate. In any device configuration, the organic compound layer always includes a light-emitting layer containing a light-emitting material.
(1) Anode/light-emitting layer/cathode
(2) Anode/hole transport layer/light-emitting layer/electron transport layer/cathode
(3) Anode/hole transport layer/light-emitting layer/electron transport layer/electron injection layer/cathode
(4) Anode/hole injection layer/hole transport layer/light-emitting layer/electron transport layer/cathode
(5) Anode/hole injection layer/hole transport layer/light-emitting layer/electron transport layer/electron injection layer/cathode
(6) Anode/hole transport layer/electron-blocking layer/light-emitting layer/hole-blocking layer/electron transport layer/cathode

However, these device configuration examples are only very basic device configurations, and the device configuration is not limited thereto. Various layer configurations can be used, and examples thereof include an insulating layer, an adhesive layer, or an interference layer provided at the interface between an electrode and an organic compound layer; an electron transport layer or a hole transport layer formed of two layers having different ionization potentials; and a light-emitting layer formed of two layers having different light-emitting materials.

The light-emitting layer may be formed of a single layer or multiple layers. The term “multiple layers” refers to a state in which a light-emitting layer and another light-emitting layer are stacked. For example, a light-emitting layer containing an organic compound represented by general formula [1] as a host molecule and an organometallic complex represented by general formula [2] as a guest molecule, and another light-emitting layer that emits light of a color different from the color of light emitted from the light-emitting layer may be stacked. In this case, the emission color may be white or an intermediate color.

In the device configurations described in (1) to (6) above, the configuration of (6) is a configuration having both an electron-blocking layer and a hole-blocking layer and thus is preferred. In other words, in (6) including the electron-blocking layer and the hole-blocking layer, both hole and electron carriers can be reliably confined in the light-emitting layer, so that the organic light-emitting device has no carrier leakage and high luminous efficiency.

A mode of extracting light output from a light-emitting layer (device configuration) may be what is called a bottom emission mode in which light is extracted from an electrode on the substrate side, or what is called a top emission mode in which light is extracted from the side opposite to the substrate. In addition, a double-sided extraction mode in which light is extracted from the substrate side and the side opposite to the substrate can also be used.

In the organic light-emitting device of the present embodiment, the organic compound having a fused-ring chalcogenophene skeleton represented by general formula [1] is preferably contained in the light-emitting layer among the organic compound layers. In this case, the light-emitting layer contains at least the organometallic complex represented by general formula [2]. Compounds contained in the light-emitting layer are used for different applications depending on their concentrations in the light-emitting layer. Specifically, the compounds are divided into a main component and an auxiliary component according to their concentrations contained in the light-emitting layer.

A compound serving as a main component is a compound having the highest proportion (concentration) by mass in a group of compounds contained in the light-emitting layer, and is also referred to as a host. The host is a compound that is present as a matrix around the light-emitting material in the light-emitting layer and that mainly responsible for transporting carriers to the light-emitting material and providing excitation energy to the light-emitting material.

A compound serving as an auxiliary component is a compound other than the main component and can be referred to as a guest (dopant), a light-emission assist material, or a charge injection material in accordance with the function of the compound. The guest, which is a type of auxiliary component, is a compound (light-emitting material) responsible for main light emission in the light-emitting layer. The light-emission assist material, which is a type of auxiliary component, is a compound that assists light emission of the guest and that has a lower proportion (concentration) by mass than the host in the light-emitting layer. The light-emission assist material is also referred to as a second host because of its function.

The concentration of the guest is 0.01% or more by mass and less than 50% by mass, preferably 0.1% or more by mass and 20% or less by mass, based on the total amount of constituent materials of the light-emitting layer. From the viewpoint of reducing concentration quenching, the concentration of the guest is particularly preferably 10% or less by mass.

The guest may be uniformly contained in the entire layer in which the host serves as a matrix, or may be contained with a concentration gradient. The guest may be partially contained in a specific region in the layer, in other words, the light-emitting layer may have a region containing only the host without containing the guest.

In the present embodiment, an aspect is preferable in which an organic compound having a fused-ring chalcogenophene skeleton represented by general formula [1] serving as a host and an organometallic complex represented by general formula [2] serving as a guest are both contained in a light-emitting layer. The light-emitting layer may further contain a third component. For example, for the purpose of assisting the transport of excitons and carriers, another phosphorescent material may be further contained in the light-emitting layer in addition to the organometallic complex represented by general formula [2]. For the purpose of assisting the transport of excitons and carriers, a compound other than the organic compound represented by general formula [1] may be further contained as a second host in the light-emitting layer.

### (2) Host Molecule

An organic compound used as a host of the light-emitting layer will be described. The host molecule contained in the organic light-emitting device of the present embodiment is an organic compound that is represented by the following general formula [1] and that has a fused-ring chalcogenophene skeleton. The basic skeleton (skeleton in which R₁ to R₁₂ are hydrogen atoms) does not have an SP³ carbon atom and does not have an amino group (each X does not contain a nitrogen atom), and therefore has a high degree of planarity.

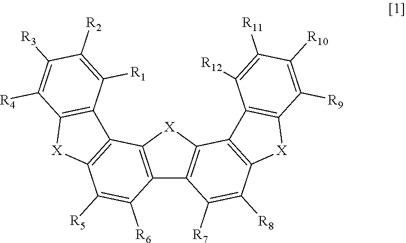

R₁ to R₁₂

In formula [1], R₁ to R₁₂ are each independently selected from a hydrogen atom, a deuterium atom, a substituted or unsubstituted aryl group, and a substituted or unsubstituted heterocyclic group, provided that at least one of R₁ to R₁₂ is selected from a substituted or unsubstituted aryl group and a substituted or unsubstituted heterocyclic group. One or two, preferably one, of R₁ to R₁₂ is preferably selected from a substituted or unsubstituted aryl group and a substituted or unsubstituted heterocyclic group.

Examples of the aryl group include, but are not limited to, a phenyl group, a naphthyl group, an indenyl group, a biphenyl group, a terphenyl group, a fluorenyl group, a phenanthryl group, a fluoranthenyl group, and a triphenylenyl group. Among these, a phenyl group is preferred.

Examples of the heterocyclic group include, but are not limited to, a pyridyl group, a pyrimidinyl group, a pyrazinyl group, a triazinyl group, a triazolyl group, an oxazolyl group, an oxadiazolyl group, a thiazolyl group, a thiadiazolyl group, a carbazolyl group, an acridinyl group, a phenanthrolinyl group, a dibenzofuranyl group, and a dibenzothiophenyl group. Among these, a triazinyl group is preferred.

Examples of substituents that may be further contained in the aryl group and the heterocyclic group include, but are not limited to, a deuterium atom; aryl groups, such as a phenyl group, a naphthyl group, an indenyl group, a biphenyl group, a terphenyl group, a fluorenyl group, a phenanthryl group, a fluoranthenyl group, and a triphenylenyl group; and heterocyclic groups, such as a pyridyl group, a pyrimidinyl group, a pyrazinyl group, a triazinyl group, a triazolyl group, an oxazolyl group, an oxadiazolyl group, a thiazolyl group, a thiadiazolyl group, a carbazolyl group, an acridinyl group, a phenanthrolinyl group, a dibenzofuranyl group, and dibenzothiophenyl group.
X

Each X is selected from an oxygen atom, a sulfur atom, a selenium atom, and a tellurium atom. X may be the same or different from each other.

The host molecule is preferably an organic compound represented by the following general formula [3].

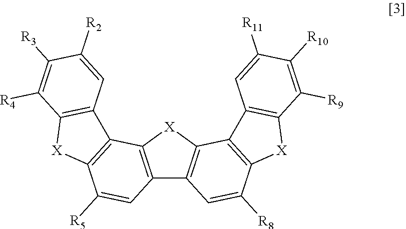

As described above, the host molecule is characterized by having a highly planar basic skeleton. Preferably, the molecule as a whole also has a high degree of planarity. The dihedral angle when any one of R₁ to R₁₂ was a phenyl group was calculated. Table 1 presents the results. The dihedral angle was calculated by molecular orbital calculation using MM2 of Chem3D.

TABLE 1

| Substitution position | Molecular structure | Dihedral angle |
|---|---|---|
| R2, R11 | 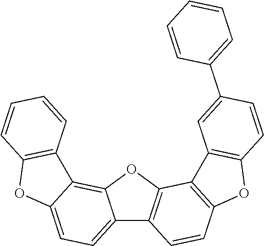 | 0° |
| R3, R10 | 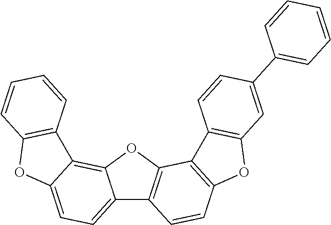 | 0° |
| R4, R9 | 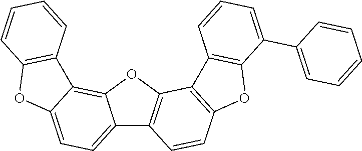 | 14° |
| R5, R8 | 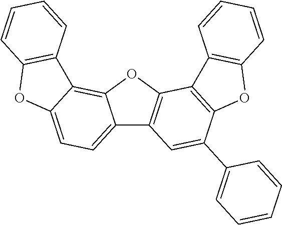 | 15° |
| R1, R12 | 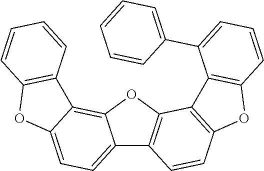 | 30° |
| R6, R7 | 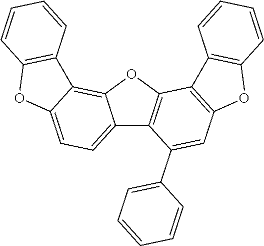 | 33° |

As presented in Table 1, it was found that the substitution positions of R₂, R₃, R₄, R₅, R₈, R₉, R₁₀, and R₁₁ provided particularly small dihedral angles and high degrees of planarity. As described below, a higher degree of planarity of the molecule is preferred because triplet excitons can be efficiently diffused to inhibit triplet-triplet exciton annihilation, thereby further improving the driving durability.

### (3) Guest Molecule (Organometallic Complex)

The guest molecule is an organometallic complex represented by the following general formula [2].

M(L)m(L′)n(L″)p [2]
M

In formula [2], M is selected from iridium and platinum. Preferably, M is iridium.
L, L′, and L″

L, L′, and L″ are each a different bidentate ligand.
m, n, and p

m is selected from integers of 1 or more and 3 or less, and n and p are each selected from integers of 0 or more and 2 or less, provided that m+n+p=3.

### Partial Structure M(L)m

The partial structure M(L)m is represented by the following general formula [2-1].

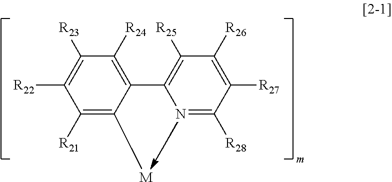

R₂₁ to R₂₈

In formula [2-1], R₂₁ to R₂₈ are each independently selected from a hydrogen atom, a deuterium atom, a halogen atom, a substituted or unsubstituted alkyl group, a substituted or unsubstituted alkoxy group, a substituted or unsubstituted silyl group, a substituted or unsubstituted aryl group, a substituted or unsubstituted heterocyclic group, a substituted or unsubstituted amino group, a substituted or unsubstituted aryloxy group, a substituted or unsubstituted heteroaryloxy group, and a cyano group, provided that at least one of R₂₁ to R₂₈ is selected from a substituted or unsubstituted aryl group and a substituted or unsubstituted heterocyclic group.

Examples of the halogen atom include, but are not limited to, a fluorine atom, a chlorine atom, a bromine atom, and an iodine atom. Among these, a fluorine atom is preferred.

Examples of the alkyl group include, but are not limited to, a methyl group, an ethyl group, a n-propyl group, an isopropyl group, a n-butyl group, a tert-butyl group, a sec-butyl group, an octyl group, a cyclohexyl group, a 1-adamantyl group, and a 2-adamantyl group.

Examples of the alkoxy group include, but are not limited to, a methoxy group, an ethoxy group, a propoxy group, a 2-ethyloctyloxy group, and a benzyloxy group.

Examples of the silyl group include, but are not limited to, a trimethylsilyl group and a triphenylsilyl group.

Examples of the aryl group include, but are not limited to, a phenyl group, a naphthyl group, an indenyl group, a biphenyl group, a terphenyl group, a fluorenyl group, a phenanthryl group, a fluoranthenyl group, and a triphenylenyl group.

Examples of the heterocyclic group include, but are not limited to, a pyridyl group, a pyrimidinyl group, a pyrazinyl group, a triazolyl group, an oxazolyl group, an oxadiazolyl group, a thiazolyl group, a thiadiazolyl group, a carbazolyl group, an acridinyl group, a phenanthrolinyl group, dibenzofuranyl group, and dibenzothiophenyl group.

Examples of the amino group include, but are not limited to, an N-methylamino group, an N-ethylamino group, an N,N-dimethylamino group, an N,N-diethylamino group, an N-methyl-N-ethylamino group, an N-benzylamino group, an N-methyl-N-benzylamino group, an N,N-dibenzylamino group, an anilino group, an N,N-diphenylamino group, an N,N-dinaphthylamino group, an N,N-difluorenylamino group, an N-phenyl-N-tolylamino group, an N,N-ditolylamino group, an N-methyl-N-phenylamino group, an N,N-dianisolylamino group, an N-mesityl-N-phenylamino group, an N,N-dimesitylamino group, an N-phenyl-N-(4-tert-butylphenyl)amino group, an N-phenyl-N-(4-trifluoromethylphenyl)amino group, an N-piperidyl group, and a carbazolyl group.

Examples of the aryloxy group and the heteroaryloxy group include, but are not limited to, a phenoxy group and a thienyloxy group.

Examples of substituents that may be further contained in the alkyl group, the alkoxy group, the silyl group, the aryl group, the heterocyclic group, the amino group, the aryloxy group, and the heteroaryloxy group include, but are not limited to, a deuterium atom; halogen atoms, such as a fluorine atom, a chlorine atom, a bromine atom, and an iodine atom; alkyl groups, such as a methyl group, an ethyl group, a n-propyl group, an isopropyl group, a n-butyl group, and a tert-butyl group; alkoxy groups, such as a methoxy group, an ethoxy group, and a propoxy group; amino groups, such as a dimethylamino group, a diethylamino group, a dibenzylamino group, a diphenylamino group, and a ditolylamino group; aryloxy groups, such as a phenoxy group; aromatic hydrocarbon groups, such as a phenyl group and a biphenyl group; heterocyclic groups, such as a pyridyl group and a pyrrolyl group; and a cyano group, a hydroxy group, and a thiol group.

Adjacent groups of R₂₁ to R₂₈, preferably adjacent groups of R₂₁ to R₂₄ or adjacent groups of R₂₅ to R₂₈ may be taken together to form a ring. The expression “adjacent groups of R₂₁ to R₂₈ are taken together to form a ring” indicates that a ring formed by taking R₂₁ and R₂₂, R₂₂ and R₂₃, or R₂₃ and R₂₄ together and the benzene ring to which R₂₁ to R₂₄ are attached form a fused ring, or that a ring formed by taking R₂₅ and R₂₆, R₂₆ and R₂₇, or R₂₇ and R₂₈ together and the pyridine ring to which R₂₅ to R₂₈ are attached form a fused ring. The ring formed by taking adjacent groups of R₂₁ to R₂₈ together may be an aromatic ring.

### Partial Structure M (L′)n

The partial structure M(L′)n is represented by the following general formula [2-2].

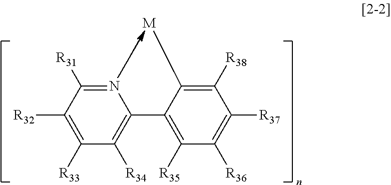

R₃₁ to R₃₈

In formula [2-2], R₃₁ to R₃₈ are each independently selected from a hydrogen atom, a deuterium atom, a halogen atom, a substituted or unsubstituted alkyl group, a substituted or unsubstituted alkoxy group, a substituted or unsubstituted silyl group, a substituted or unsubstituted aryl group, a substituted or unsubstituted heterocyclic group, a substituted or unsubstituted amino group, a substituted or unsubstituted aryloxy group, a substituted or unsubstituted heteroaryloxy group, and a cyano group.

Specific examples of the halogen atom, the alkyl group, the alkoxy group, the silyl group, the aryl group, the heterocyclic group, the amino group, the aryloxy group, and the heteroaryloxy group include, but are not limited to, the same as those described for R₃₁ to R₃₈. Specific examples of substituents that may be further contained in the alkyl group, the alkoxy group, the silyl group, the aryl group, the heterocyclic group, the amino group, the aryloxy group, and the heteroaryloxy group include, but are not limited to, the same as those described for R₃₁ to R₃₈.

Adjacent groups of R₃₁ to R₃₈, preferably adjacent groups of R₃₁ to R₃₄ or adjacent groups of R₃₅ to R₃₈ may be taken together to form a ring. The expression “adjacent groups of R₃₁ to R₃₈ are taken together to form a ring” indicates that a ring formed by taking R₃₁ and R₃₂, R₃₂ and R₃₃, or R₃₃ and R₃₄ together and the pyridine ring to which R₃₁ to R₃₄ are attached form a fused ring, or that a ring formed by taking R₃₅ and R₃₆, R₃₆ and R₃₇, or R₃₇ and R₃₈ together and the benzene ring to which R₃₅ to R₃₈ are attached form a fused ring. The ring formed by taking adjacent groups of R₃₁ to R₃₈ together may be an aromatic ring.

### Partial Structure M(L″)p

The partial structure M(L″)p is represented by the following general formula [2-3].

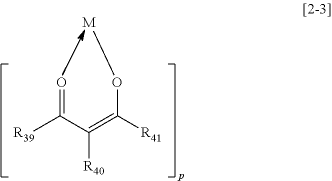

R₃₉ to R₄₁

In formula [2-3], R₃₉ to R₄₁ are each independently selected from a hydrogen atom, a deuterium atom, a halogen atom, a substituted or unsubstituted alkyl group, a substituted or unsubstituted alkoxy group, a substituted or unsubstituted silyl group, a substituted or unsubstituted aryl group, a substituted or unsubstituted heterocyclic group, a substituted or unsubstituted amino group, a substituted or unsubstituted aryloxy group, a substituted or unsubstituted heteroaryloxy group, and a cyano group.

Specific examples of the halogen atom, the alkyl group, the alkoxy group, the silyl group, the aryl group, the heterocyclic group, the amino group, the aryloxy group, and the heteroaryloxy group include, but are not limited to, the same as those described for R₃₁ to R₃₈. Specific examples of substituents that may be further contained in the alkyl group, the alkoxy group, the silyl group, the aryl group, the heterocyclic group, the amino group, the aryloxy group, and the heteroaryloxy group include, but are not limited to, the same as those described for R₃₁ to R₃₈.

Among the organometallic complexes represented by general formula [2], an organometallic complex in which the partial structure M(L)m contains a tricyclic or higher cyclic fused ring is preferred. This is because the degree of planarity is improved by a skeleton containing the tricyclic or higher cyclic fused ring, and the energy transfer from the host molecule is promoted, leading to higher efficiency and improved durability. Examples of the tricyclic or higher cyclic fused ring include a phenanthrene ring, a triphenylene ring, a benzofluorene ring, a dibenzofuran ring, a dibenzothiophene ring, a benzoaphthofuran ring, a benzoaphthothiophene ring, a benzoisoquinoline ring, and a naphthoisoquinoline ring.

### (4) Effects Provided by Host Molecule and Guest Molecule

In the organic light-emitting device of the present embodiment, the light-emitting layer contains the guest molecule and the host molecule. The host molecule is an organic compound represented by general formula [1], and the guest molecule is an organometallic complex represented by general formula [2].

To use the host material of the present embodiment more usefully, an organic compound having a fused-ring chalcogenophene skeleton and a guest material suitable for the light-emitting layer have been studied. The inventors have found that the luminous efficiency and the driving durability of an organic light-emitting device can be improved by designing the molecules of a host material and a guest material in consideration of the following points.
(I) Each of the host material and the guest material has a highly planar skeleton.
(II) The host material has no SP³ carbon atoms or amino groups and has high bond stability.

The following two factors considered as luminance degradation factors are suppressed: (I) triplet-triplet exciton annihilation, which leads to the deterioration of the material of the light-emitting layer, and (II) the deterioration of the host due to bond dissociation. Thereby, the lifetime of the organic light-emitting device can be extended.
(I) Each of the host material and the guest material has a highly planar skeleton.

In the light-emitting layer of a phosphorescent device, exciton annihilation between triplet excitons formed by recombination is known to lead to a decrease in efficiency and driving durability. This is because the excitation lifetime of triplet excitons is longer than that of singlet excitons, and they are present in the light-emitting layer more, increasing the probability of triplet excitons colliding with each other. The inventors have found a means for reducing the probability of the triplet excitons colliding with each other. The means is to improve the degree of planarity of the host molecules and reduce the distance between the molecules, thereby facilitating the diffusion of triplet excitons.

To reduce the distance between molecules, we have designed a highly planar molecule that is not substituted with a sterically hindering group, such as an SP³ carbon atom or an amino group. In addition, we have found that improving the planarity of the guest material can lead to higher efficiency and improved durability. This will be described below.

In the partial structure M(L)m of the organometallic complex represented by general formula [2], at least one of R₂₁ to R₂₈ is an aryl group or a heterocyclic group, thereby extending the conjugated plane of the π orbitals. As a result, an interaction with a material (in particular, a host material) near the guest material occurs easily, so that energy transfer from the host material to the light-emitting material can be promoted. In contrast, in the Ir(ppy)₃ complex described in Patent Literature 1, the molecule is globular, and the conjugated plane of the π orbitals is narrow. This limits energy transfer between the host material and the guest material, and triplet excitons are accumulated in the host molecules, thereby accelerating triplet-triplet exciton annihilation. Therefore, the efficiency and durability are reduced.

The inventors have found that the efficiency and driving durability of an organic light-emitting device can be improved by molecular design in which “each of a host material and a guest material has a highly planar skeleton” in order to avoid triplet-triplet exciton annihilation.

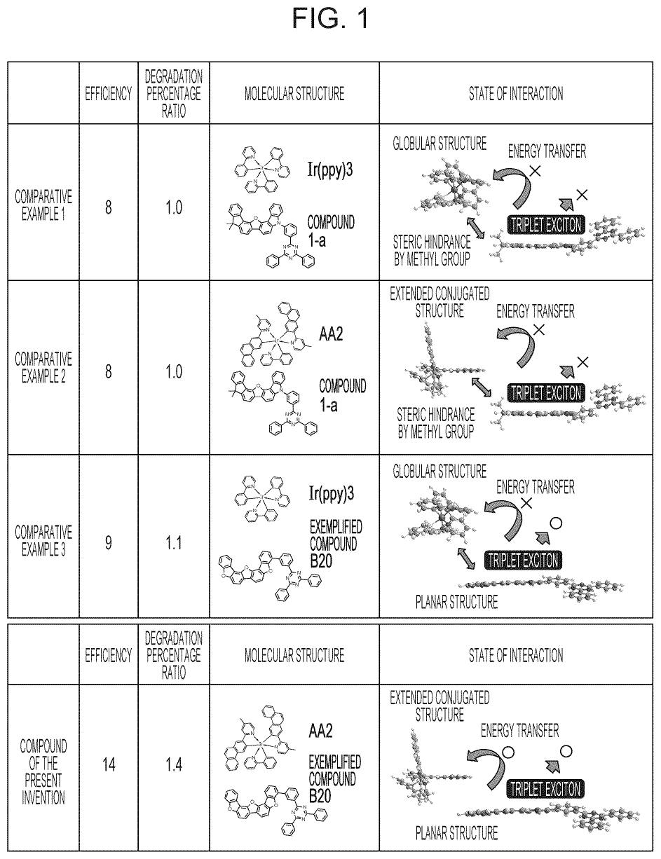

FIG. 1 illustrates the states of the molecular structures and intermolecular interactions of a host material and a guest material of the present invention and comparative compounds, and the efficiency (E.Q.E) and the percentage ratio of luminance degradation described in each example.

In the case of a host having an alkyl group (comparative compound 1-a) of Comparative Examples 1 and 2, the degree of planarity of the molecule is low and triplet excitons cannot diffuse but accumulate; thus, the durability characteristics are not good due to triplet-triplet exciton annihilation. In addition, due to the steric hindrance effect of the alkyl groups, the intermolecular distance between the host material and the guest material is long regardless of the iridium complex, and the energy transfer efficiency is lowered; thus, the efficiency is low, and the durability characteristics are also not good due to the triplet-triplet exciton annihilation caused by the accumulation of triplet excitons.

As in Comparative Example 3, even when the highly planar host material of the present embodiment is used, in the case where the iridium complex has a globular structure, although there is a diffusion effect of triplet excitons, the energy transfer efficiency is reduced, and thus, the percentage of luminance degradation is slightly improved, but the efficiency is low.

In contrast, the combination of the host and the guest of the present embodiment promotes the diffusion of triplet excitons and improves energy transfer efficiency, thus improving both efficiency and luminance degradation.
(II) The host material has no SP³ carbon atoms or amino groups and has high bond stability.

A compound in an organic layer of an organic light-emitting device, particularly in a light-emitting layer, repeatedly transitions between a ground state and an excited state in the process of light emission of the organic light-emitting device. In this process, intense molecular movements, such as stretching and rotation, occur. At this time, if there is a site where the bond is easily dissociated, the bond may be cleaved to liberate a portion of the compound. When a portion of the compound is liberated, the structure is changed. Thus, when the liberation occurs easily, the durability as a compound decreases. In addition, when such a compound is used in an organic light-emitting device, the liberated portion serves as a quencher to reduce the device durability. Therefore, a molecule having a structure in which a bond is less likely to be dissociated and liberation is less likely to occur has better durability.

Comparative compound 1-a has a C(SP³)—C(SP³) bond and a C—N bond. These bond dissociation energies are 88 kcal/mol and 87-104 kcal/mol, respectively. The bond dissociation energy of the C(SP²)—C(SP²) bond is 110 kcal/mol; thus, the C(SP³)—C(SP³) bond and the C—N bond are more likely to be dissociated.

For this reason, the organic compound according to the present embodiment is less likely to be liberated due to bond cleavage and is more durable than comparative compound 1-a. When the organic compound according to the present embodiment is used in an organic layer of an organic light-emitting device, the liberation due to the bond cleavage during the driving of the device does not easily occur, so that the deterioration of the device is inhibited even when the device is driven for a long time. Thus, the organic light-emitting device having excellent durability can be provided.

As described above, in the present embodiment, by the above (I) and (II), the energy transfer from the host molecule to the guest molecule is promoted, the triplet-triplet exciton annihilation in the host molecule can be inhibited, and the bond stability of the host molecule is also high, thereby improving the luminous efficiency and the driving durability.

### (5) Specific Examples of Host Molecule

Specific structural formulae of the host molecule are exemplified below.

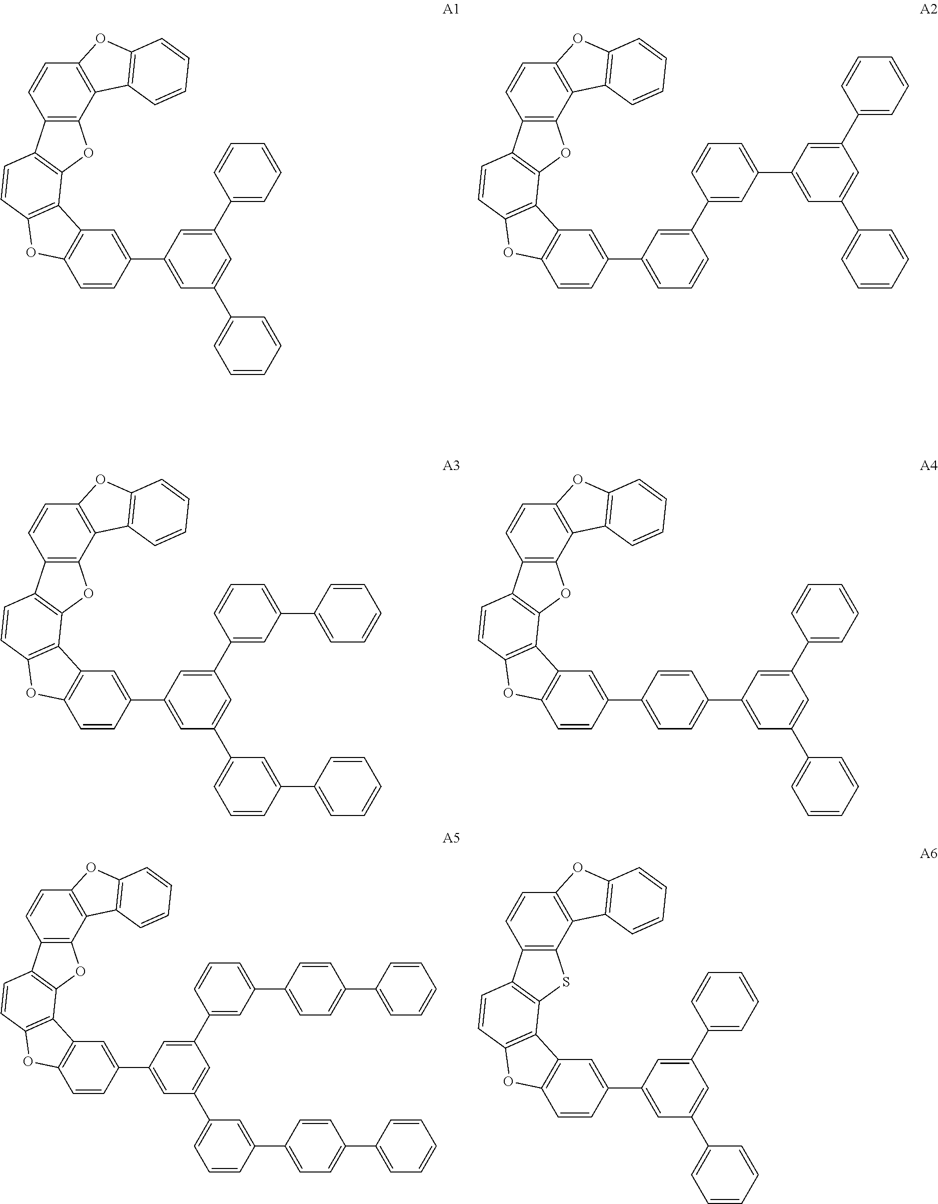

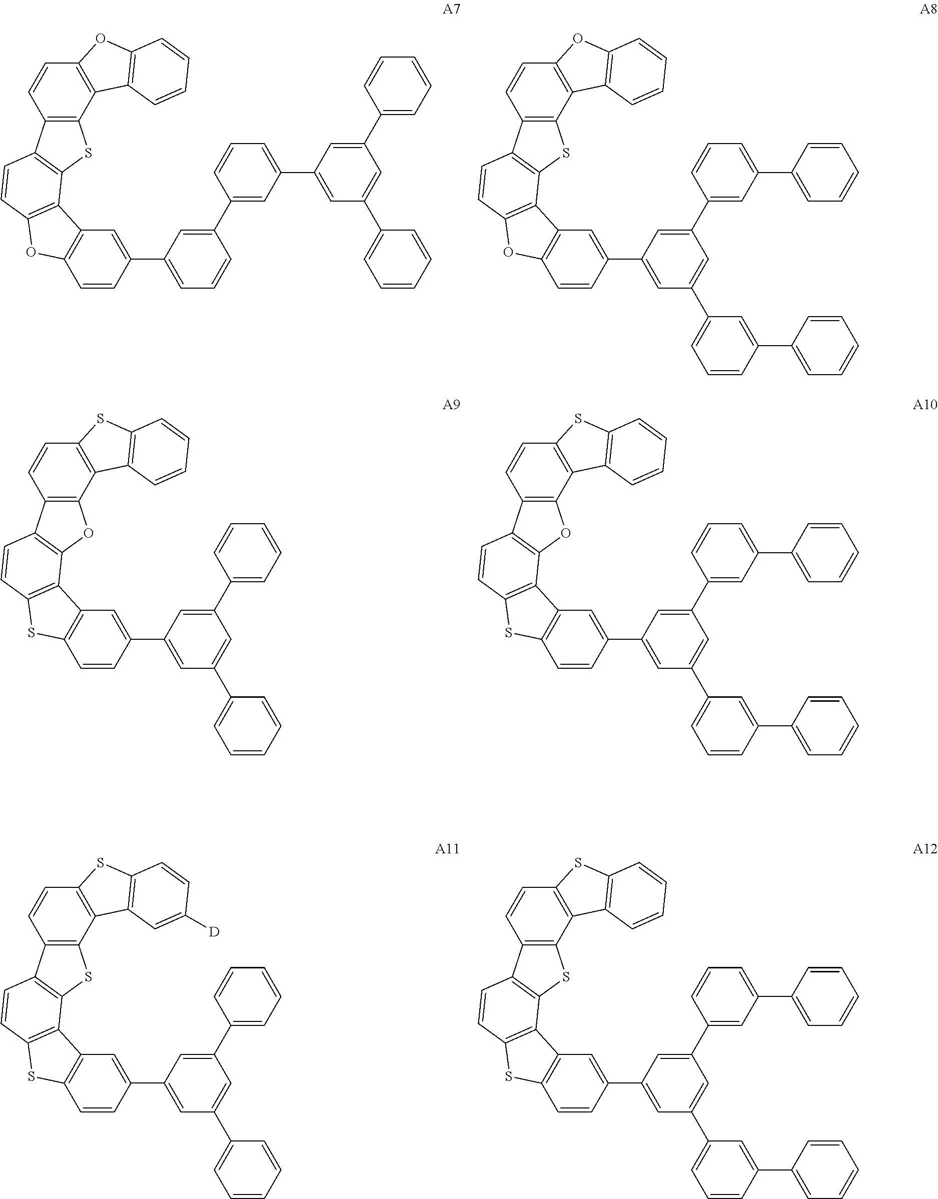

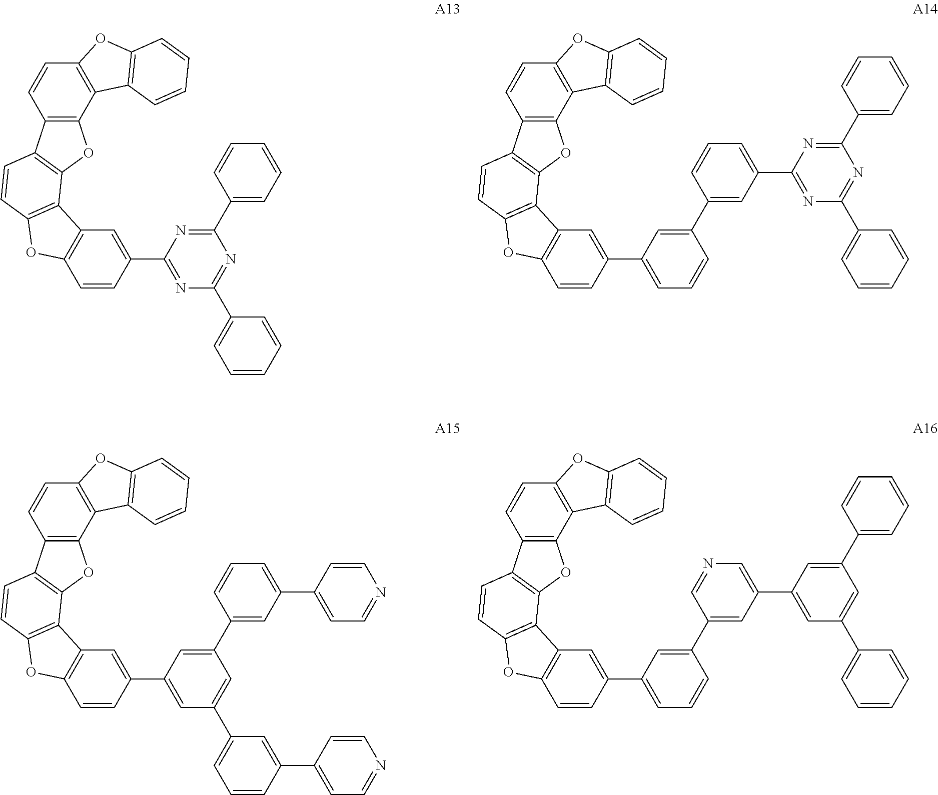 [SMILES: c1ccc(-c2nc(-c3ccccc3)nc(-c3ccc4oc5ccc6c7ccc8oc9ccccc9c8c7oc6c5c4c3)n2)cc1 ; c1ccc(-c2nc(-c3ccccc3)nc(-c3cccc(-c4cccc(-c5ccc6oc7ccc8c9ccc%10oc%11ccccc%11c%10c9oc8c7c6c5)c4)c3)n2)cc1 ; c1cc(-c2ccncc2)cc(-c2cc(-c3cccc(-c4ccncc4)c3)cc(-c3ccc4oc5ccc6c7ccc8oc9ccccc9c8c7oc6c5c4c3)c2)c1 ; c1ccc(-c2cc(-c3ccccc3)cc(-c3cncc(-c4cccc(-c5ccc6oc7ccc8c9ccc%10oc%11ccccc%11c%10c9oc8c7c6c5)c4)c3)c2)cc1]

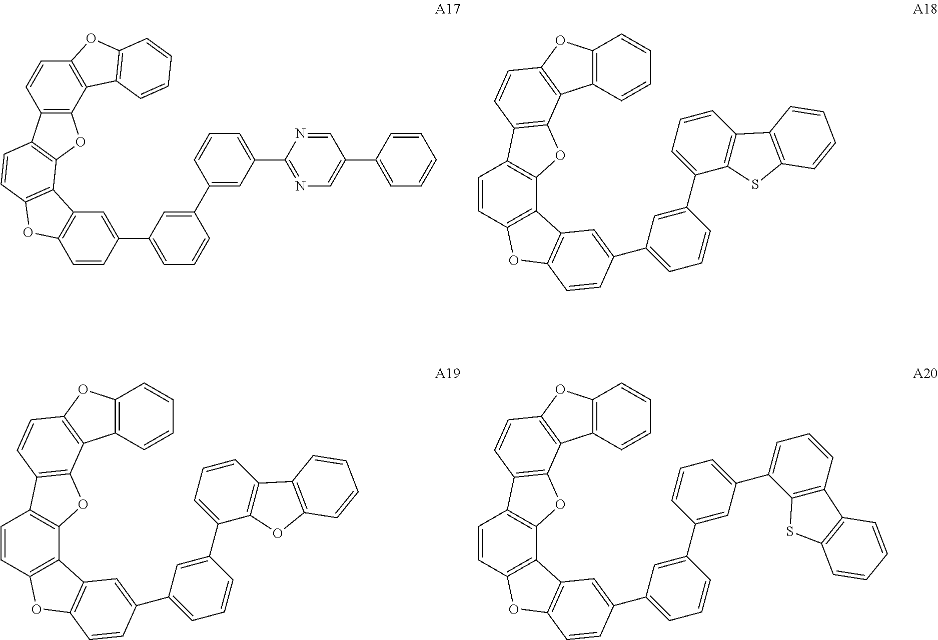

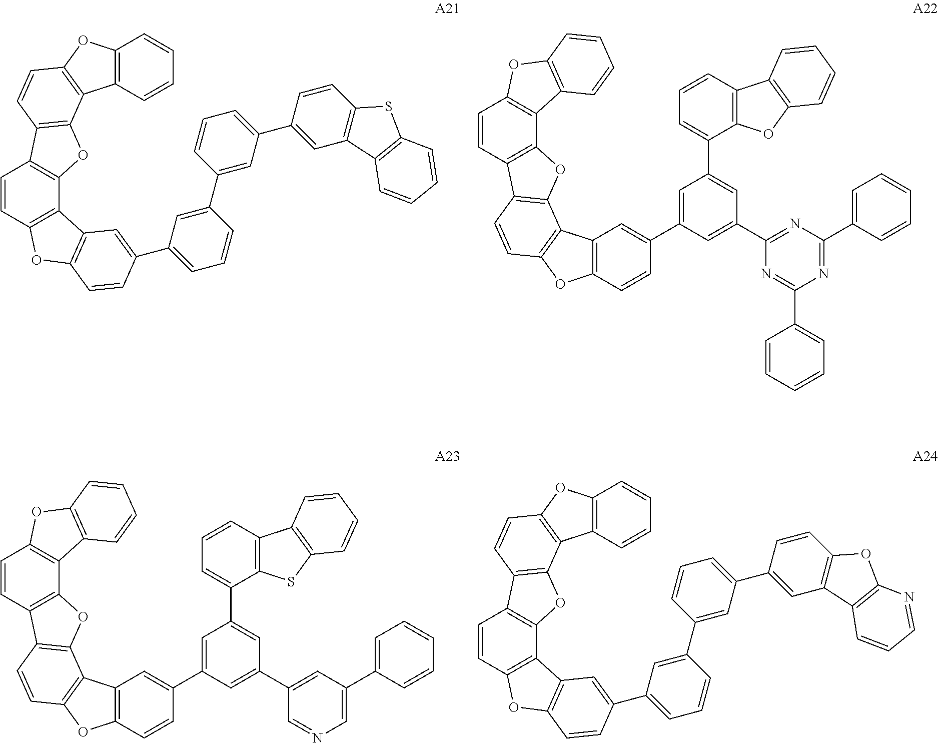

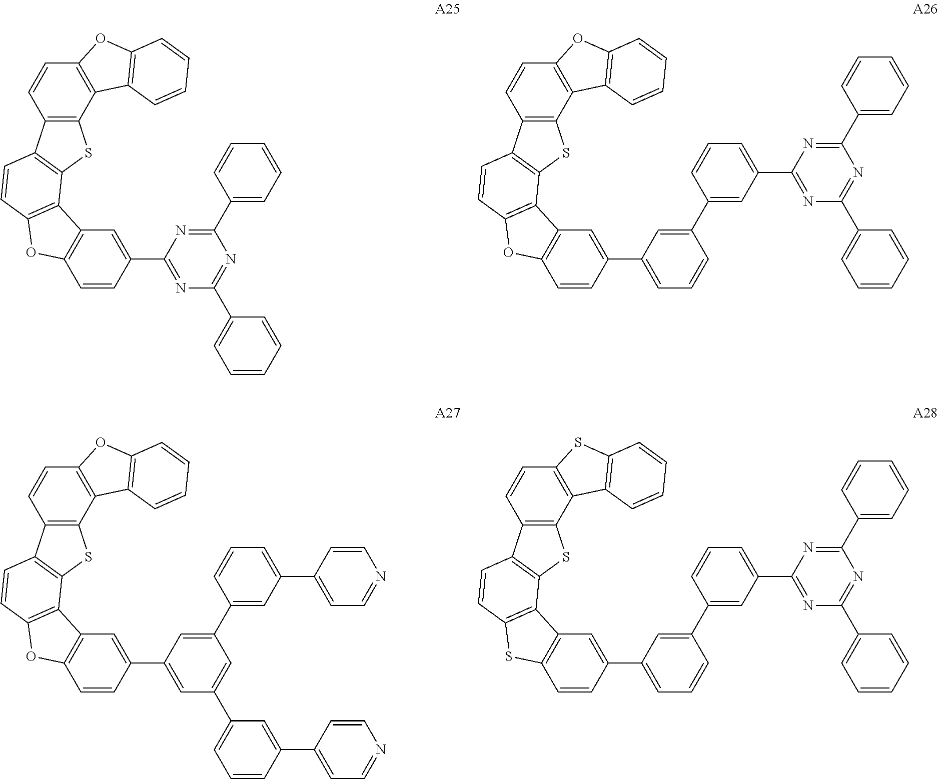 [SMILES: c1ccc(-c2nc(-c3ccccc3)nc(-c3ccc4oc5ccc6c7ccc8oc9ccccc9c8c7sc6c5c4c3)n2)cc1 ; c1ccc(-c2nc(-c3ccccc3)nc(-c3cccc(-c4cccc(-c5ccc6oc7ccc8c9ccc%10oc%11ccccc%11c%10c9sc8c7c6c5)c4)c3)n2)cc1 ; c1cc(-c2ccncc2)cc(-c2cc(-c3cccc(-c4ccncc4)c3)cc(-c3ccc4oc5ccc6c7ccc8oc9ccccc9c8c7sc6c5c4c3)c2)c1 ; c1ccc(-c2nc(-c3ccccc3)nc(-c3cccc(-c4cccc(-c5ccc6sc7ccc8c9ccc%10sc%11ccccc%11c%10c9sc8c7c6c5)c4)c3)n2)cc1]

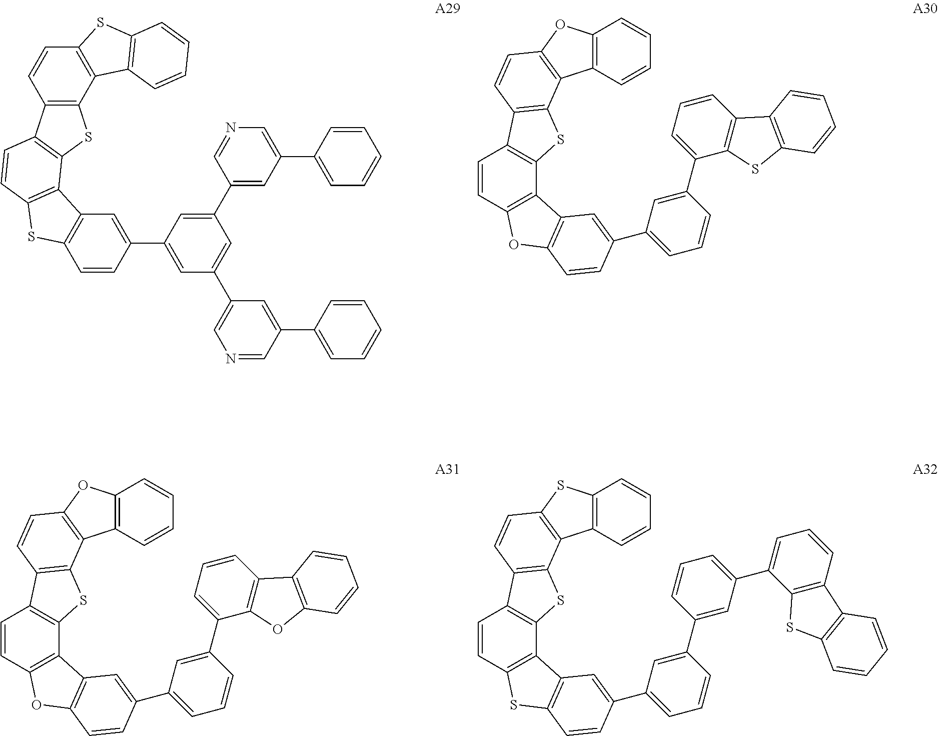 [SMILES: c1ccc(-c2cncc(-c3cc(-c4cncc(-c5ccccc5)c4)cc(-c4ccc5sc6ccc7c8ccc9sc%10ccccc%10c9c8sc7c6c5c4)c3)c2)cc1 ; c1cc(-c2ccc3oc4ccc5c6ccc7oc8ccccc8c7c6sc5c4c3c2)cc(-c2cccc3c2sc2ccccc23)c1 ; c1cc(-c2ccc3oc4ccc5c6ccc7oc8ccccc8c7c6sc5c4c3c2)cc(-c2cccc3c2oc2ccccc23)c1 ; c1cc(-c2cccc(-c3cccc4c3sc3ccccc34)c2)cc(-c2ccc3sc4ccc5c6ccc7sc8ccccc8c7c6sc5c4c3c2)c1]

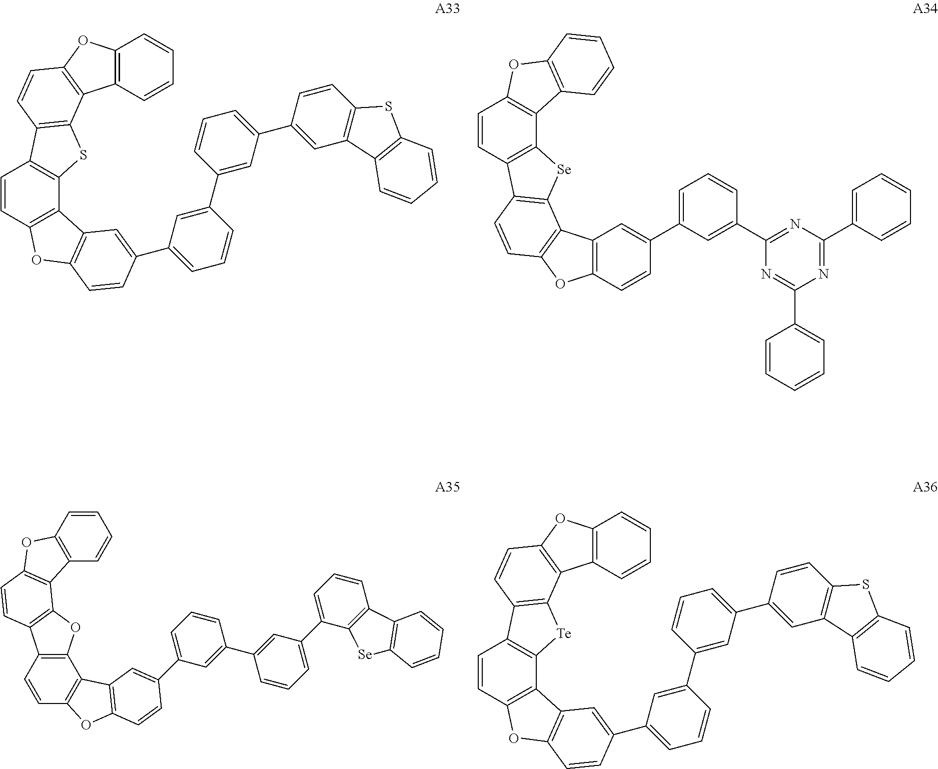

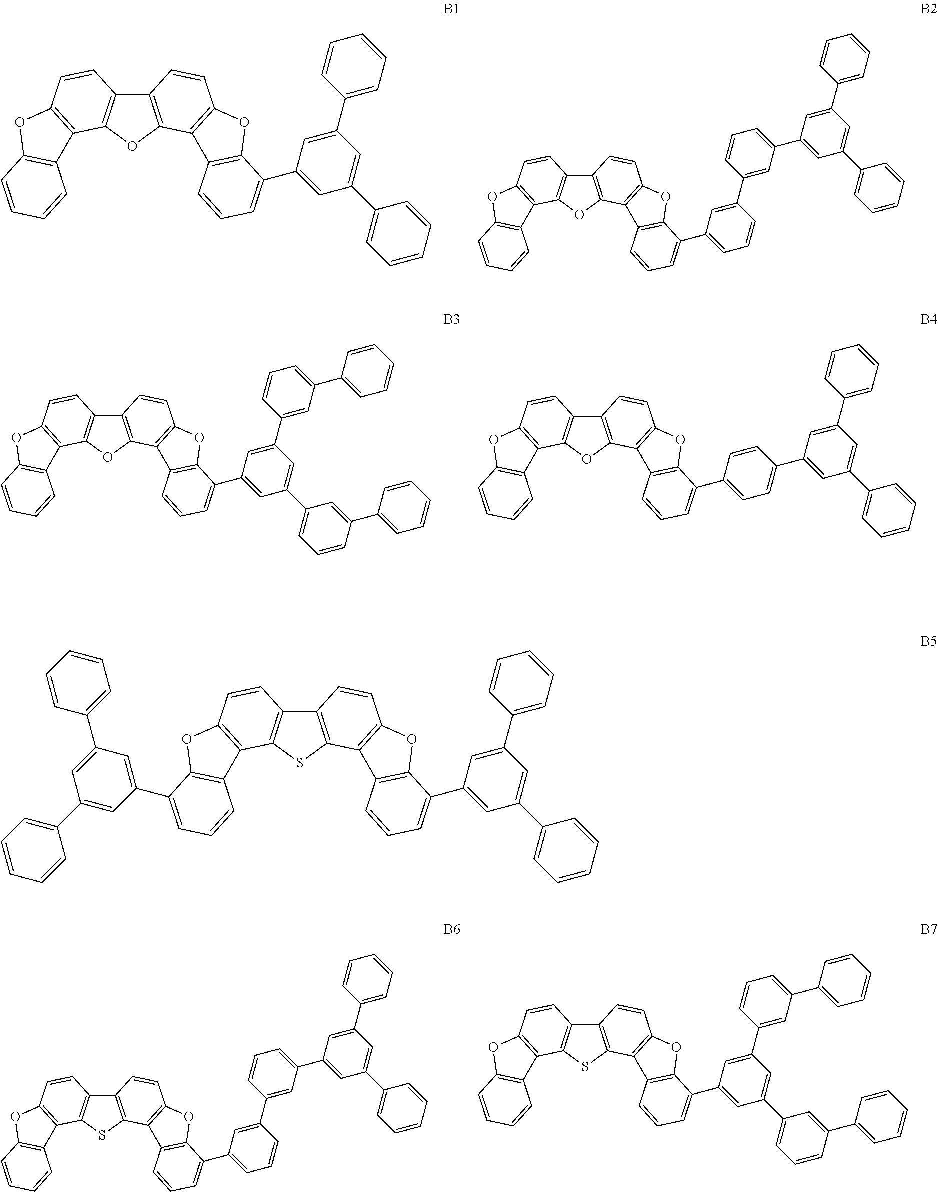

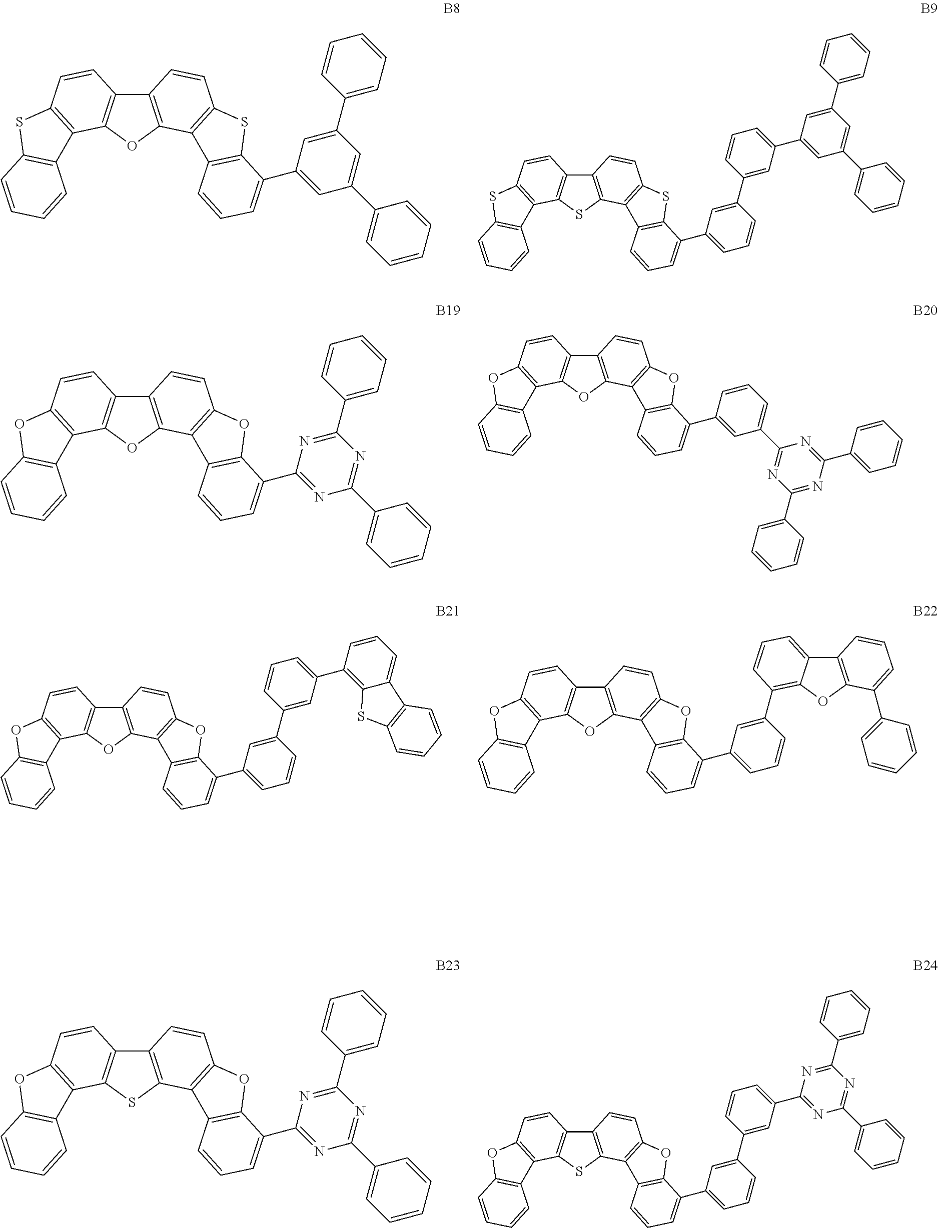

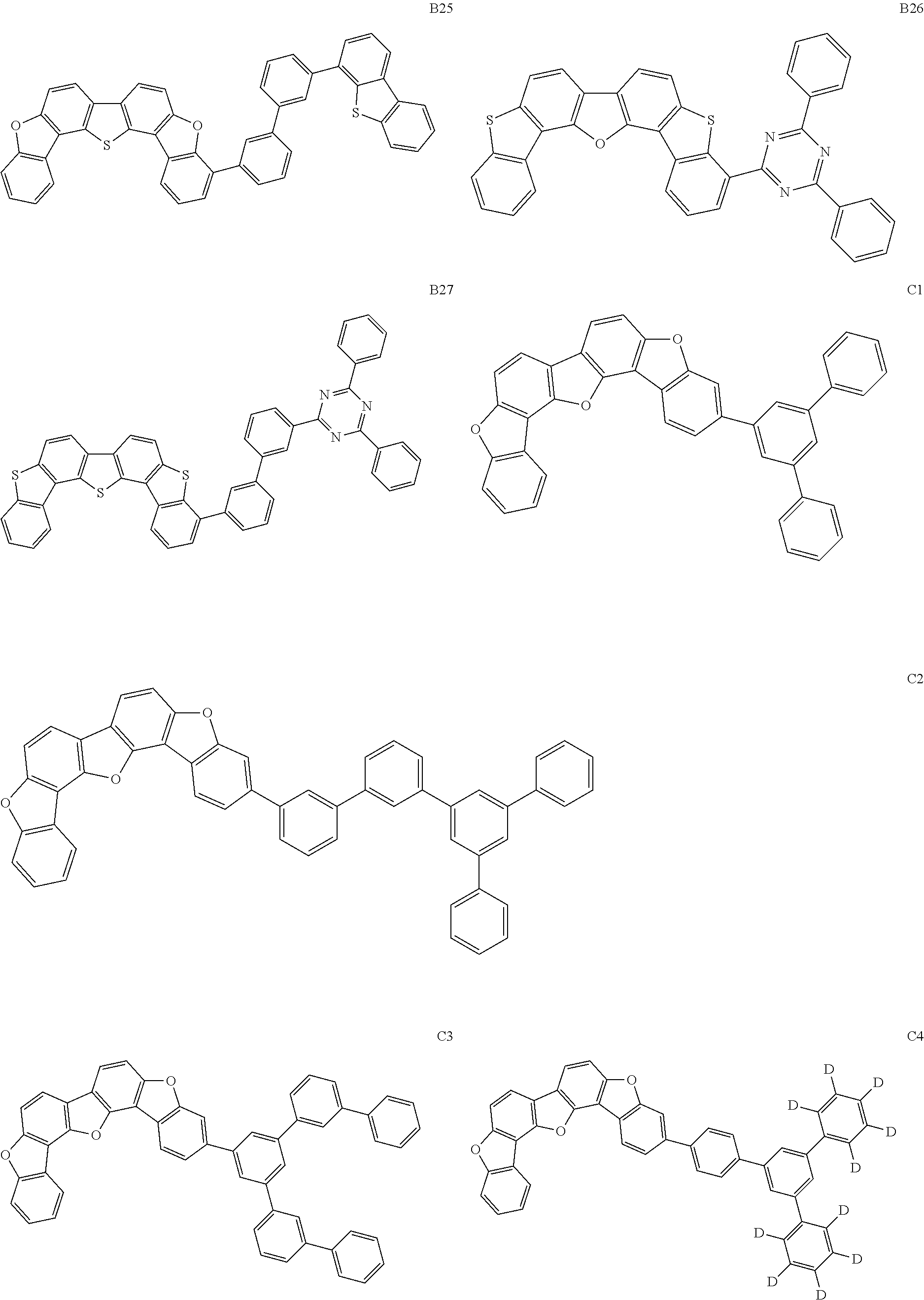

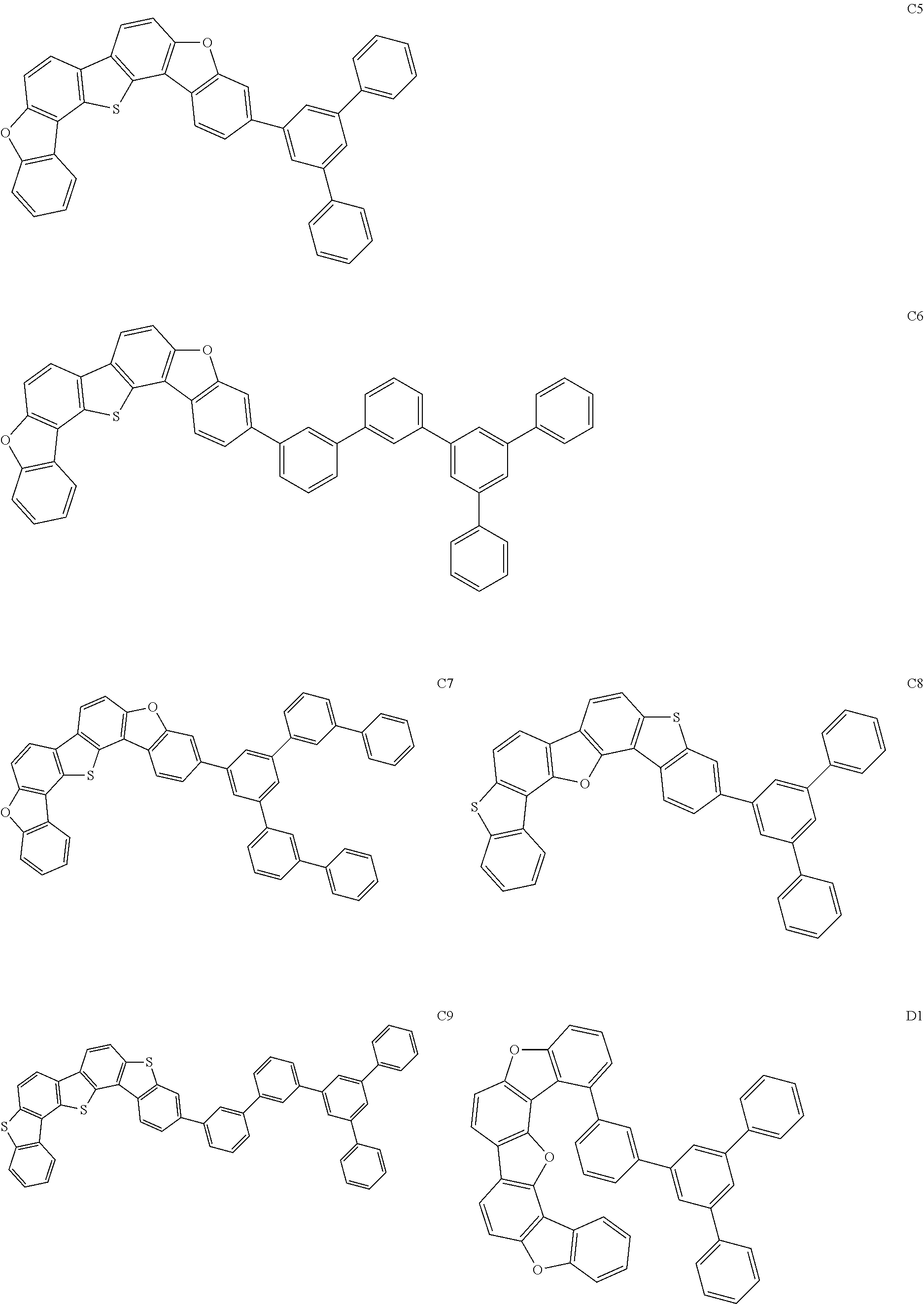

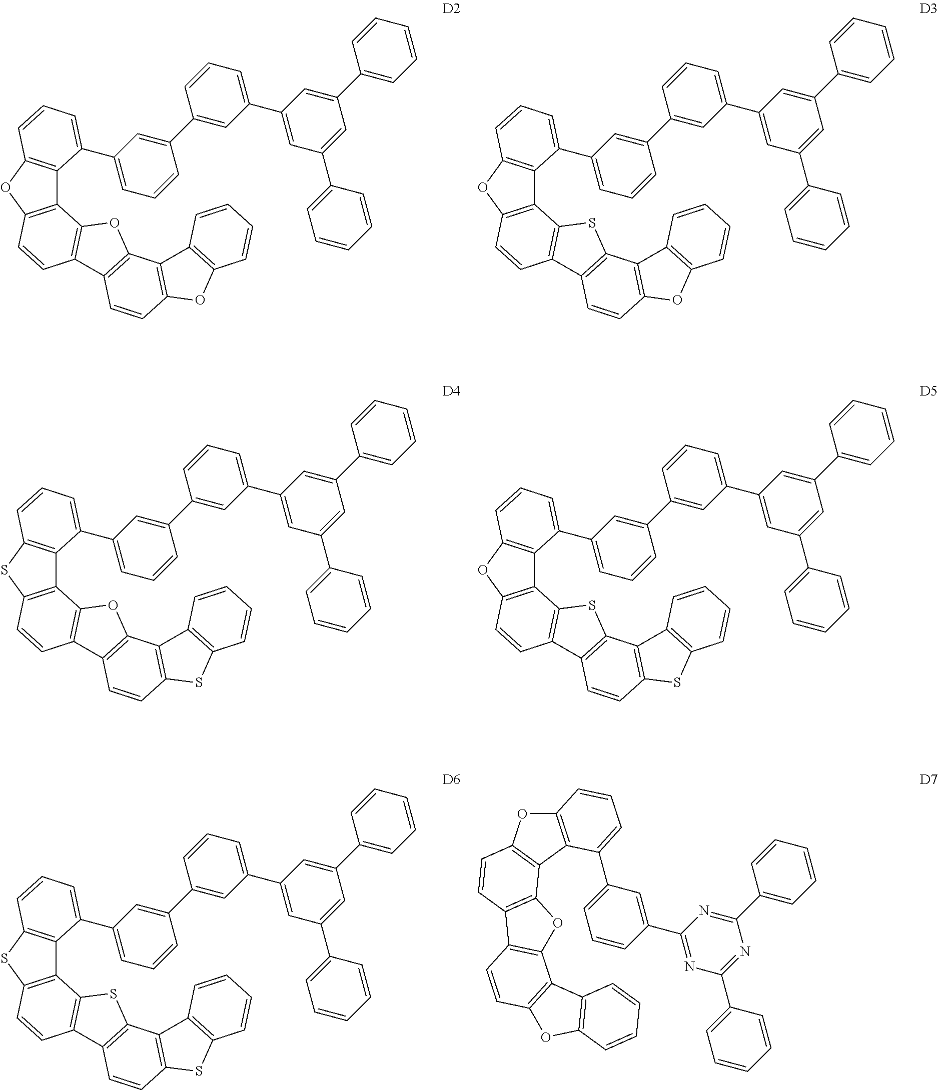

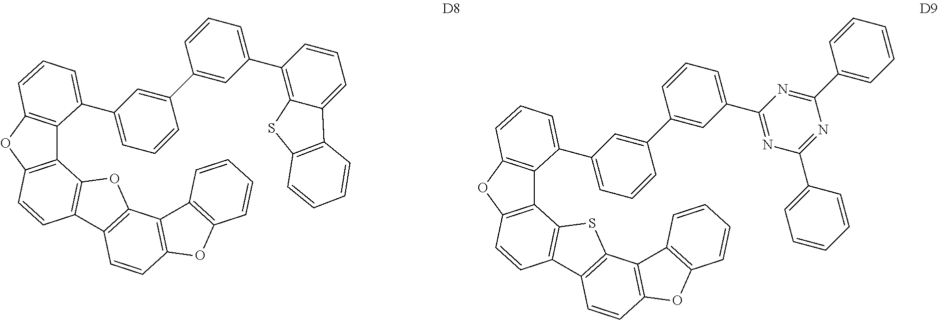 [SMILES: c1cc(-c2cccc(-c3cccc4oc5ccc6c7ccc8oc9ccccc9c8c7oc6c5c34)c2)cc(-c2cccc3c2sc2ccccc23)c1 ; c1ccc(-c2nc(-c3ccccc3)nc(-c3cccc(-c4cccc(-c5cccc6oc7ccc8c9ccc%10oc%11ccccc%11c%10c9sc8c7c56)c4)c3)n2)cc1]

Among the organic compounds represented by formula [3], compounds belonging to group A are a group of compounds in which R₂ or Ru is an aryl group or a heterocyclic group. Among the compounds according to the present embodiment, the compounds belonging to group A have higher degrees of planarity and exhibit higher T₁. That is, group A is a group of compounds characterized by higher efficiency when used in an organic light-emitting device. A13 to A36 are a group of compounds each having a heterocyclic group, and the HOMO level and the LUMO level can be adjusted.

B1 to B9 and B19 to B27 are a group of compounds in which R₄ or R₉ is an aryl group or a heterocyclic group among the organic compounds represented by formula [3]. B10 to B18 and B28 to B36 are a group of compounds in which R₅ or R₈ is an aryl group or a heterocyclic group among the organic compounds represented by formula [3]. Among the compounds according to the present embodiment, the compounds belonging to group B can achieve both film properties and high T₁. That is, group B is a group of compounds characterized by longer lifetime when used in an organic light-emitting device. B19 to B36 are a group of compounds each having a heterocyclic group, and the HOMO level and the LUMO level can be adjusted.

Among the organic compounds represented by formula [3], compounds belonging to group C are a group of compounds in which R₃ or R₁₀ is an aryl group or a heterocyclic group. The compounds belonging to group C have deeper LUMO levels among the compounds according to the present embodiment. That is, group C is a group of compounds characterized by lower-voltage driving when used in an organic light-emitting device. C10 to C18 are a group of compounds each having a heterocyclic group, and the HOMO level and the LUMO level can be adjusted.

D1 to D9 are a group of compounds in which R₁ or R₁₂ is an aryl group or a heterocyclic group among the organic compounds represented by formula [1]. D10 to D18 are a group of compounds in which R₆ or R₇ is an aryl group or a heterocyclic group among the organic compounds represented by formula [1]. Among the compounds according to the present embodiment, the compounds belonging to group D exhibit better film properties. That is, group D is a group of compounds suitable for, for example, a coating process when used in an organic light-emitting device. D7 to D9 and D16 to D18 are a group of compounds each having a heterocyclic group, and the HOMO level and the LUMO level can be adjusted.

### (6) Specific Examples of Organometallic Complex

Specific examples of the partial structure M(L) m of the organometallic complex serving as a guest are illustrated below, but the partial structure is not limited thereto. In each of the specific examples, a coordinate bond is indicated by a straight line, a dotted line, or an arrow.

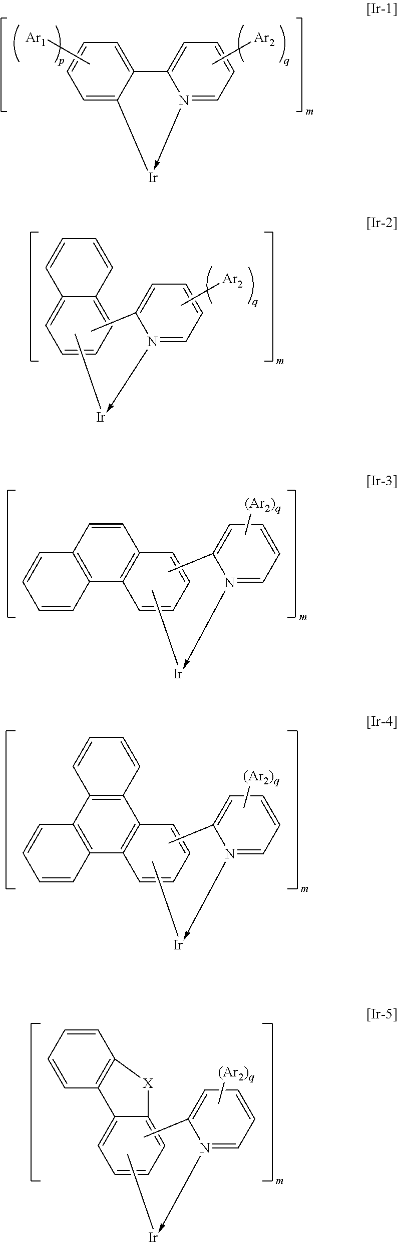

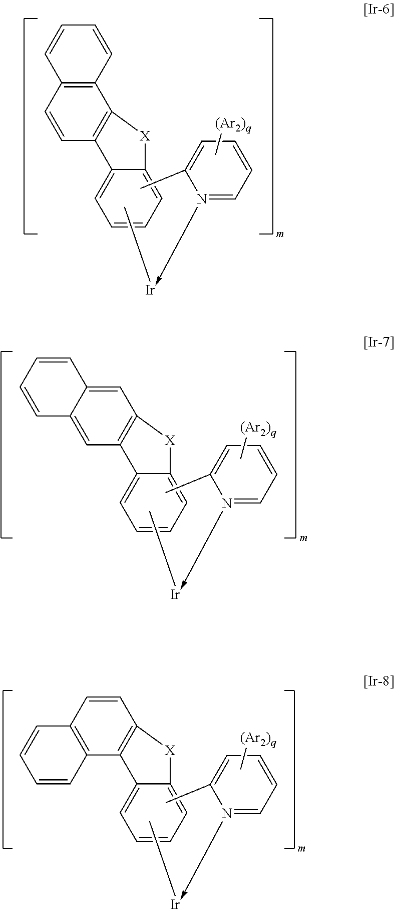

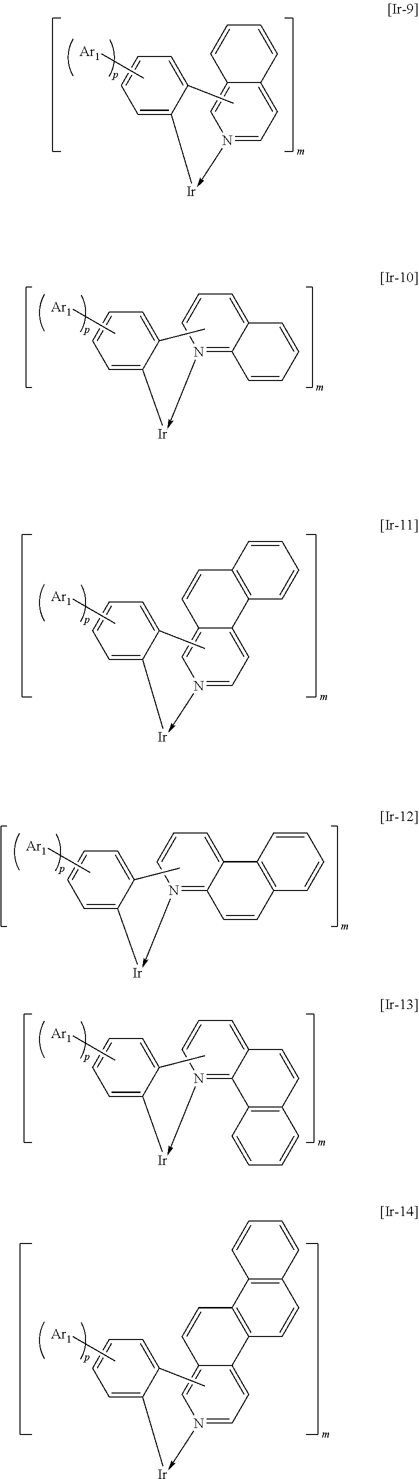

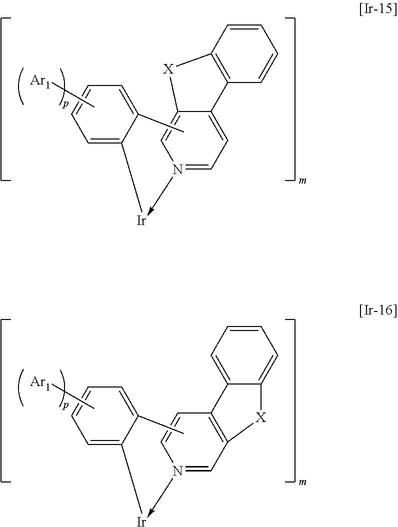

In general formulae [Ir-5] to [Ir-8], [Ir-15], and [Ir-16], each X is selected from an oxygen atom, a sulfur atom, a substituted or unsubstituted carbon atom, and a substituted or unsubstituted nitrogen atom.

In general formulae [Ir-2] to [Ir-8], adjacent groups of R₂₁ to R₂₄ are taken together to form a ring. In general formulae [Ir-9] to [Ir-16], adjacent groups of R₂₅ to R₂₈ are taken together to form a ring. In general formulae [Ir-3] to [Ir-8], at least one of R₂₁ to R₂₄ is a phenyl group or a naphthyl group and forms a ring with an adjacent group. In general formulae [Ir-11] to [Ir-16], at least one of R₂₅ to R₂₈ is a phenyl group or a naphthyl group and forms a ring with an adjacent group. Therefore, general formulae [Ir-3] to [Ir-8] and [Ir-11] to [Ir-16] may further contain or need not further contain an aryl group or a heterocyclic group.

Among the metal complexes each having the partial structure M (L)m represented by any of general formulae [Ir-1] to [Ir-16], metal complexes each having a ligand containing a tricyclic or higher cyclic fused ring are more preferred. Specifically, they are metal complexes each having the partial structure M(L)m represented by any of general formulae [Ir-3] to [Ir-8] and [Ir-11] to [Ir-16]. Specific examples thereof are illustrated below, but the metal complexes are not limited thereto.

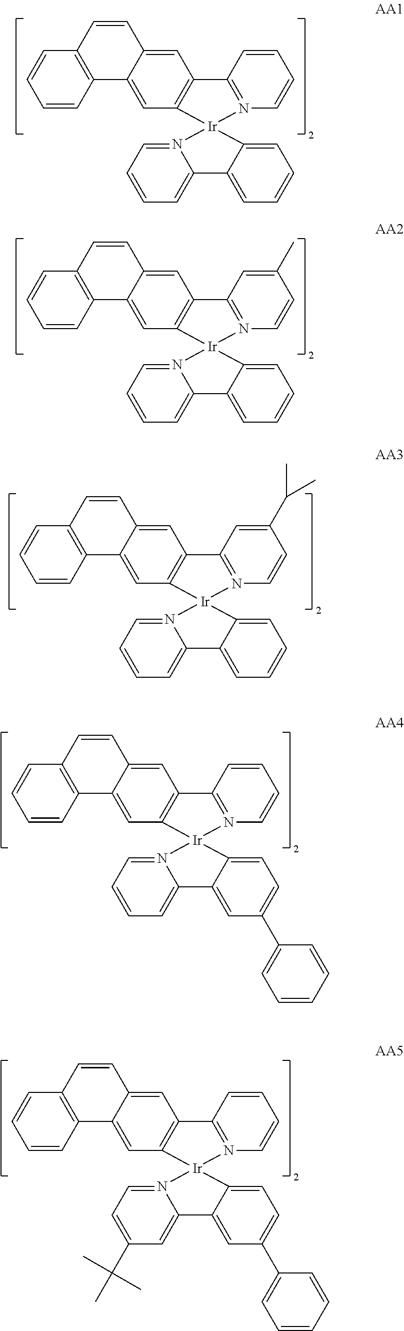

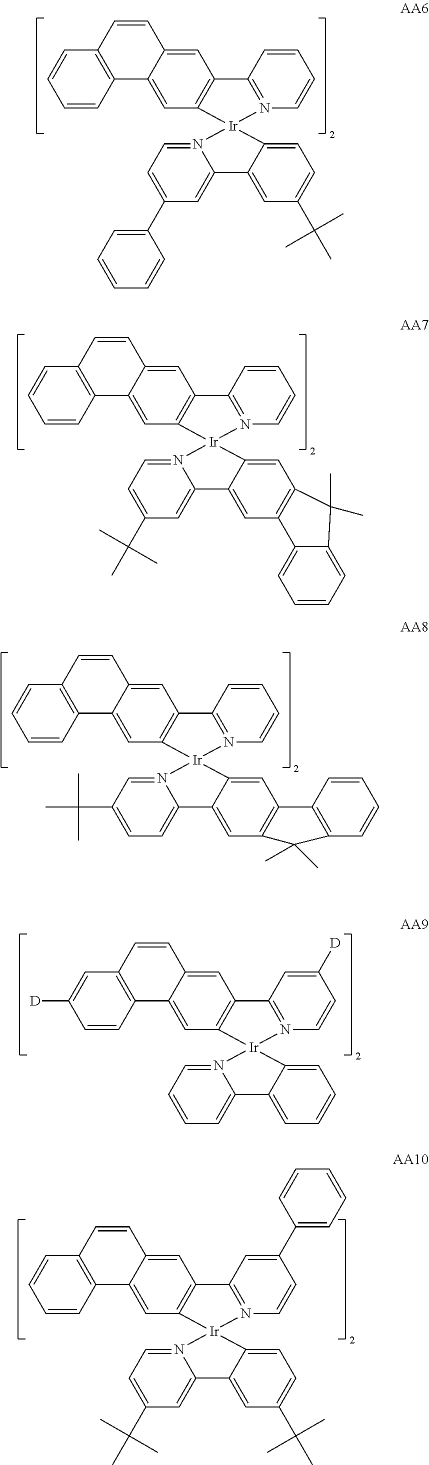

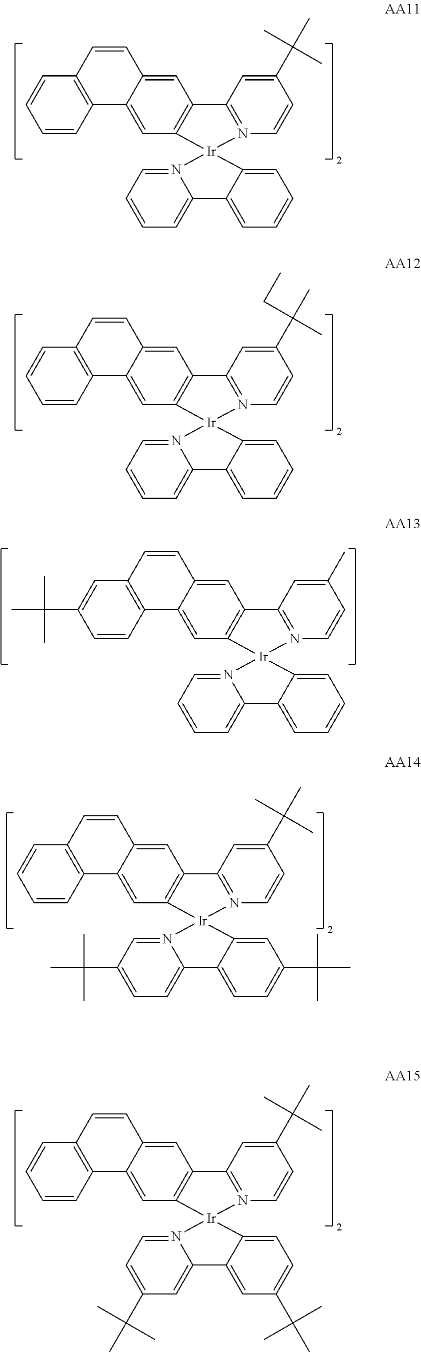

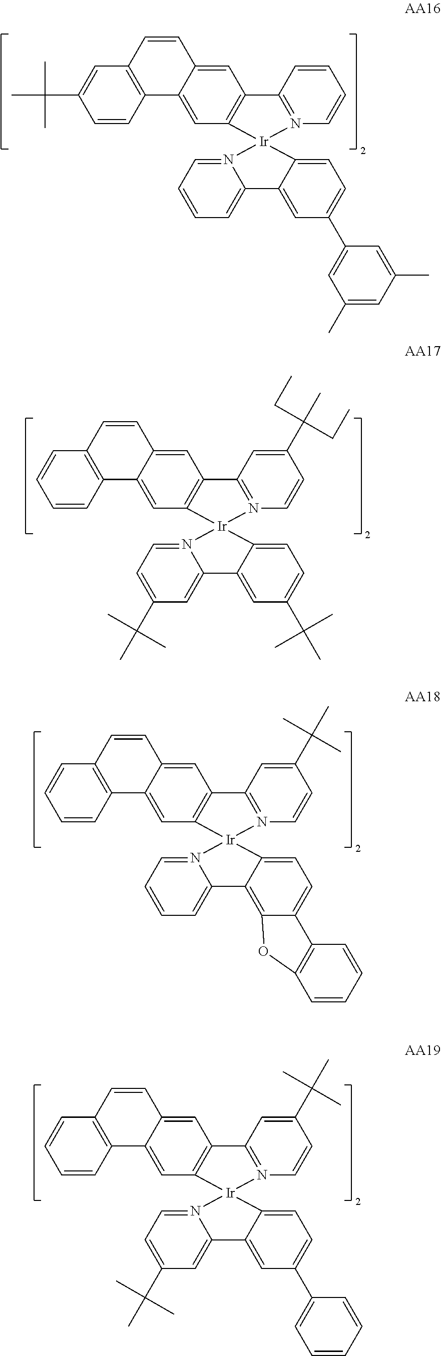

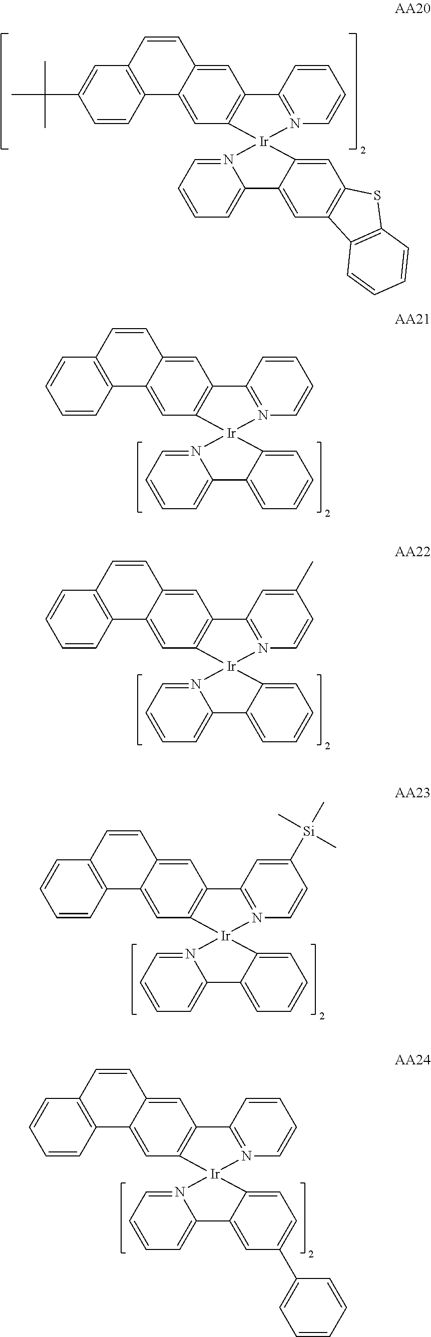

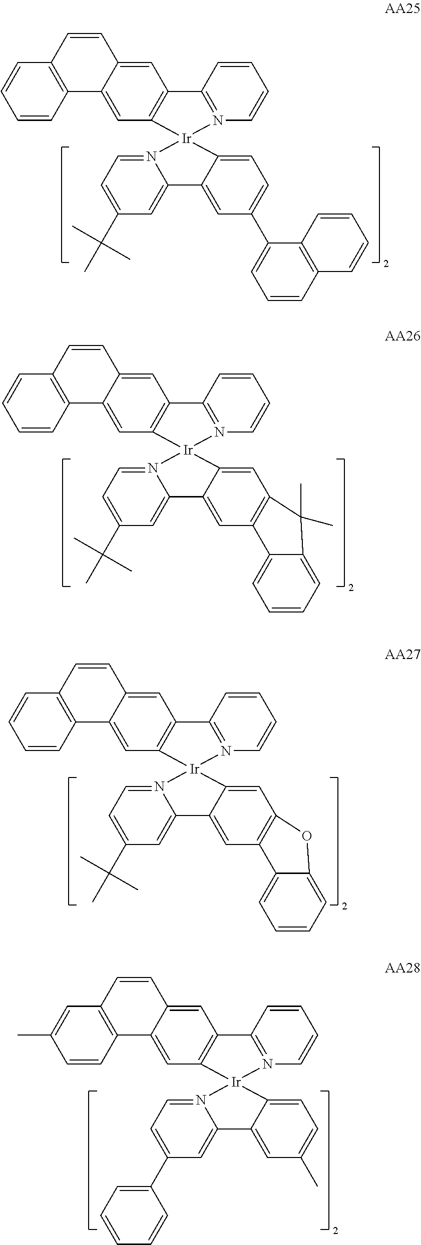

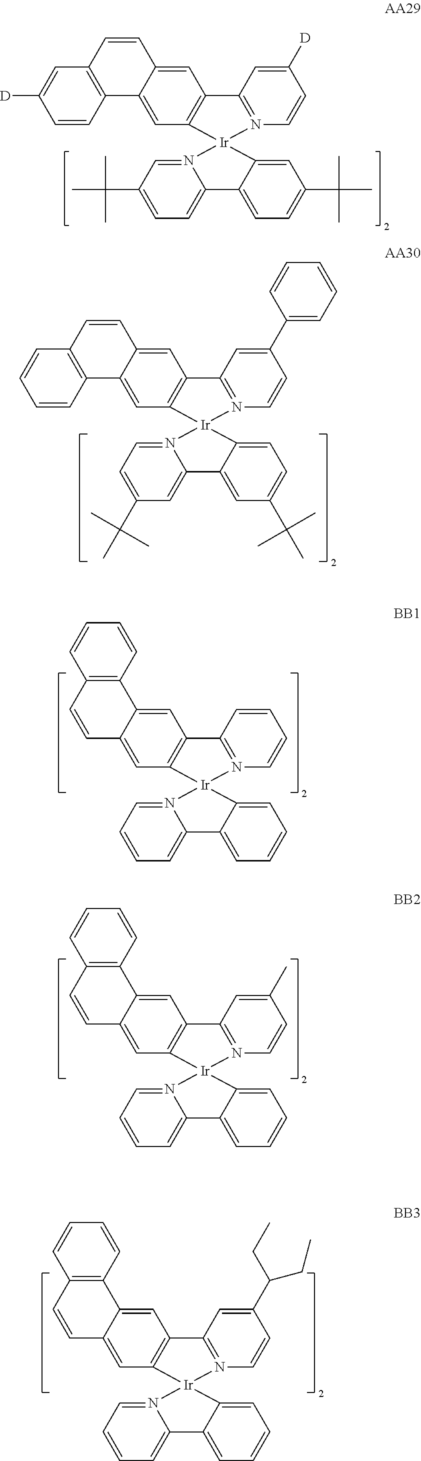

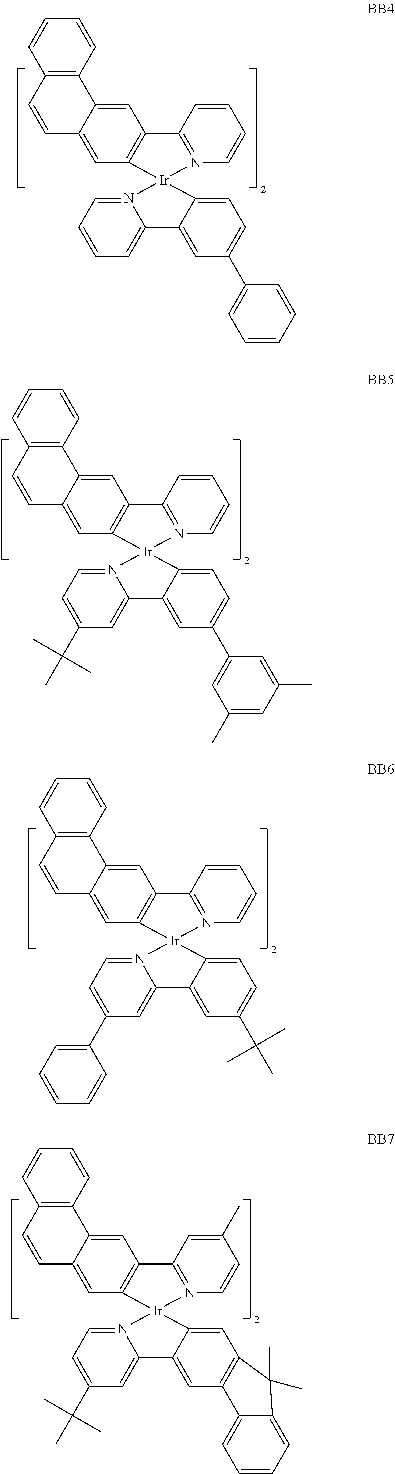

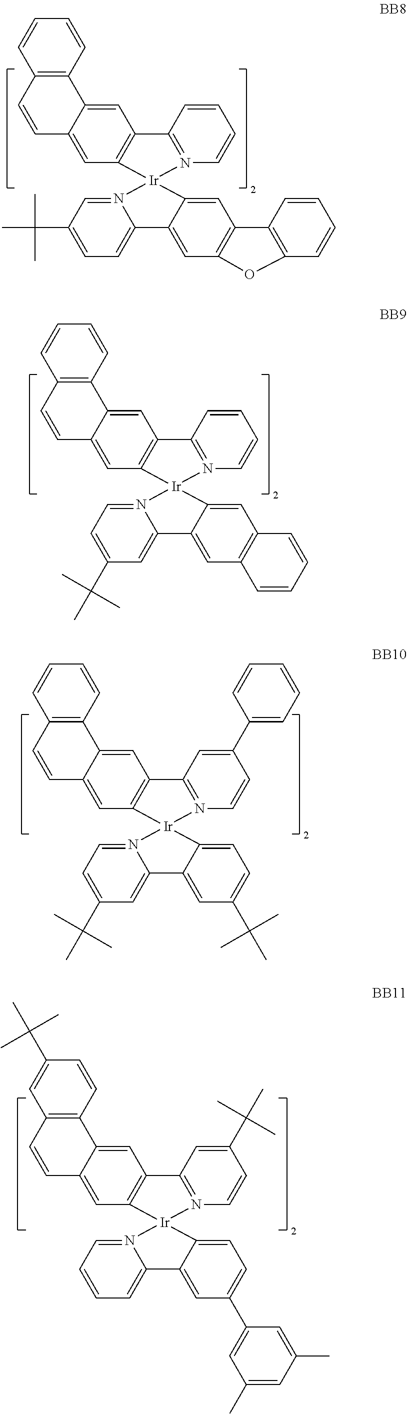

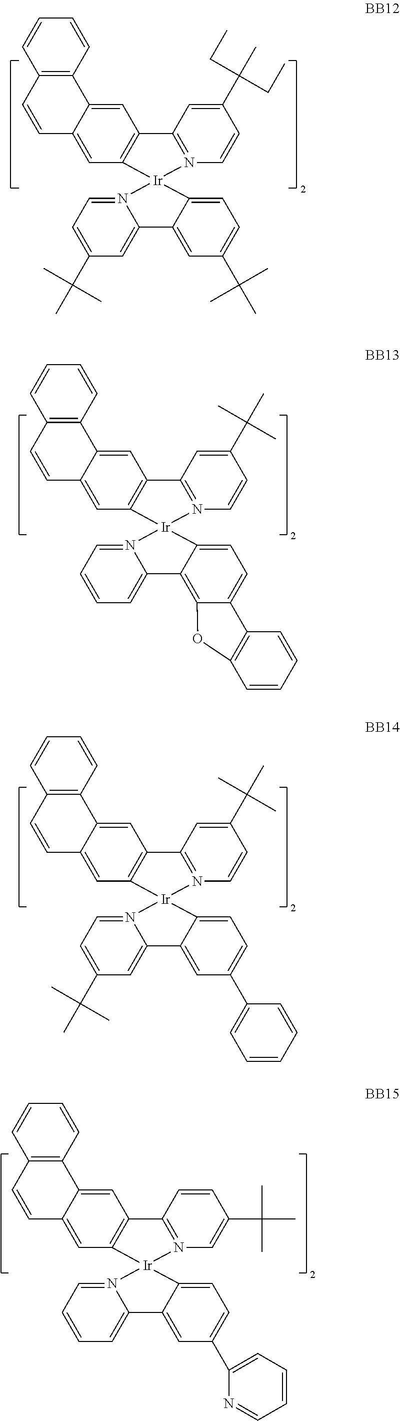

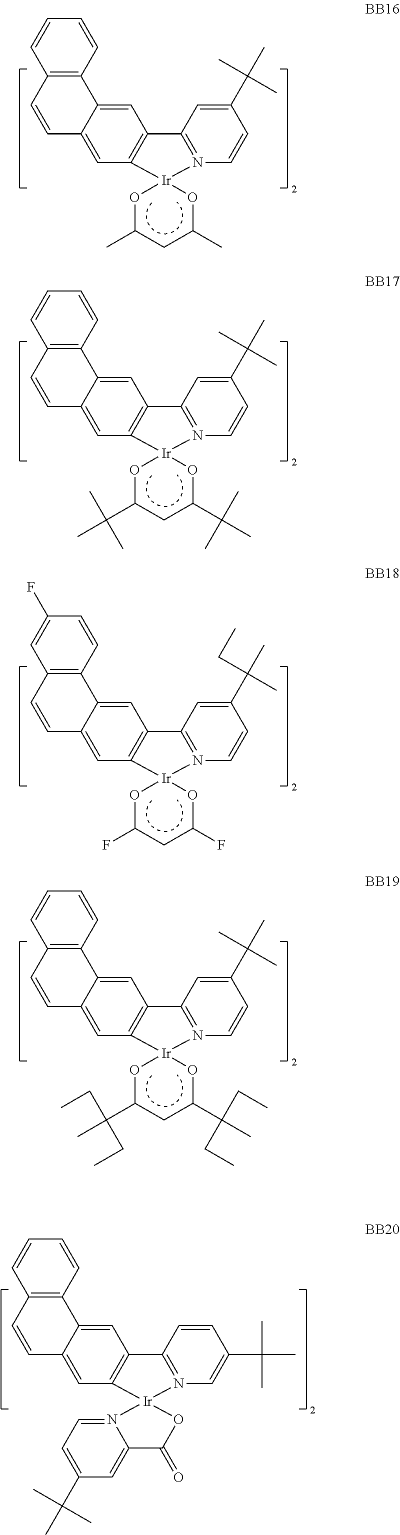

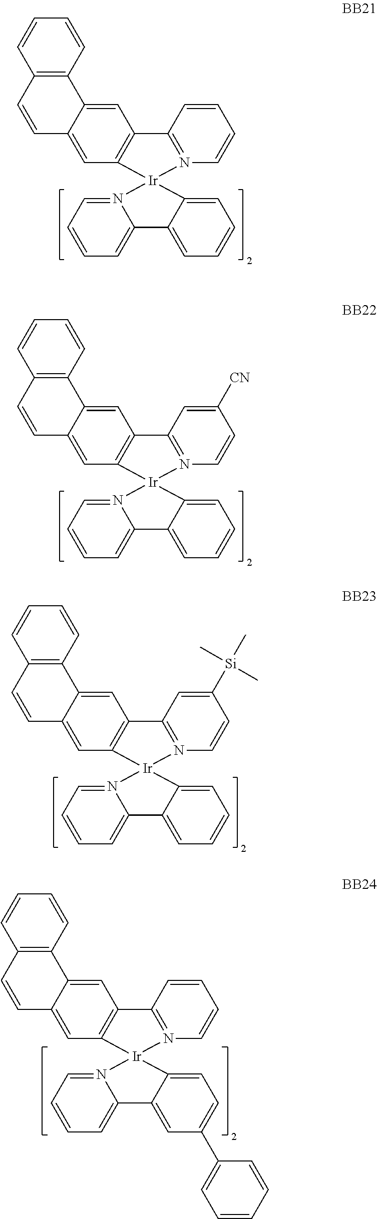

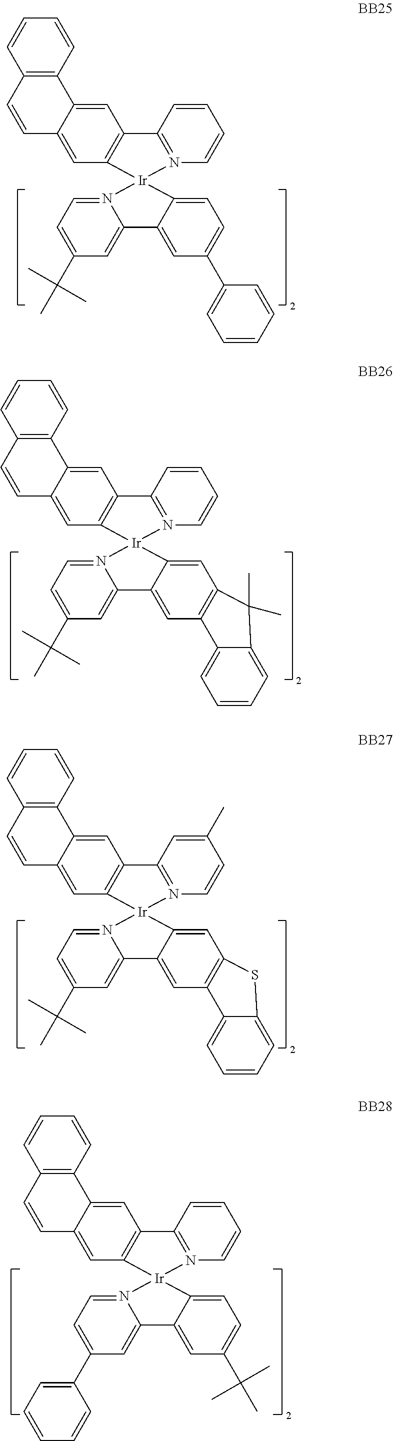

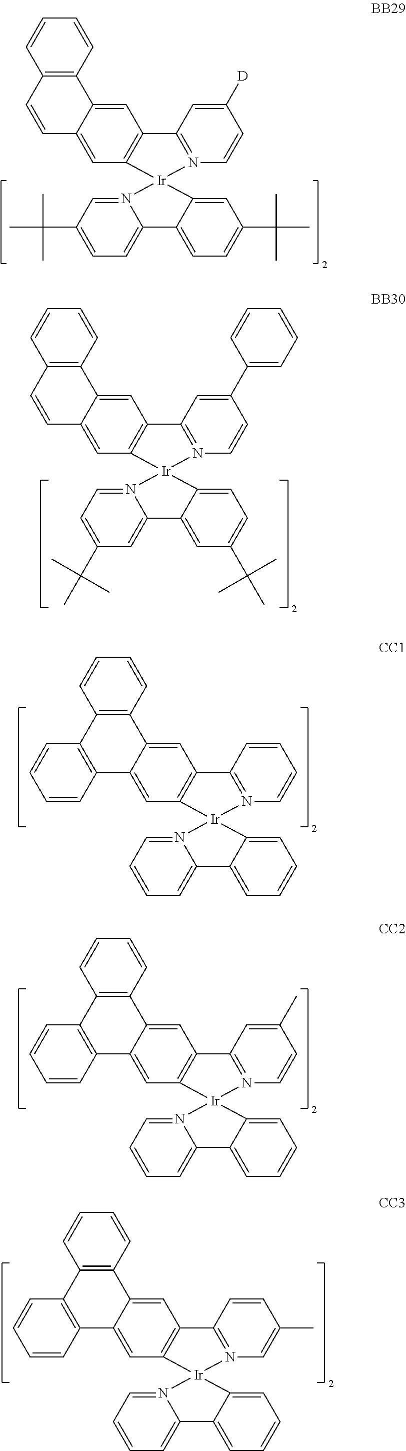

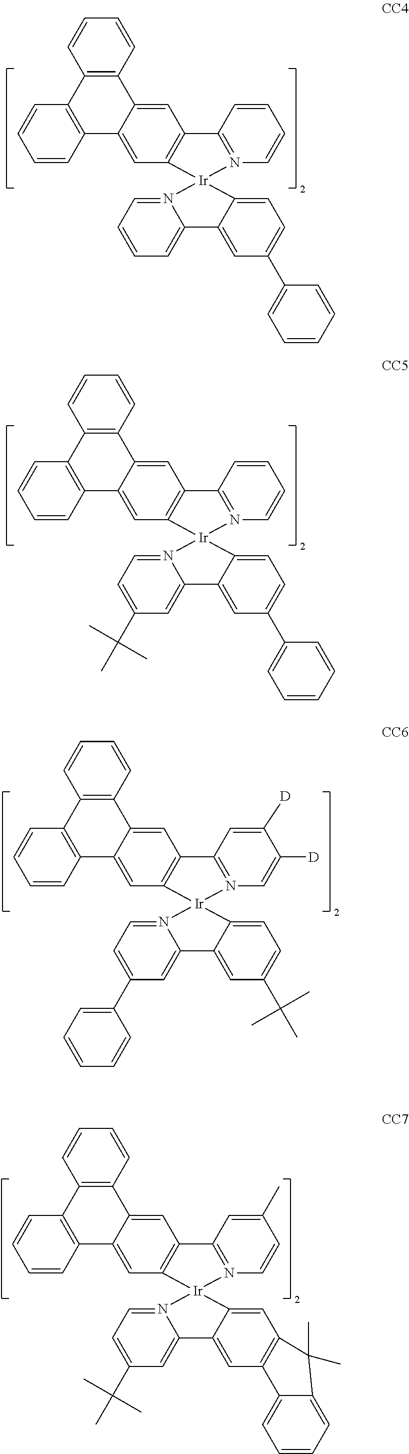

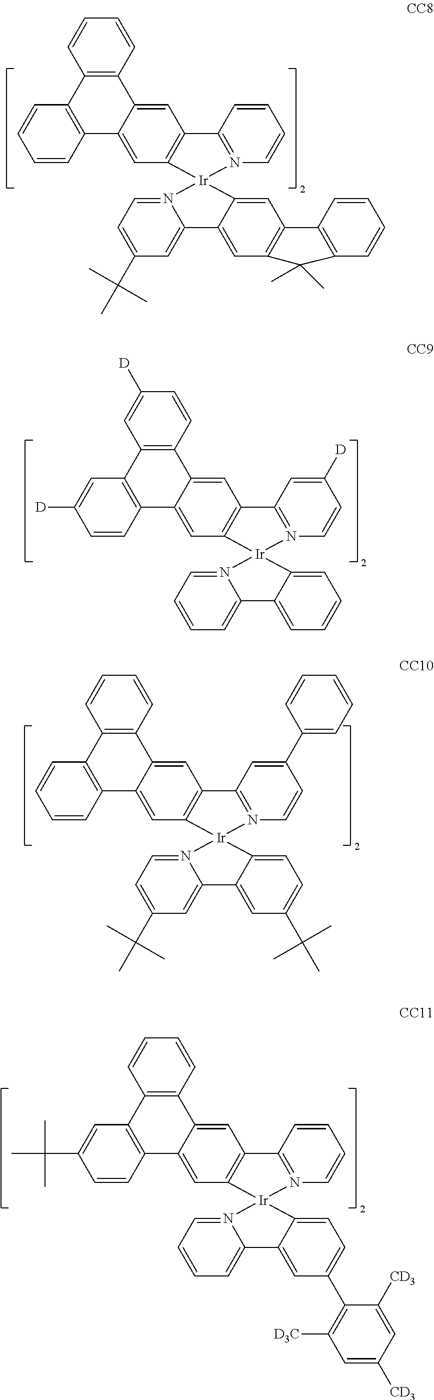

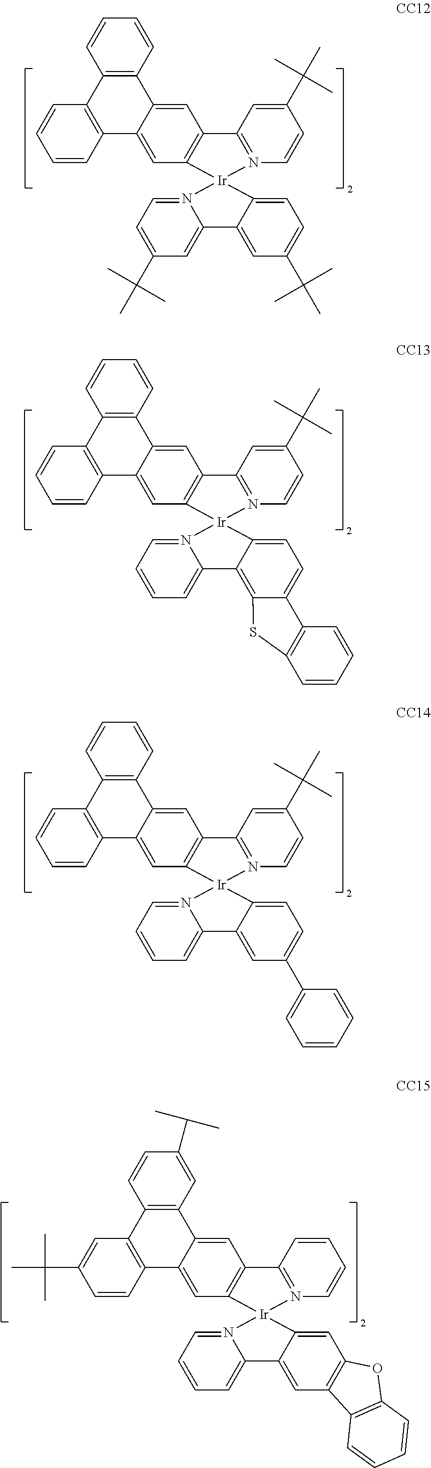

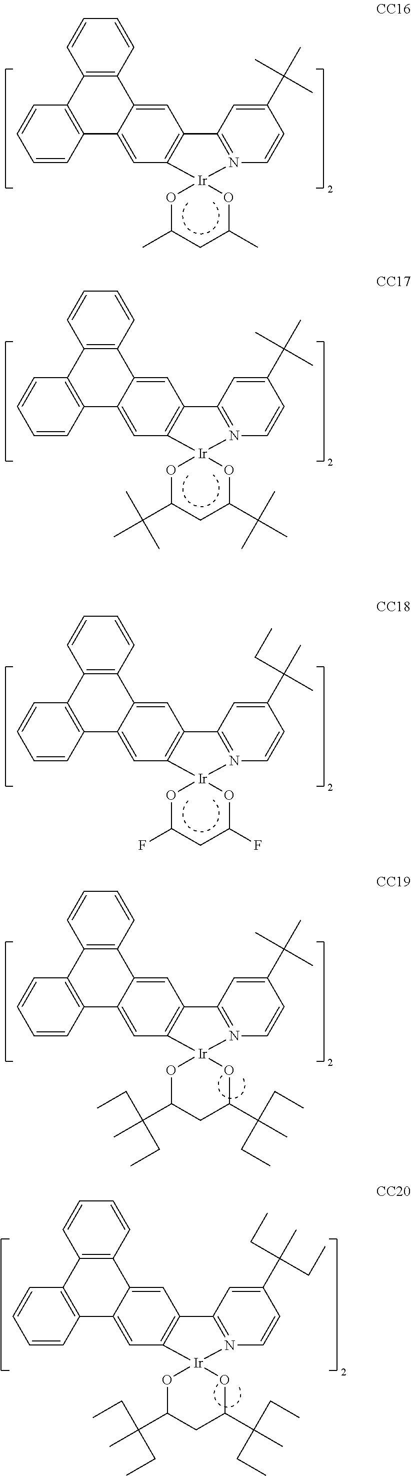

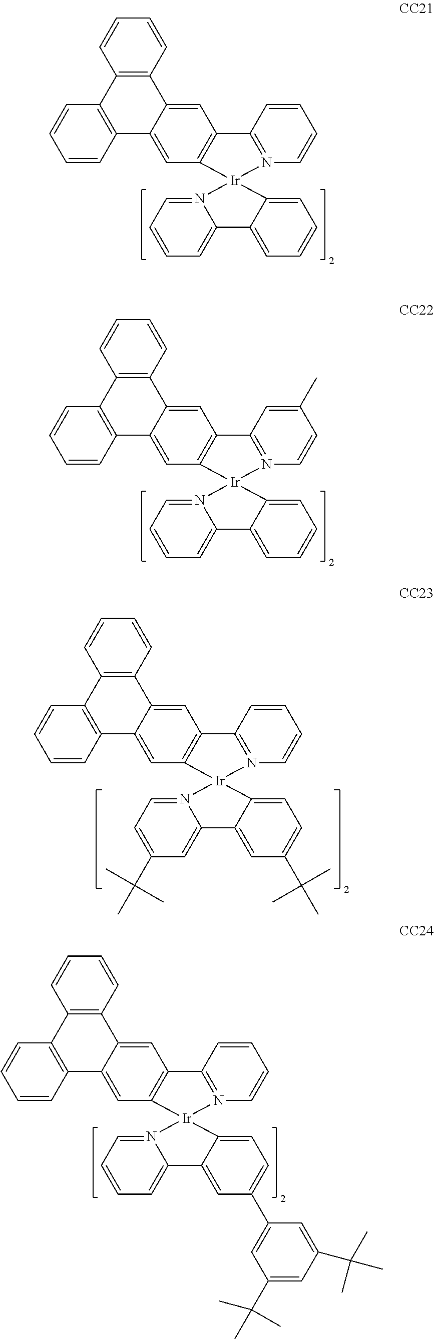

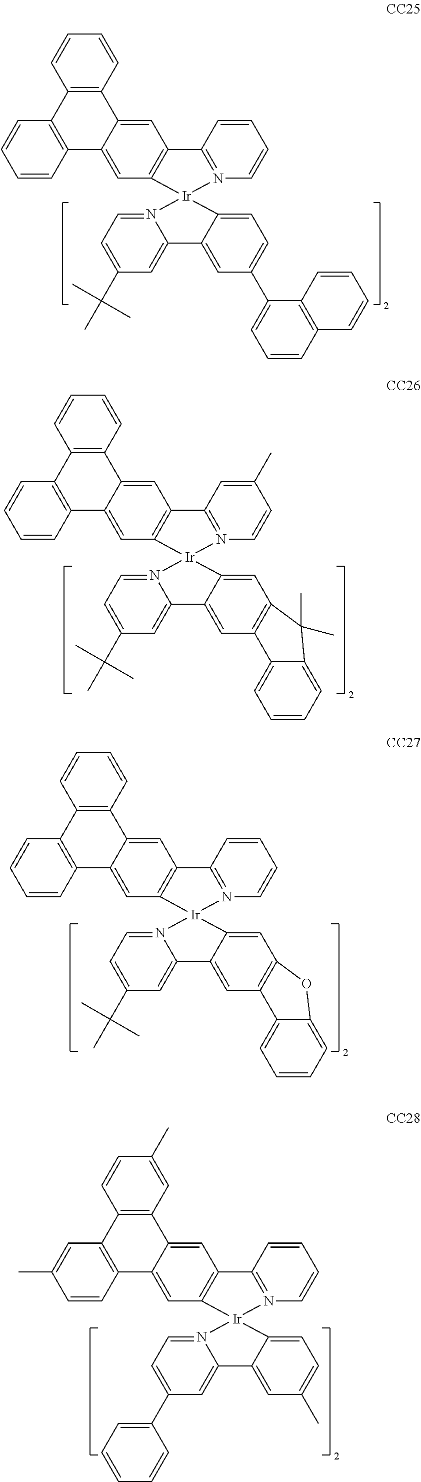

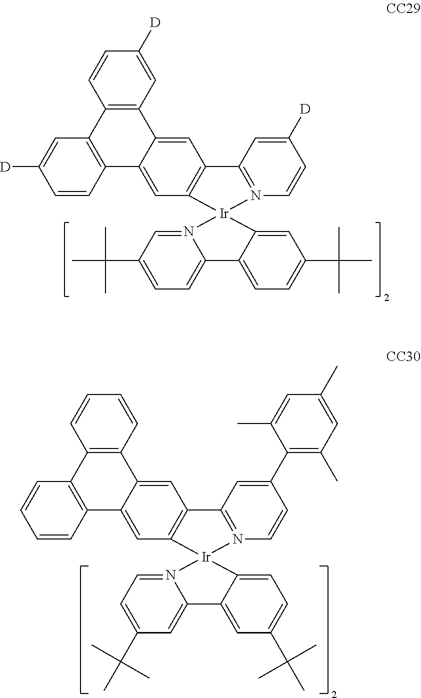

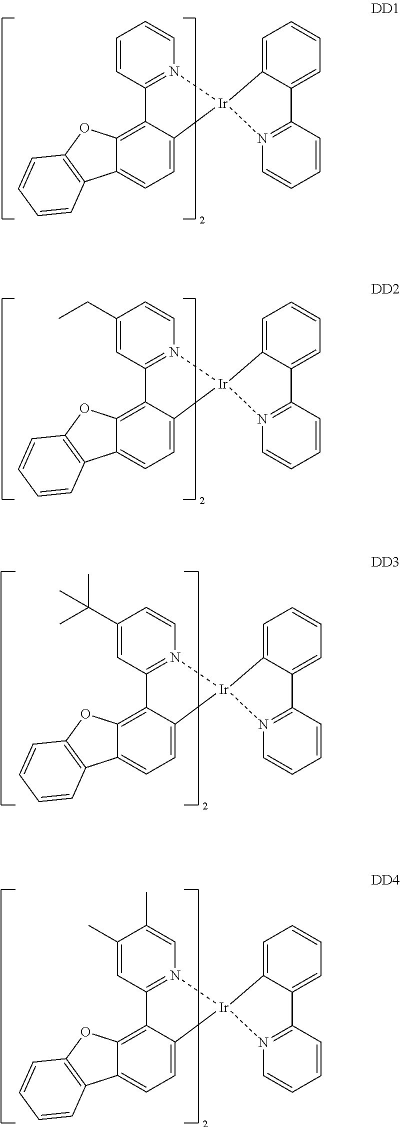

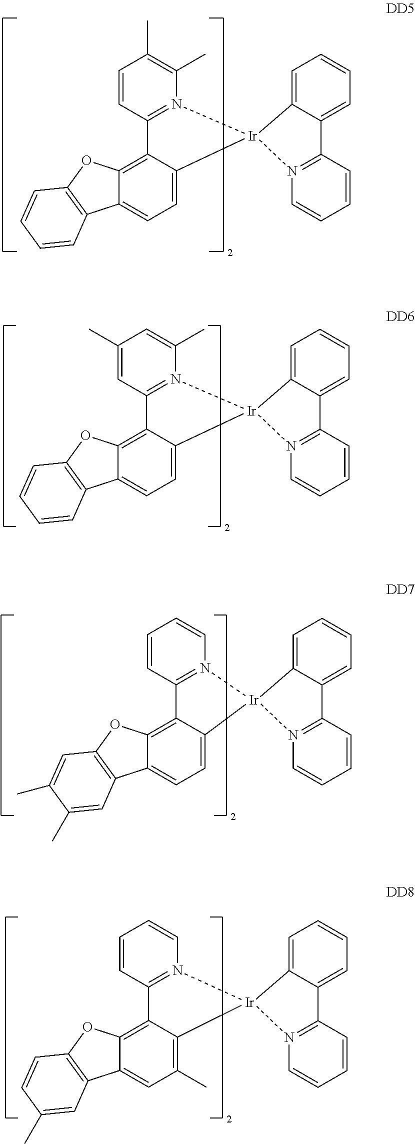

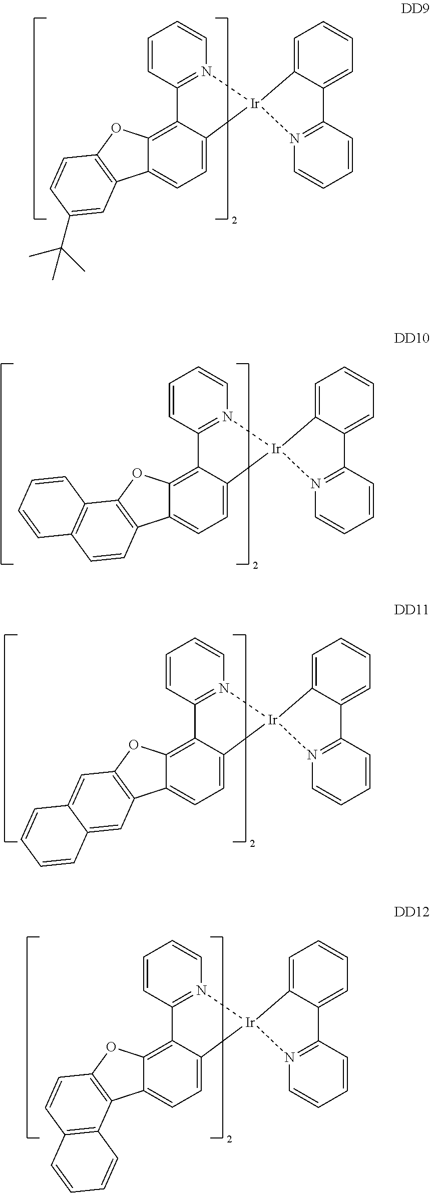

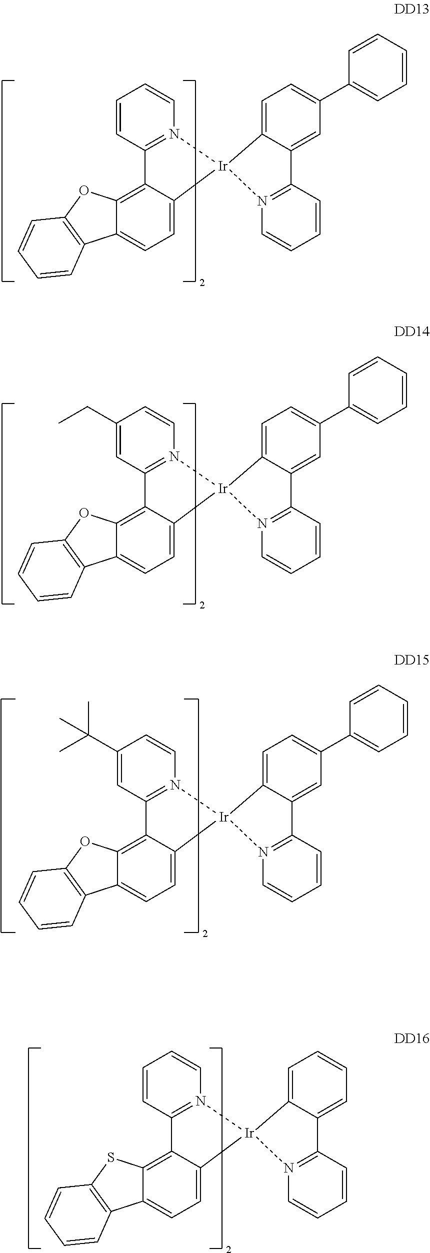

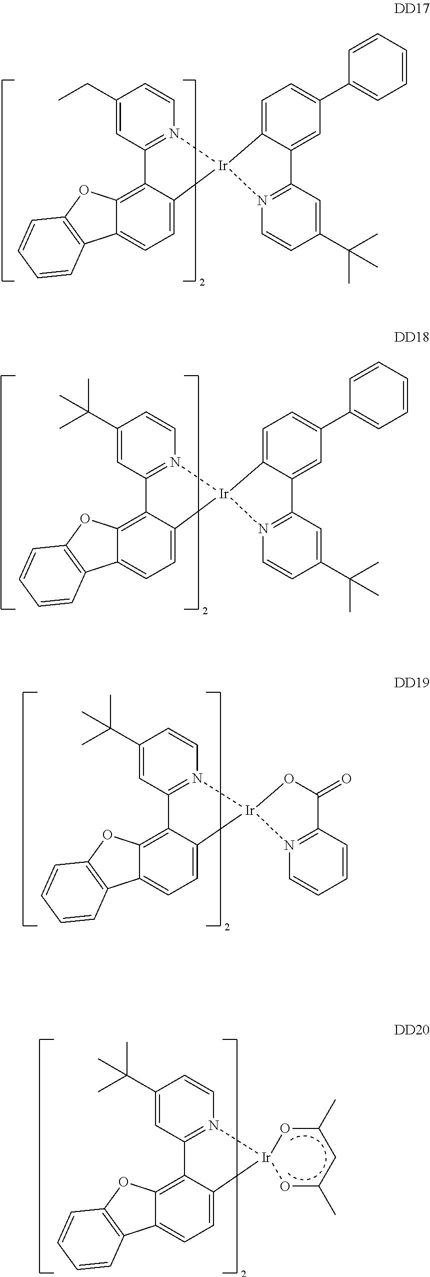

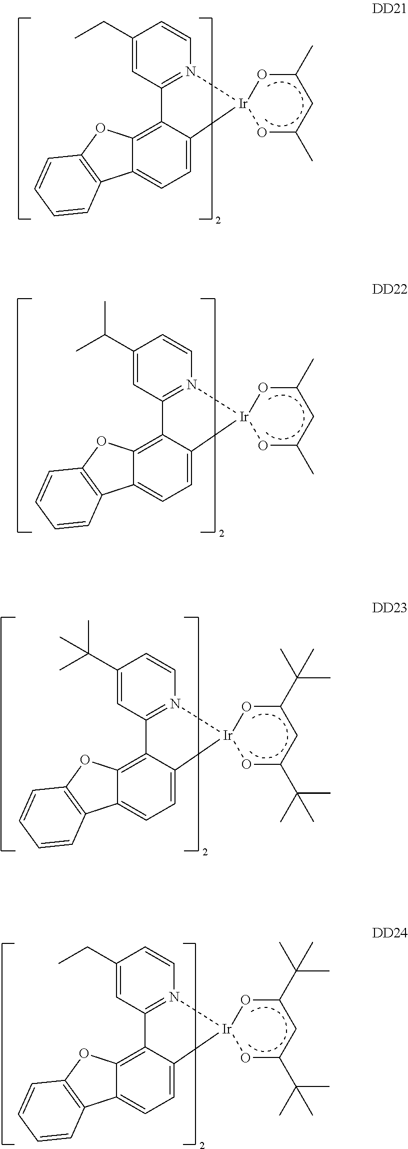

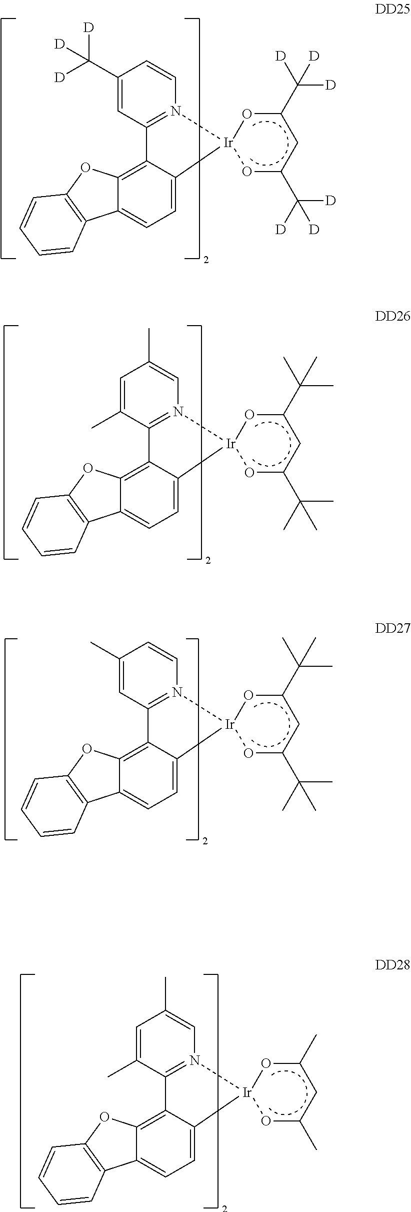

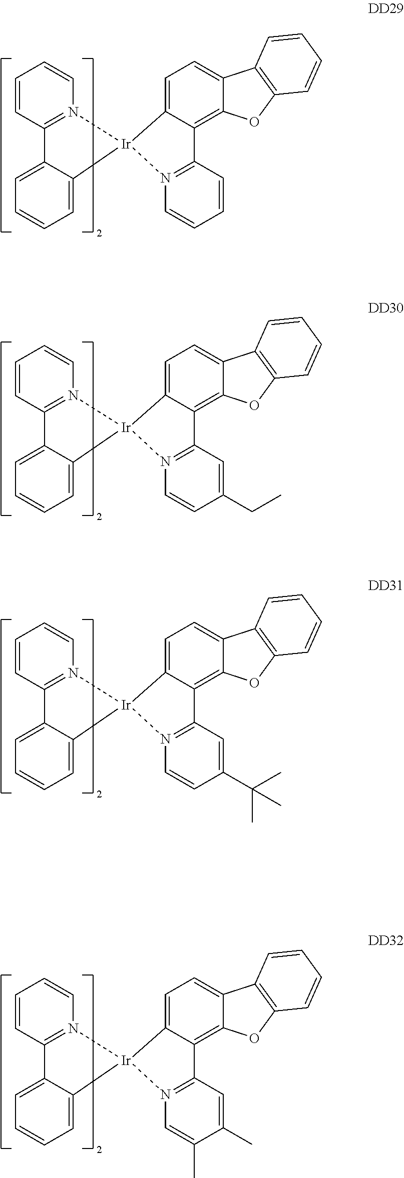

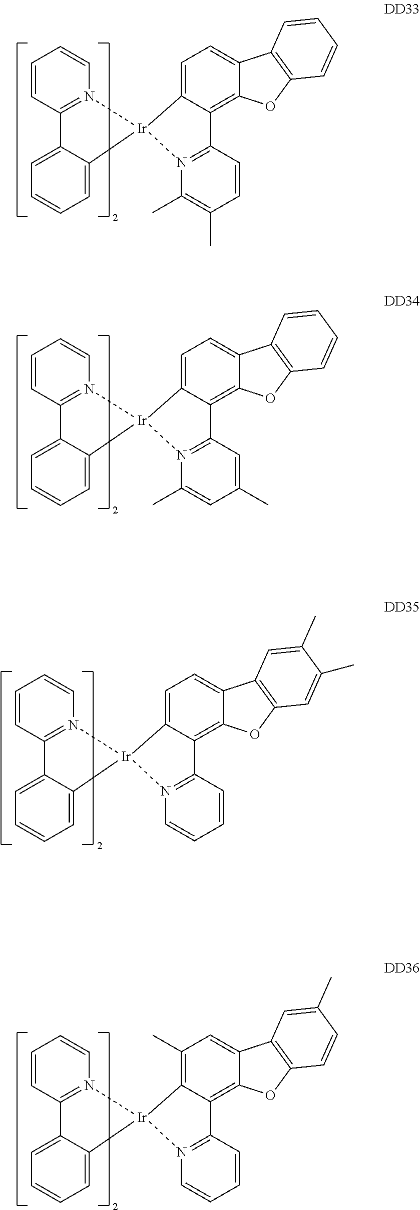

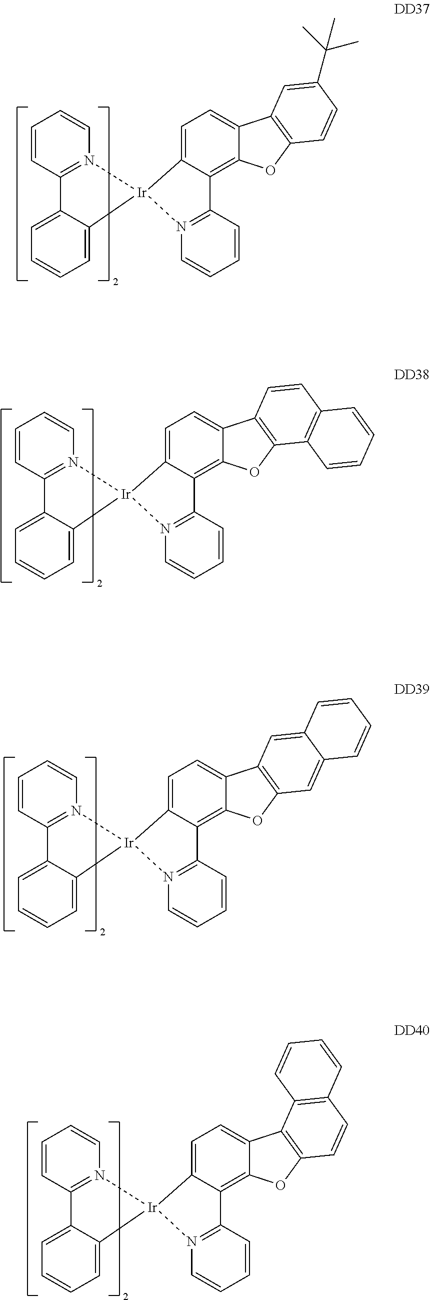

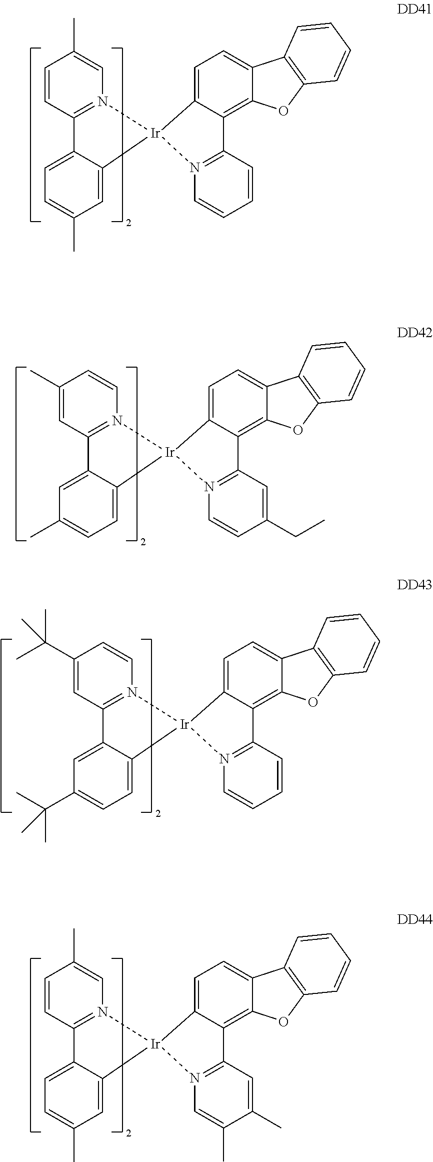

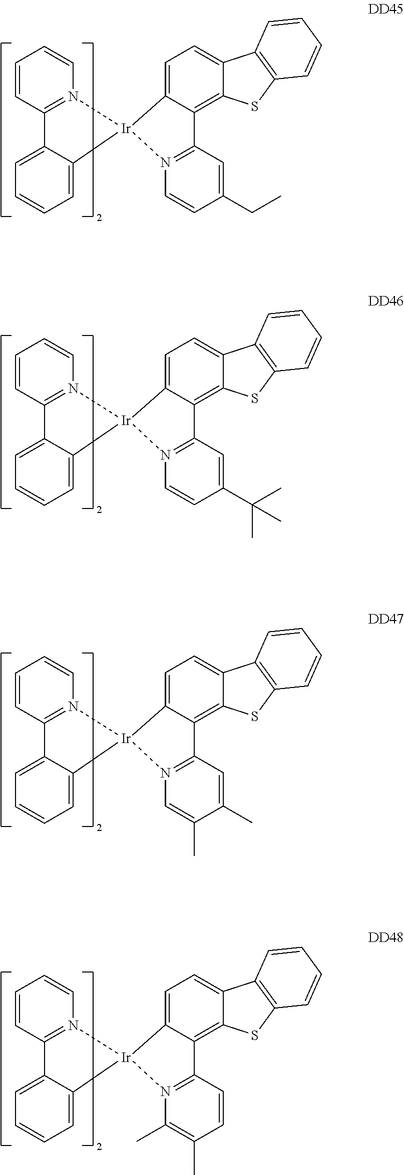

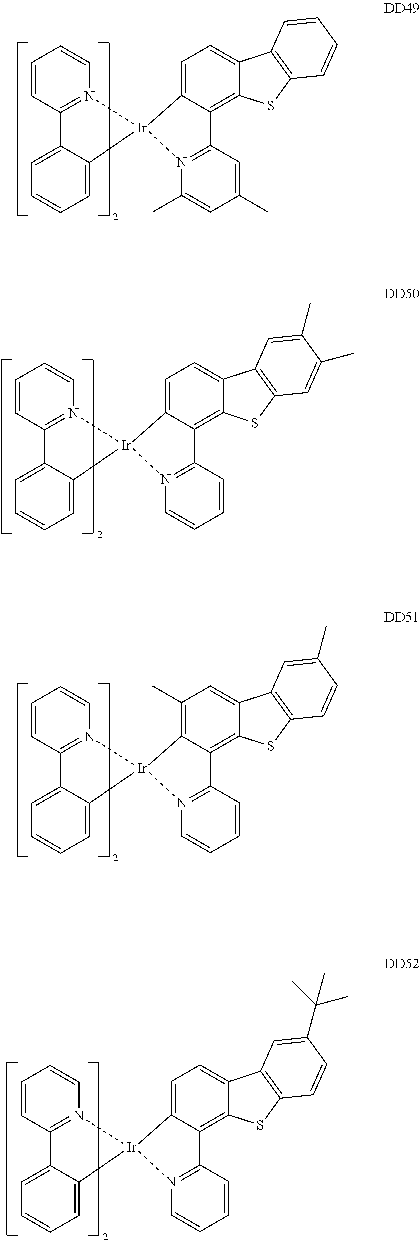

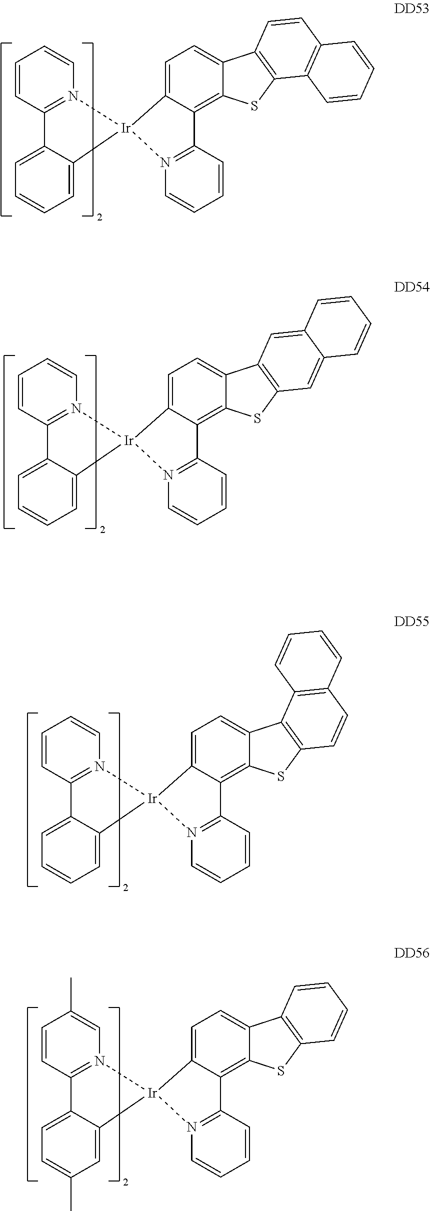

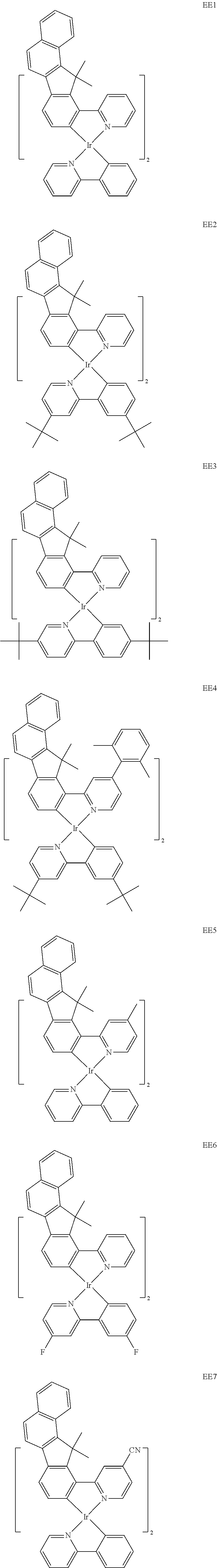

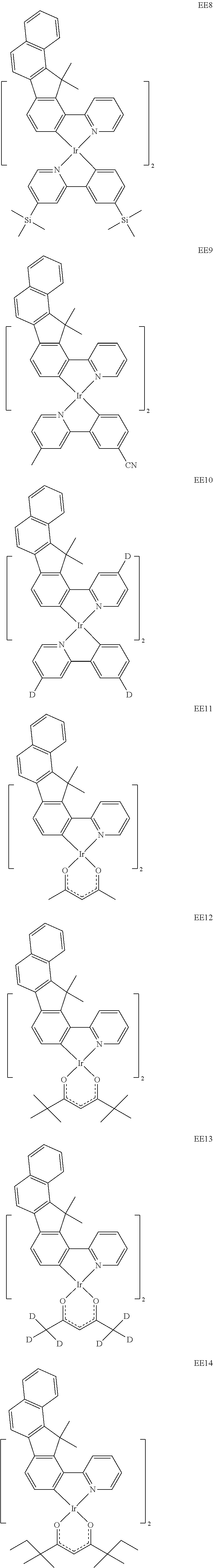

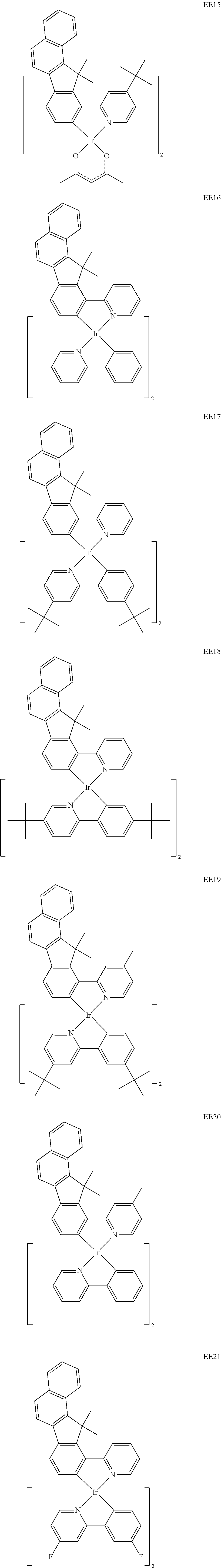

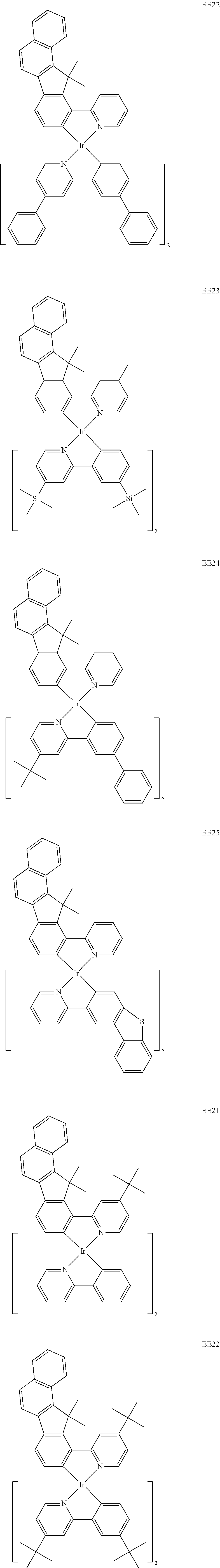

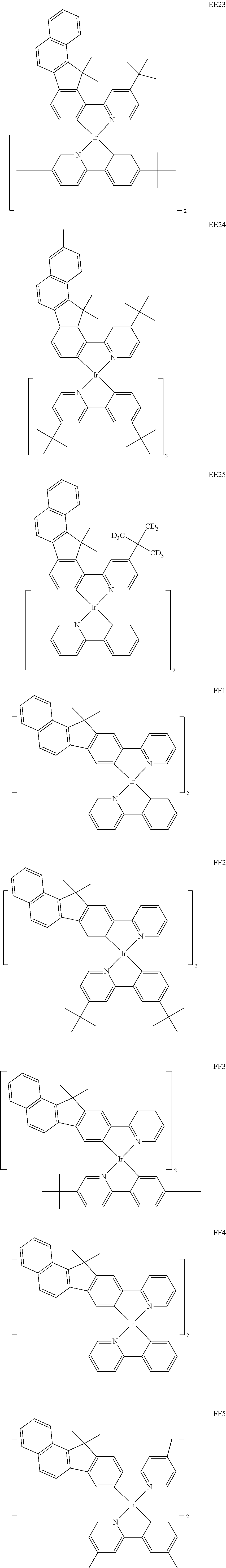

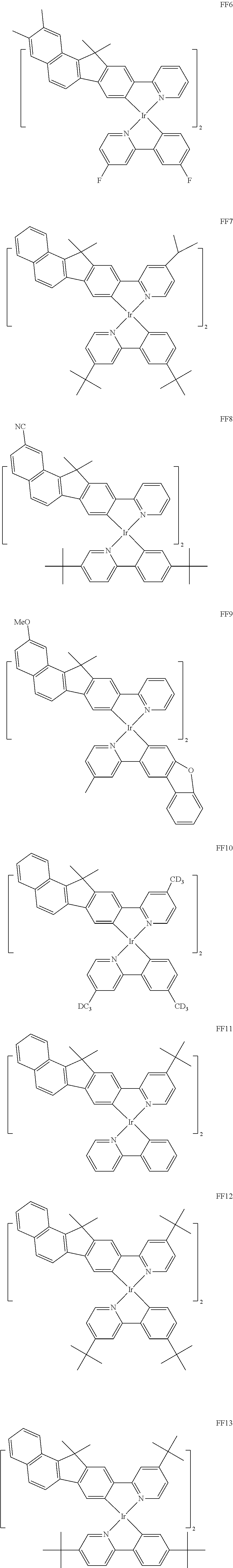

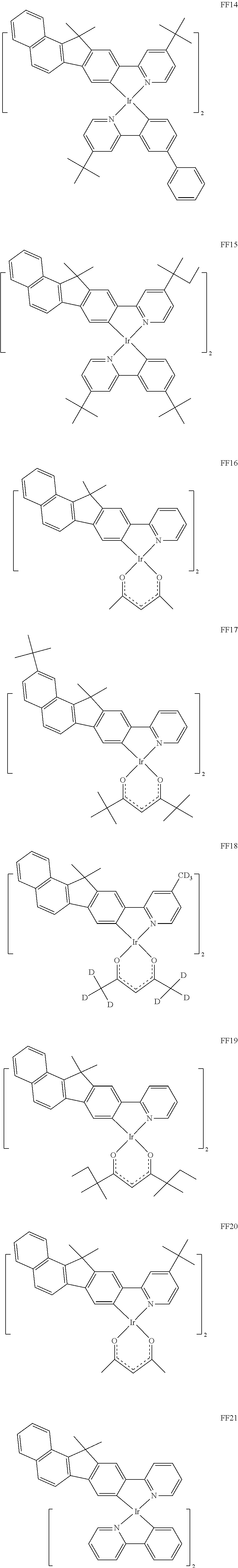

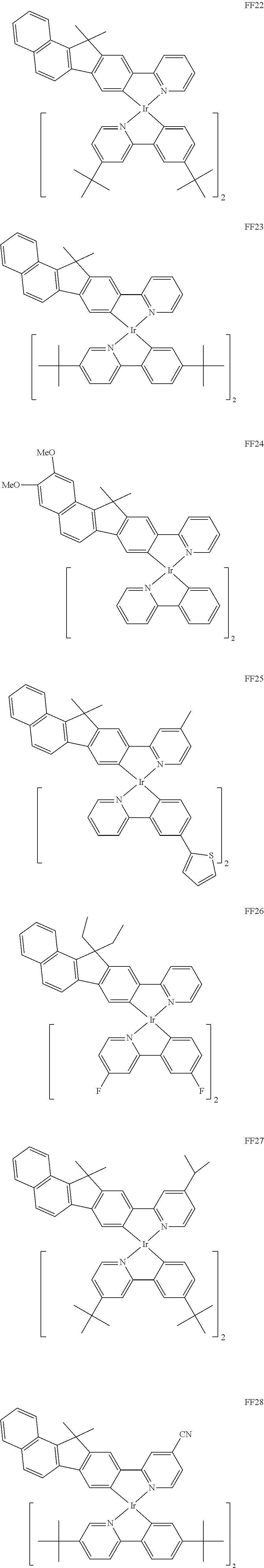

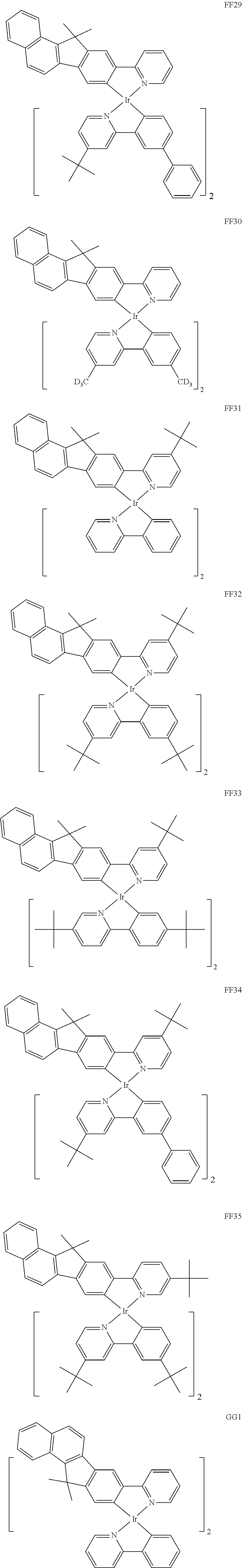

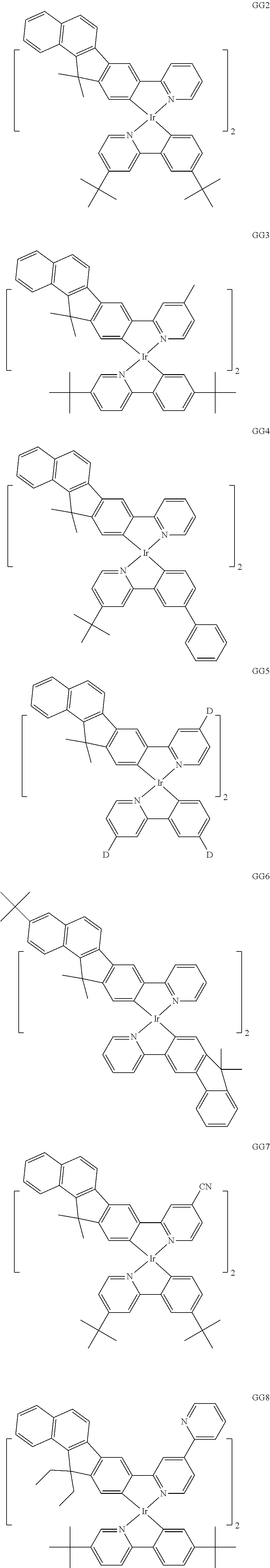

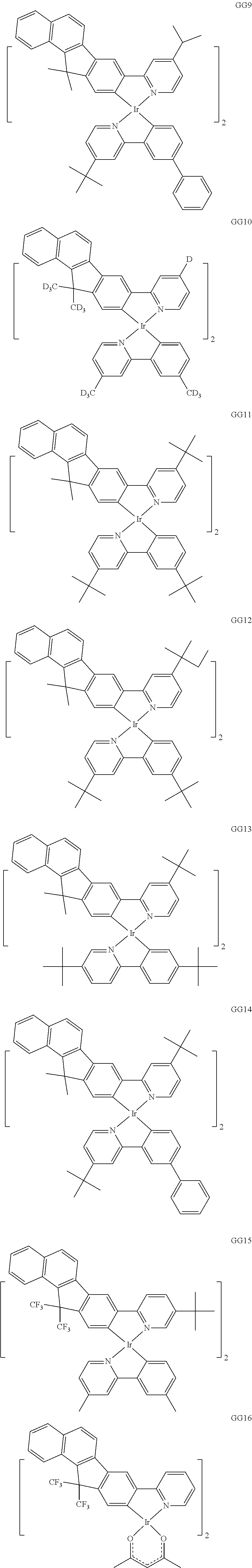

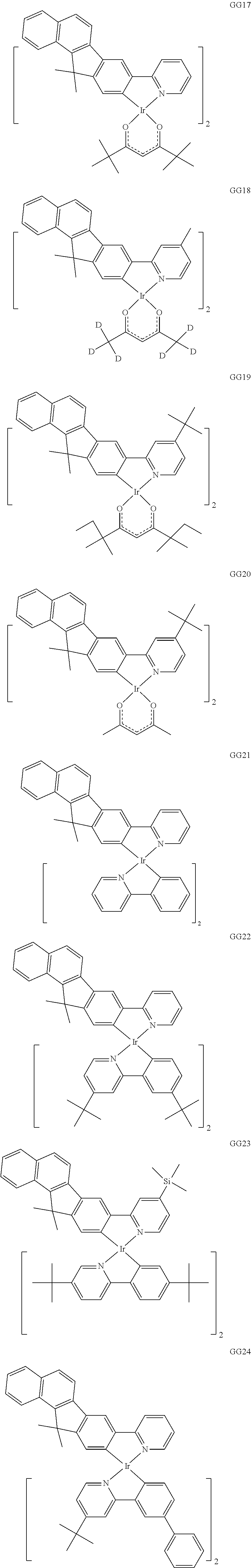

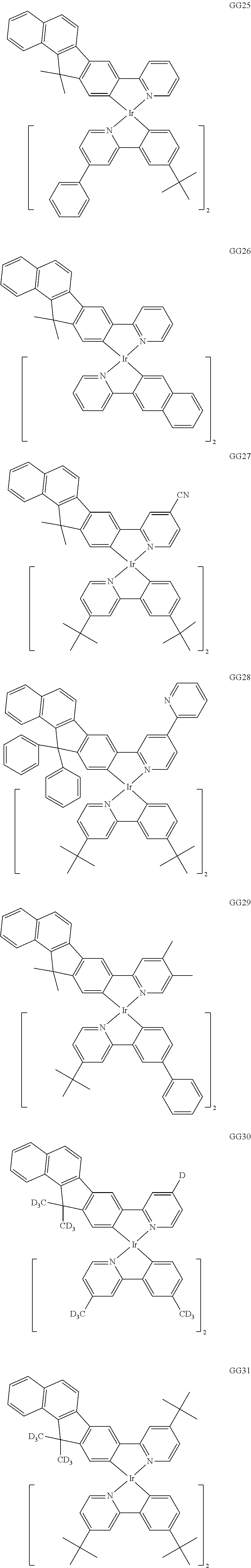

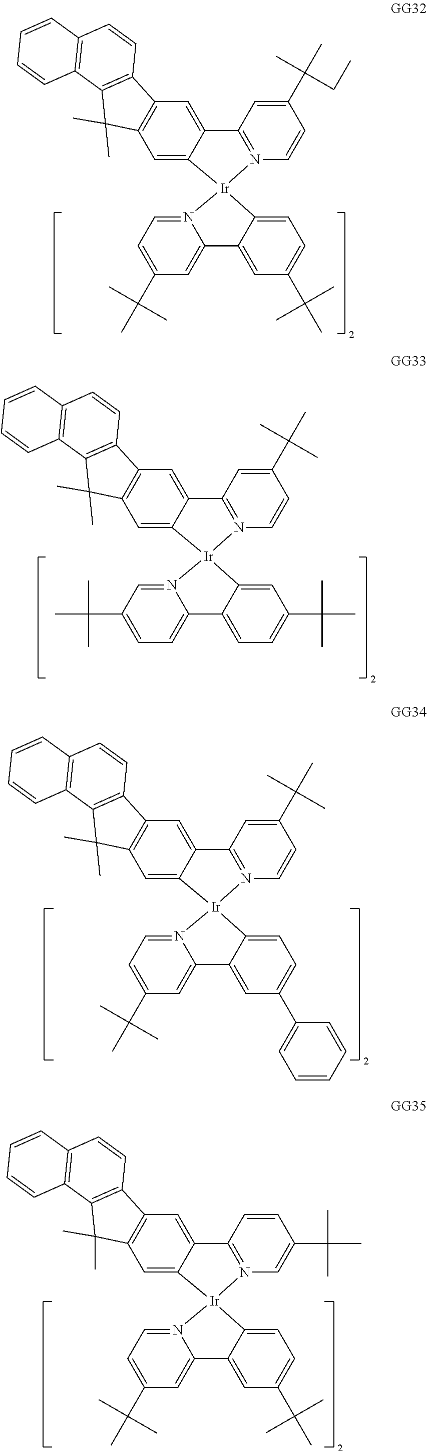

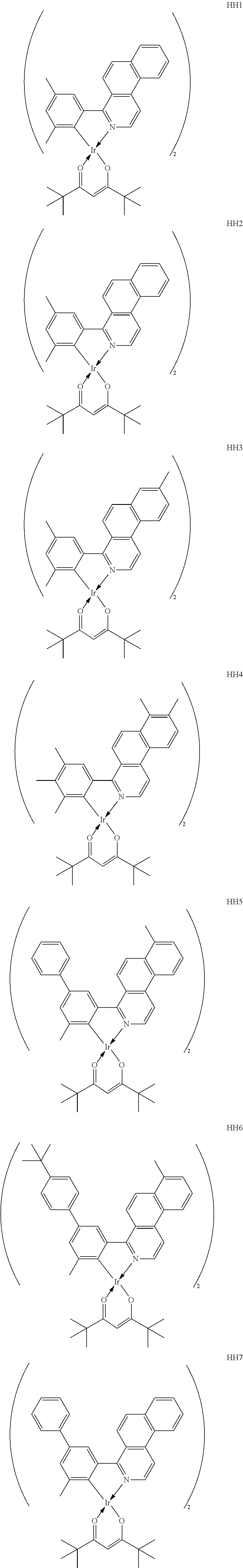

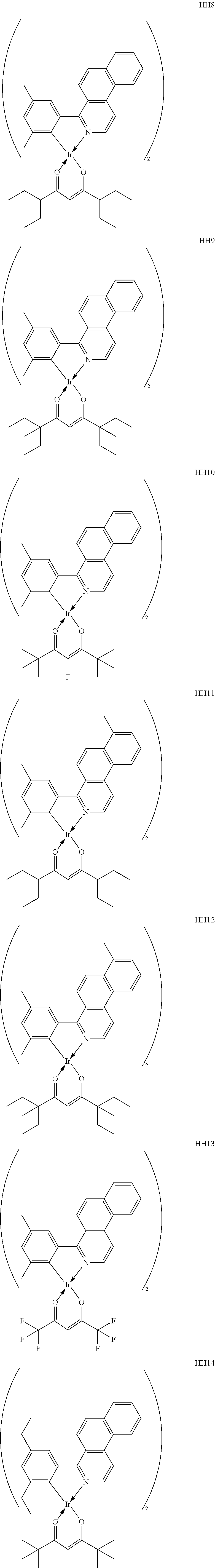

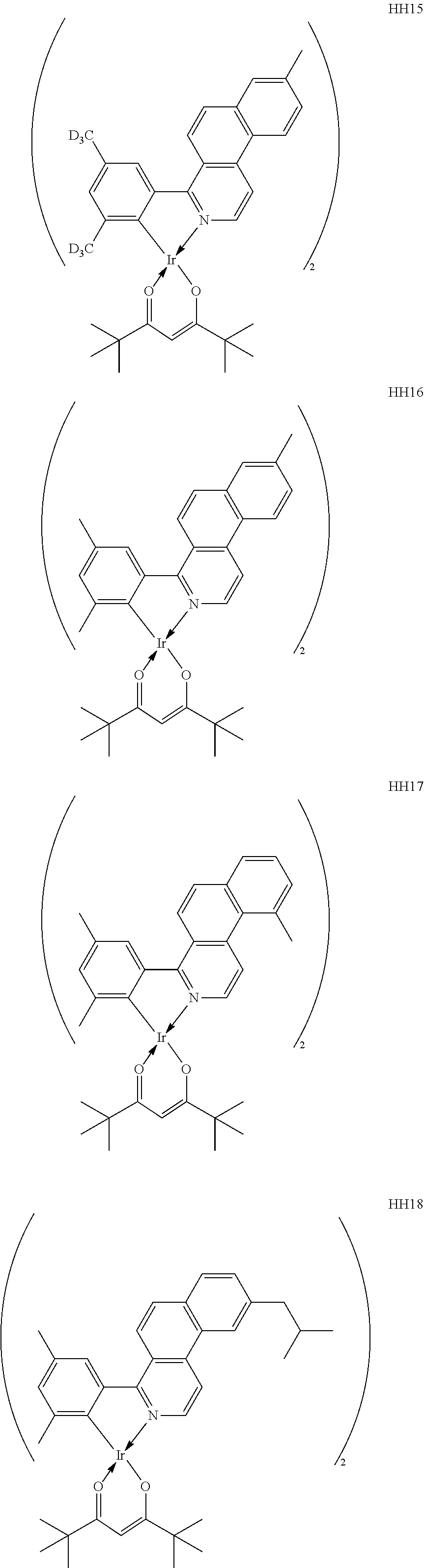

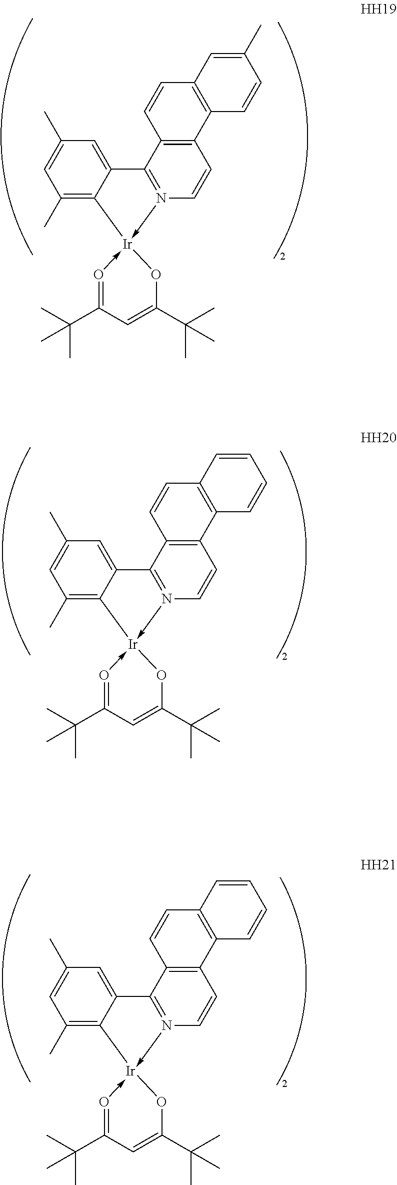

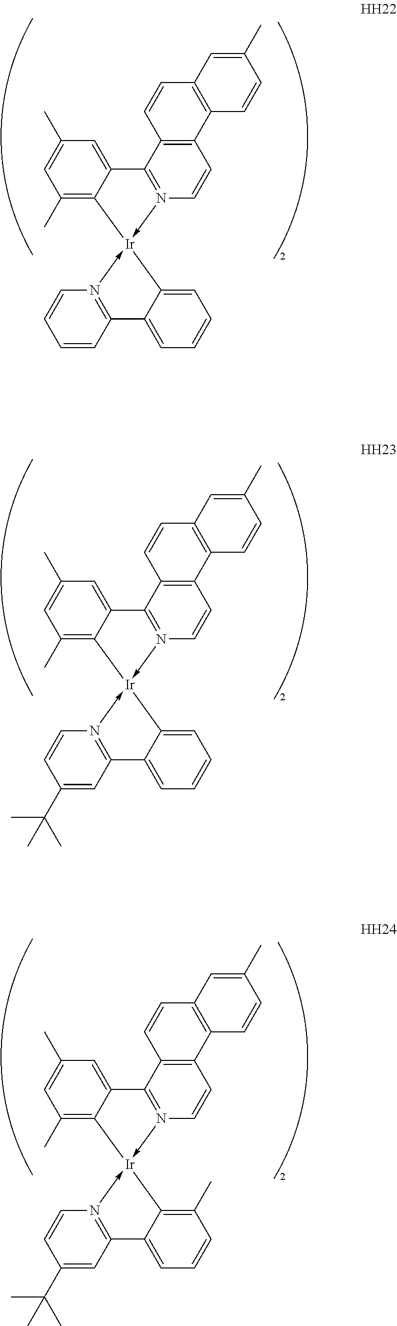

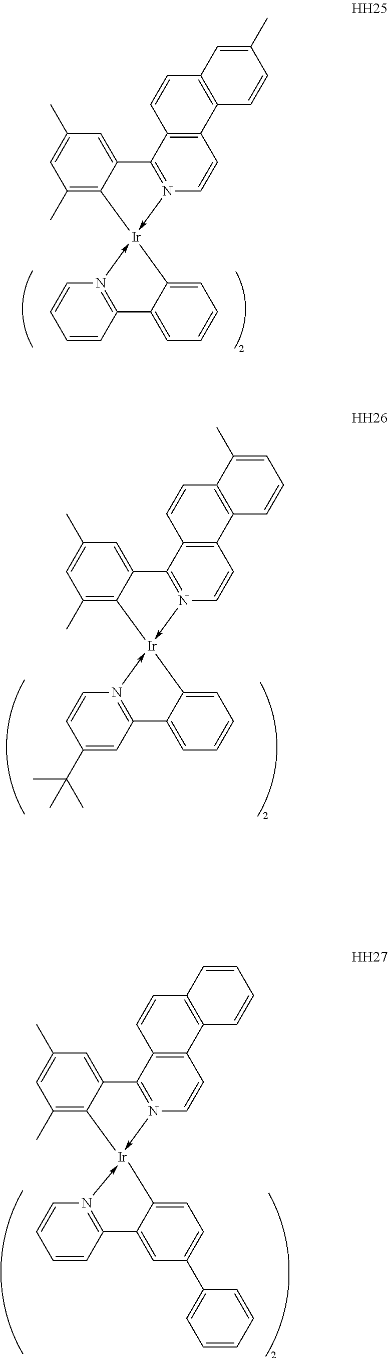

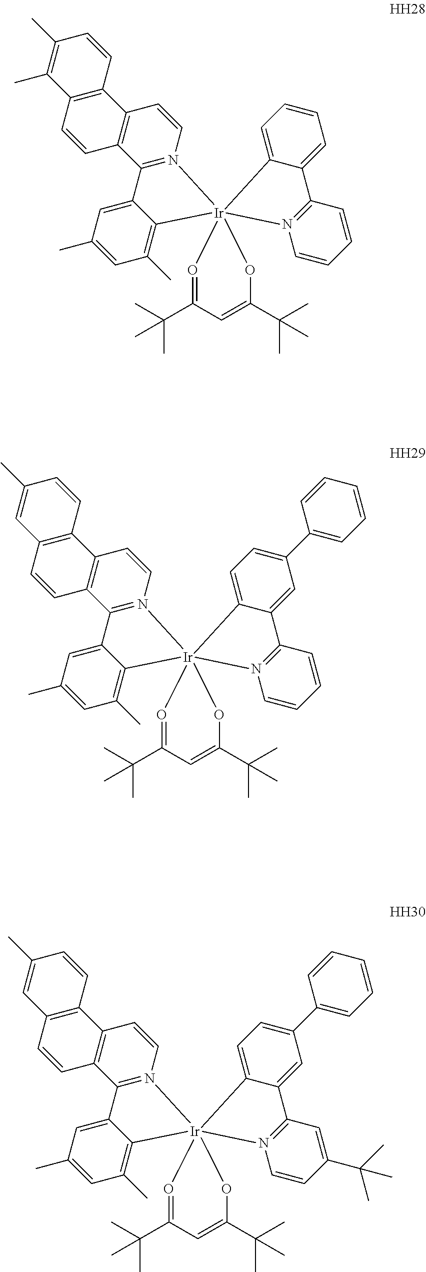

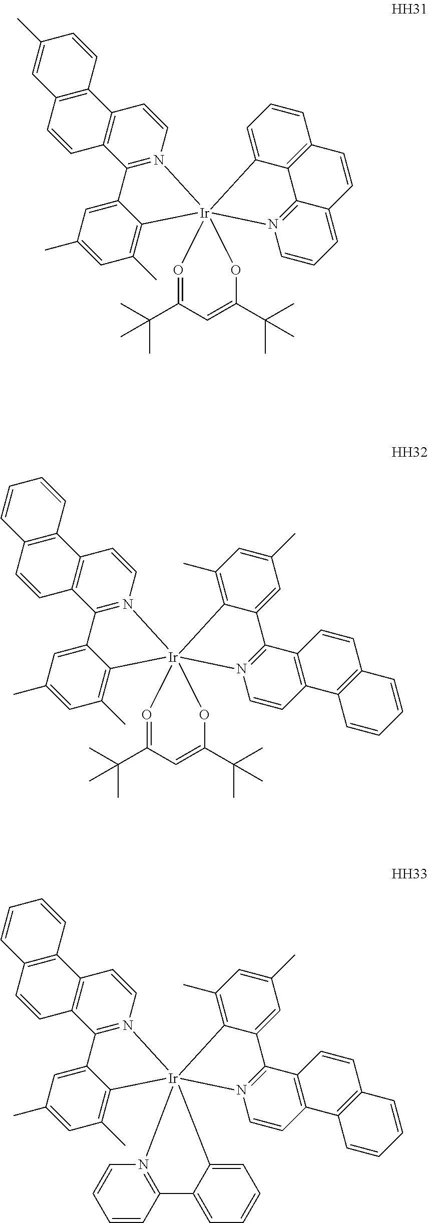

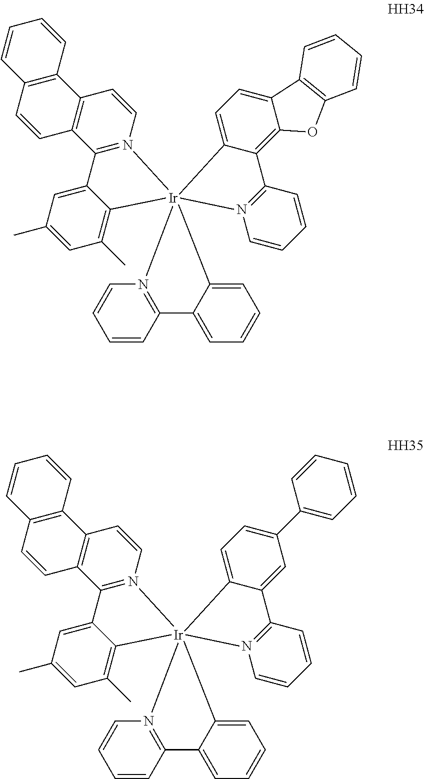

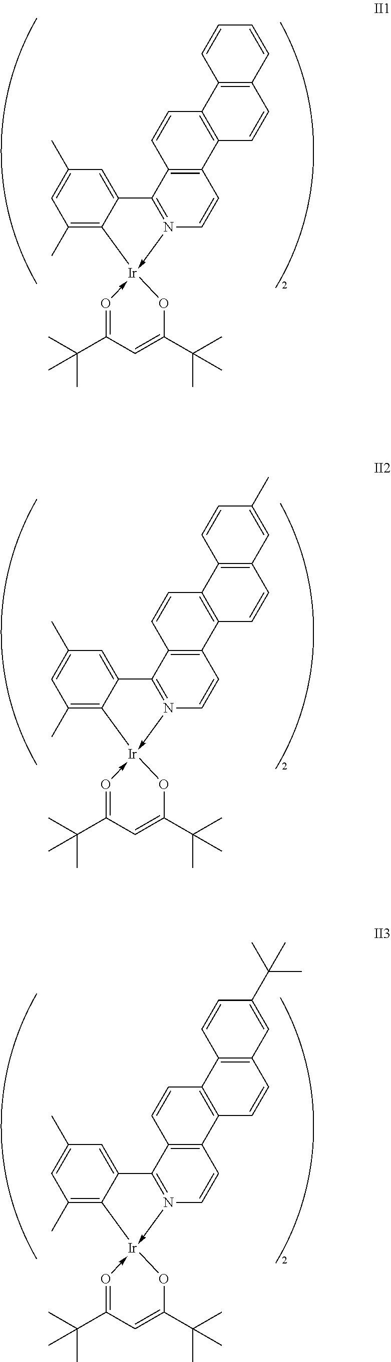

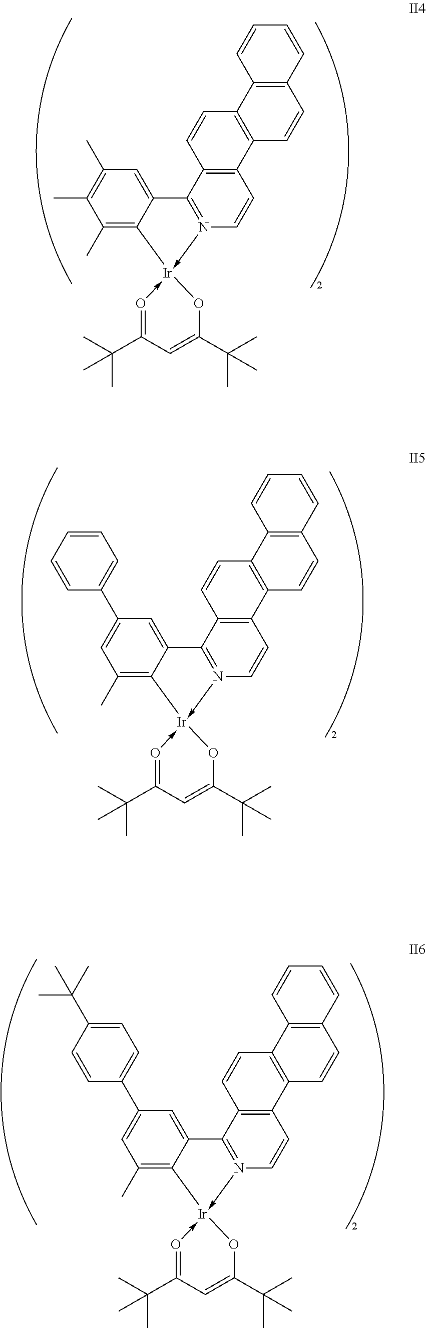

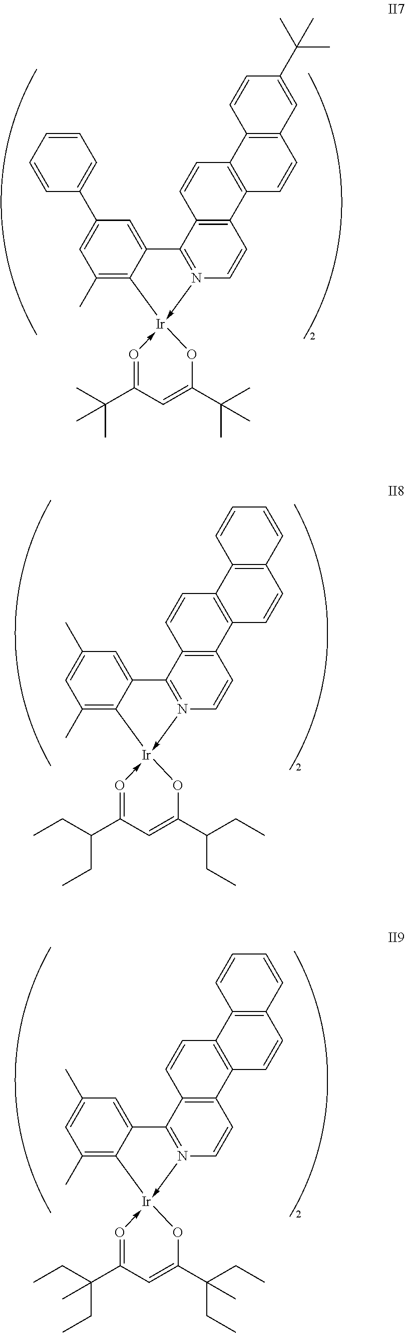

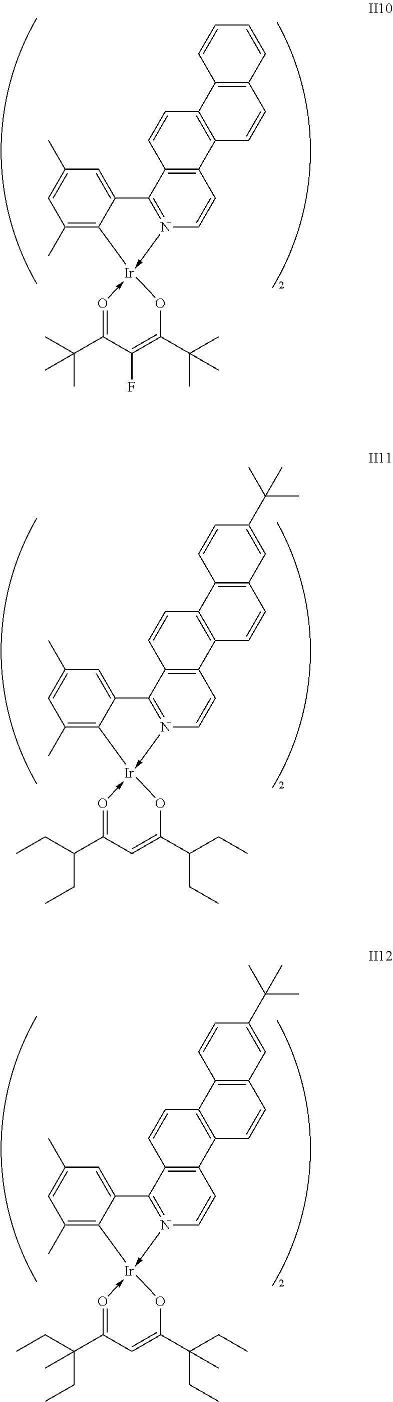

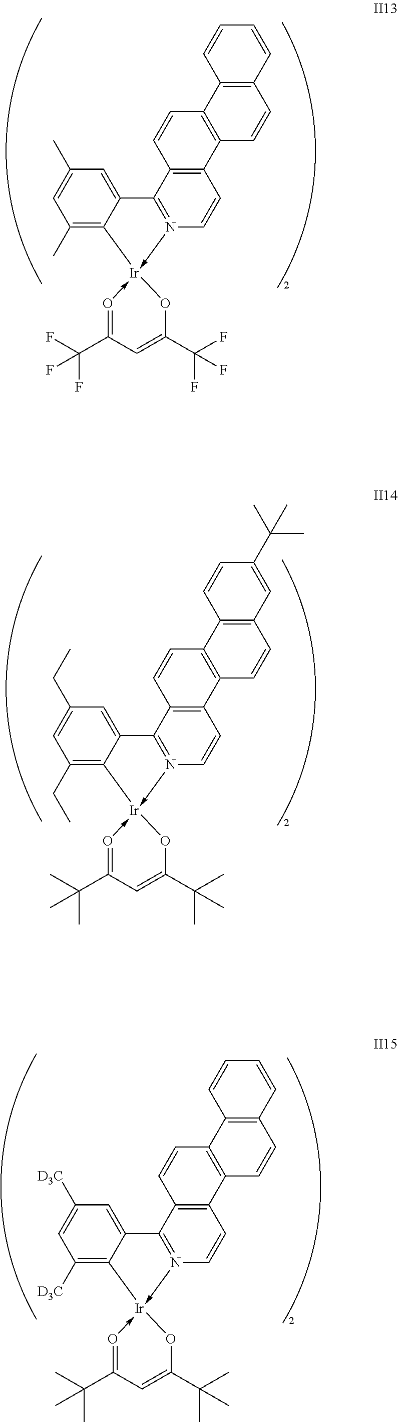

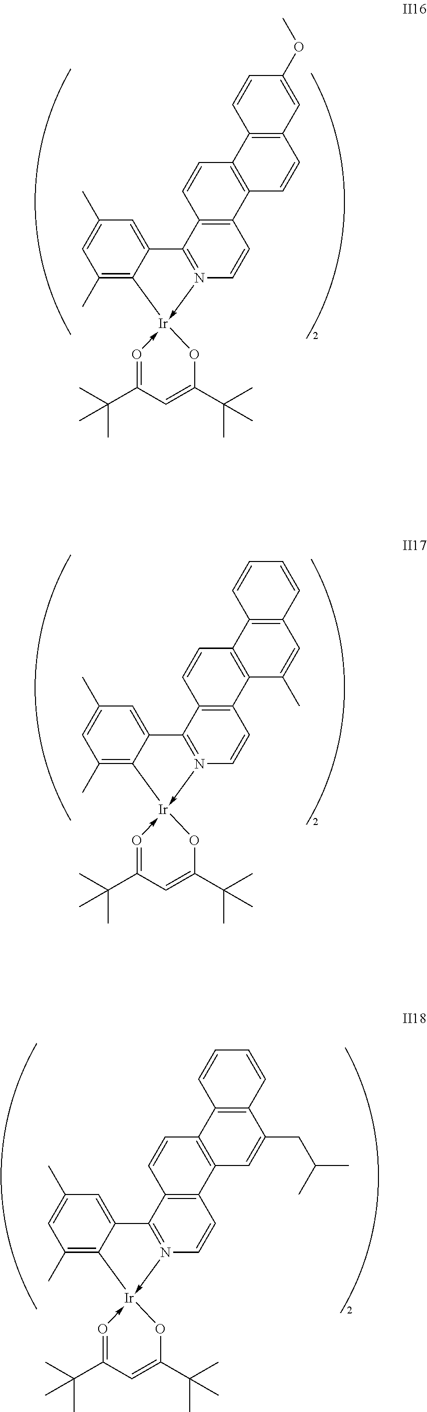

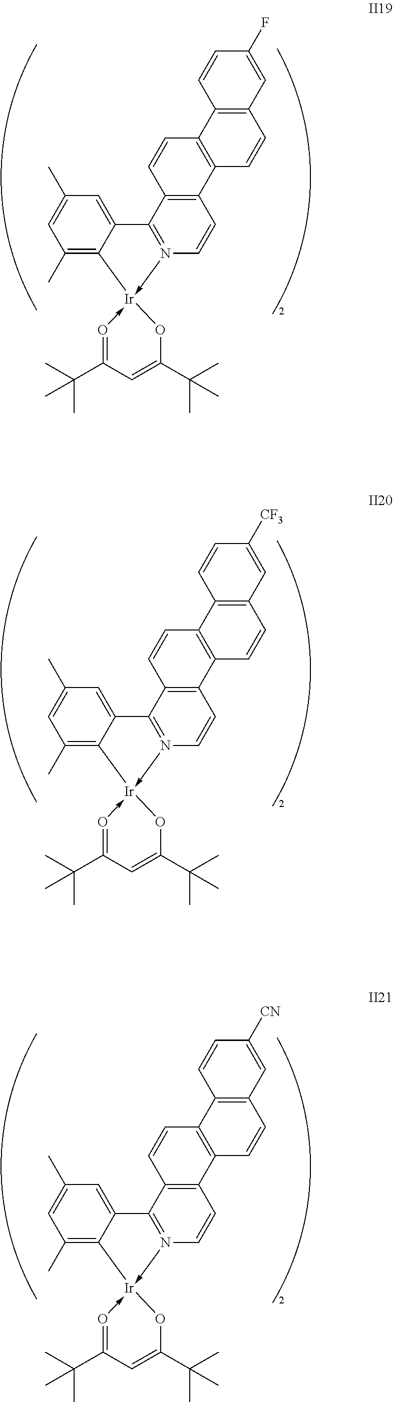

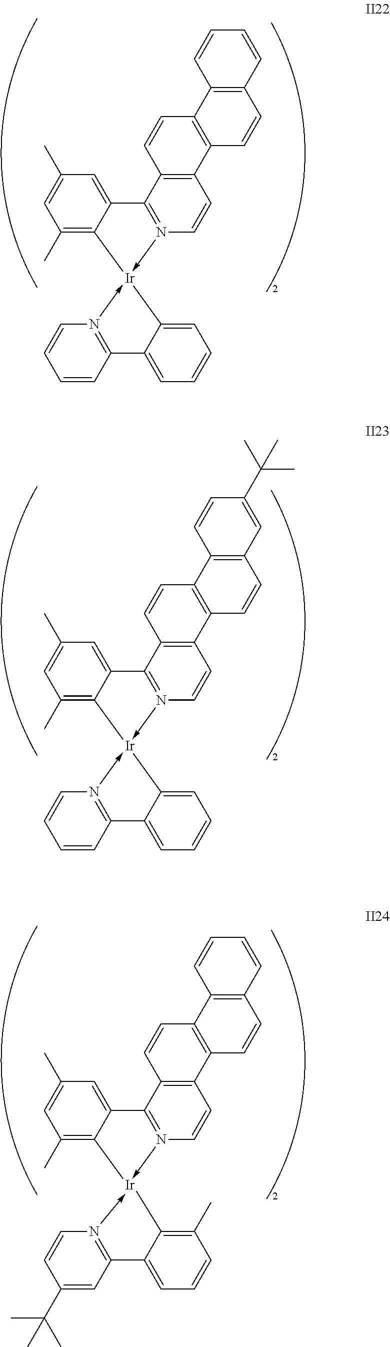

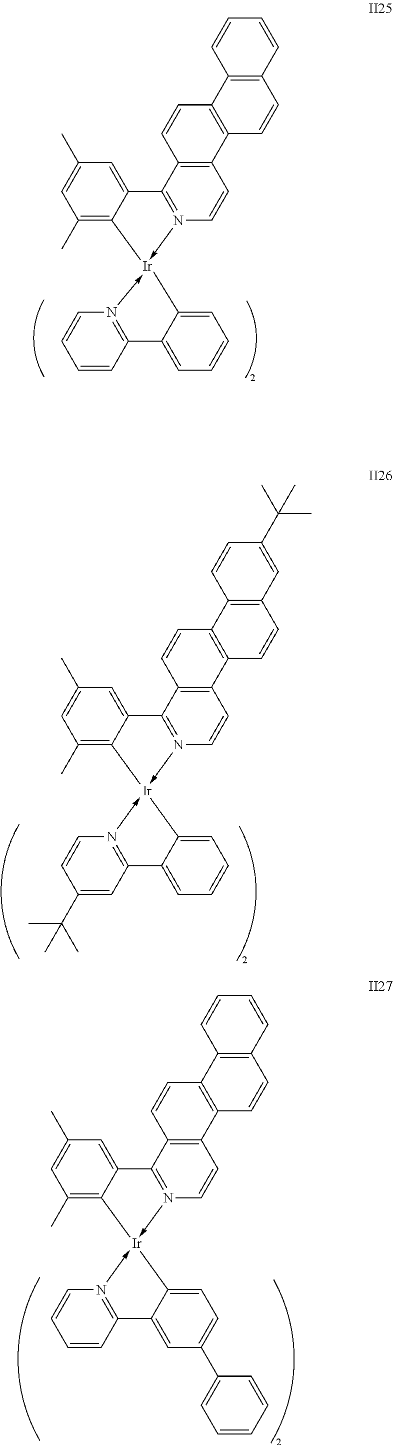

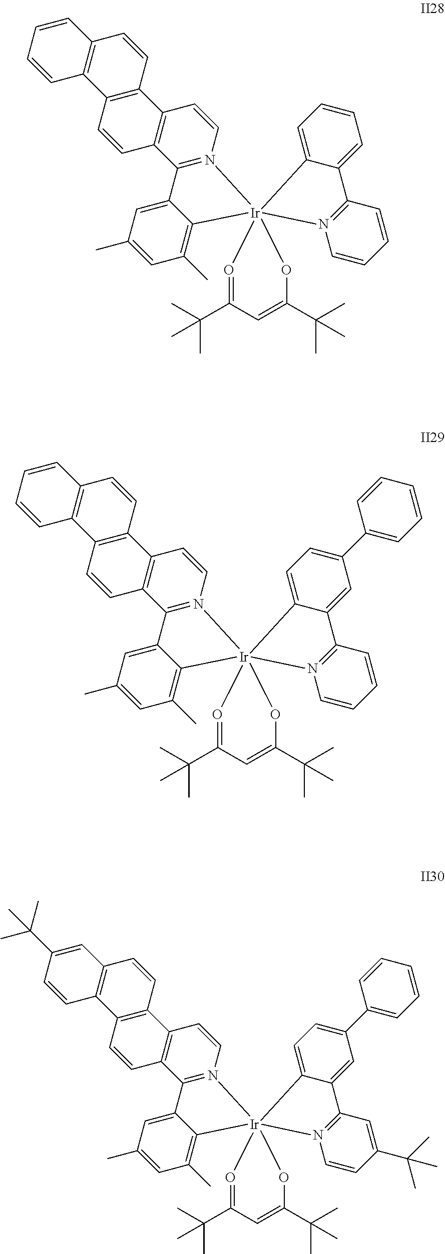

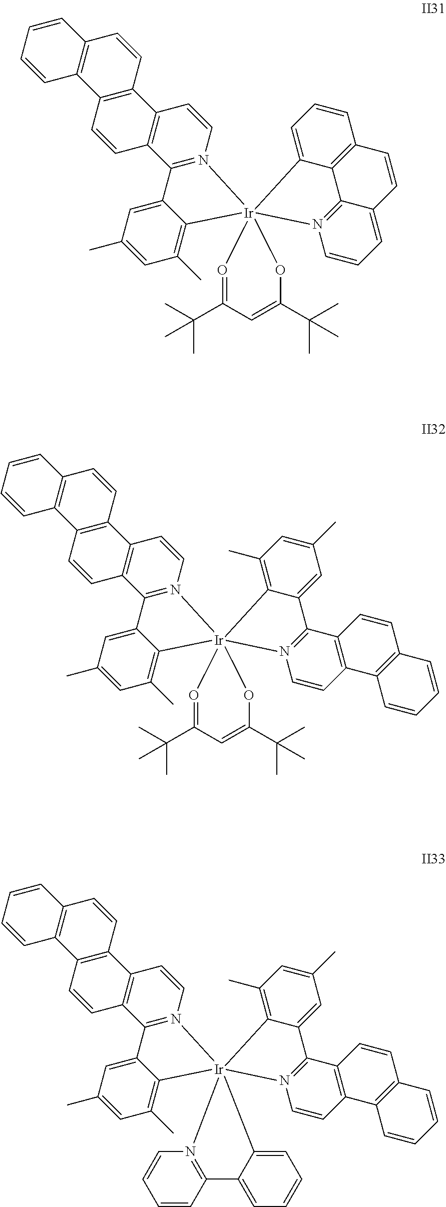

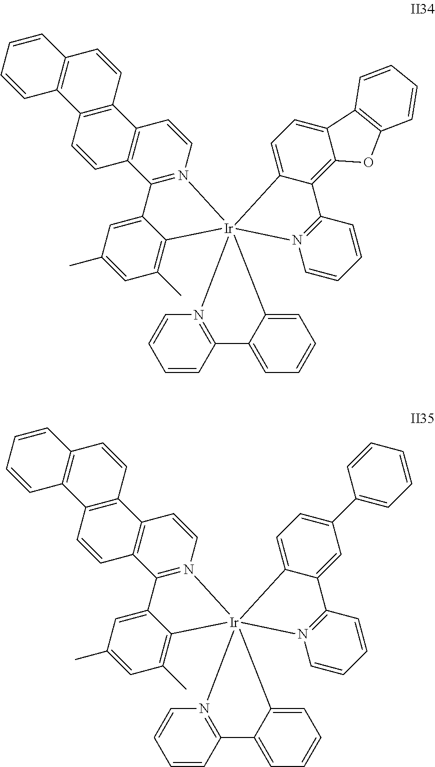

Exemplified compounds belonging to group AA to group BB are metal complexes each having the partial structure M (L)m represented by general formula [Ir-3], and are compounds each having a ligand containing at least a phenanthrene ring. These compounds are particularly stable because the fused rings are composed of SP² hybrid orbitals.

Exemplified compounds belonging to group CC are metal complexes each having the partial structure M (L) m represented by general formula [Ir-4], and are compounds each having a ligand containing at least a triphenylene ring. These compounds are particularly stable because the fused rings are composed of SP² hybrid orbitals.

Exemplified compounds belonging to group DD are metal complexes each having the partial structure M (L) m represented by any of general formulae [Ir-5] to [Ir-8], and are compounds each having a ligand containing at least a dibenzofuran ring, a dibenzothiophene ring, a benzoaphthofuran ring, or a benzoaphthothiophene ring. These compounds each contain an oxygen atom or a sulfur atom in its fused ring, and the charge transport properties can be enhanced by the abundant lone pairs of these atoms. Thus, in particular, these compounds are easy to adjust the carrier balance.

Exemplified compounds belonging to group EE and group GG are metal complexes each having the partial structure M (L)m represented by any of general formulae [Ir-6] to [Ir-8], and are compounds each having a ligand containing at least a benzofluorene ring. These compounds each have a substituent at the 9-position of the fluorene ring in a direction perpendicular to the in-plane direction of the fluorene ring. It is thus possible to particularly inhibit the fused rings from overlapping each other. For this reason, in particular, the compounds are excellent in sublimability.

Exemplified compounds belonging to group HH are metal complexes each having the partial structure M (L) m represented by any of general formulae [Ir-11] to [Ir-13], and are compounds each having a ligand containing at least a benzoisoquinoline ring. These compounds contain N atoms in their fused rings, and the charge transport properties can be enhanced by the lone pairs of these atoms and the high electronegativity. Thus, in particular, these compounds are easy to adjust the carrier balance.

Exemplified compounds belonging to group II are metal complexes each having the partial structure M (L) m represented by general formula [Ir-14], and are compounds each having a ligand containing at least a naphthoisoquinoline ring. These compounds contain N atoms in their fused rings, and the charge transport properties can be enhanced by the lone pairs of these atoms and the high electronegativity. Thus, in particular, these compounds are easy to adjust the carrier balance.

### (7) Other Compounds

In an organic light-emitting device according to the present embodiment, for example, a conventionally known low-molecular-weight or high-molecular-weight hole injection compound, hole transport compound, compound serving as a host, light-emitting compound, electron injection compound, or electron transport compound can be used together as needed. Examples of these compounds are illustrated below.

As a hole injection-transport material, a material having a high hole mobility is preferably used so as to facilitate the injection of holes from the anode and to transport the injected holes to the light-emitting layer. To inhibit a deterioration in film quality, such as crystallization, in the organic light-emitting device, a material having a high glass transition temperature is preferred. Examples of a low- or high-molecular-weight material having the ability to inject and transport holes include triarylamine derivatives, aryl carbazole derivatives, phenylenediamine derivatives, stilbene derivatives, phthalocyanine derivatives, porphyrin derivatives, poly(vinyl carbazole), polythiophene, and other conductive polymers. Moreover, the hole injection-transport material is also suitably used for the electron-blocking layer. Specific examples of a compound used as the hole injection-transport material are illustrated below, but of course, the compound is not limited thereto.

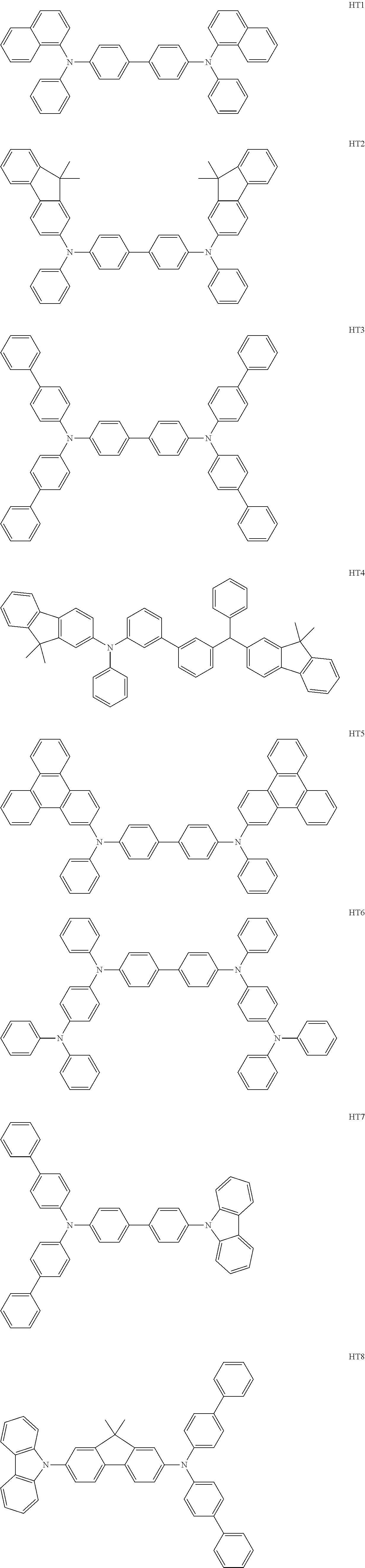

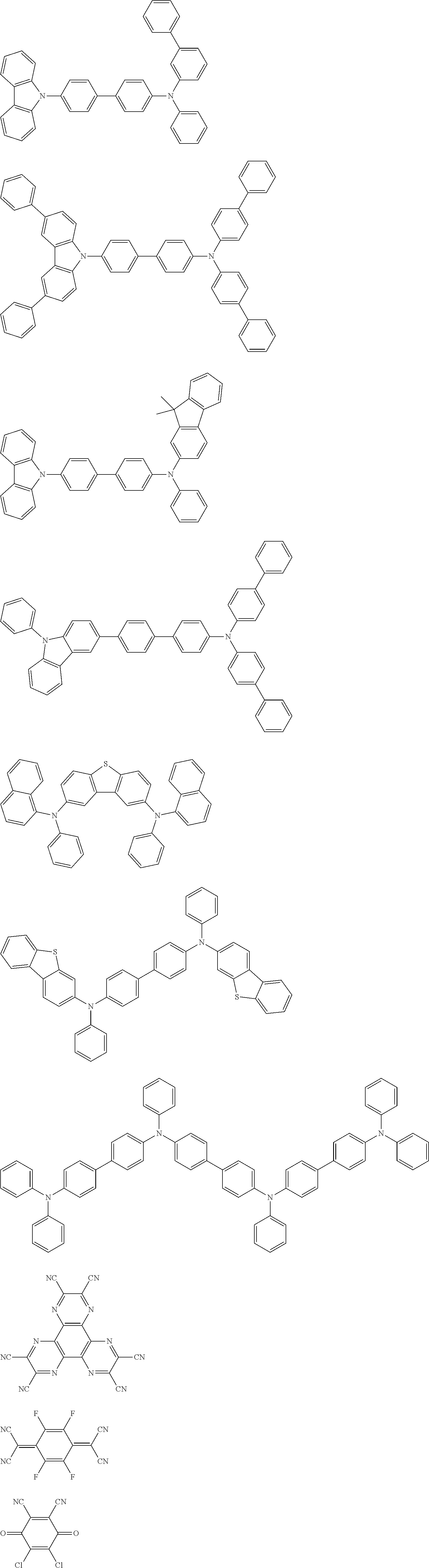

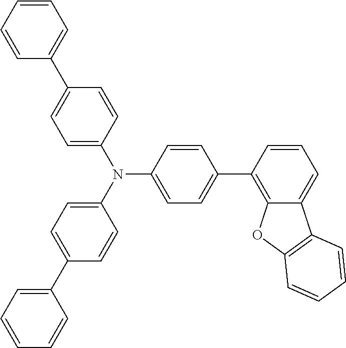 [SMILES: c1ccc(-c2ccc(N(c3ccc(-c4ccccc4)cc3)c3ccc(-c4cccc5c4oc4ccccc45)cc3)cc2)cc1]

Examples of the light-emitting material mainly related to the light-emitting function include, in addition to the organometallic complex represented by general formula [2], fused-ring compounds (such as fluorene derivatives, naphthalene derivatives, pyrene derivatives, perylene derivatives, tetracene derivatives, anthracene derivatives, and rubrene), quinacridone derivatives, coumarin derivatives, stilbene derivatives, organoaluminum complexes, such as tris(8-quinolinolato)aluminum, iridium complexes, platinum complexes, rhenium complexes, copper complexes, europium complexes, ruthenium complexes, and polymer derivatives, such as poly(phenylene vinylene) derivatives, polyfluorene derivatives, and polyphenylene derivatives. Specific examples of a compound used as a light-emitting material are illustrated below, but of course, the light-emitting material is not limited thereto.

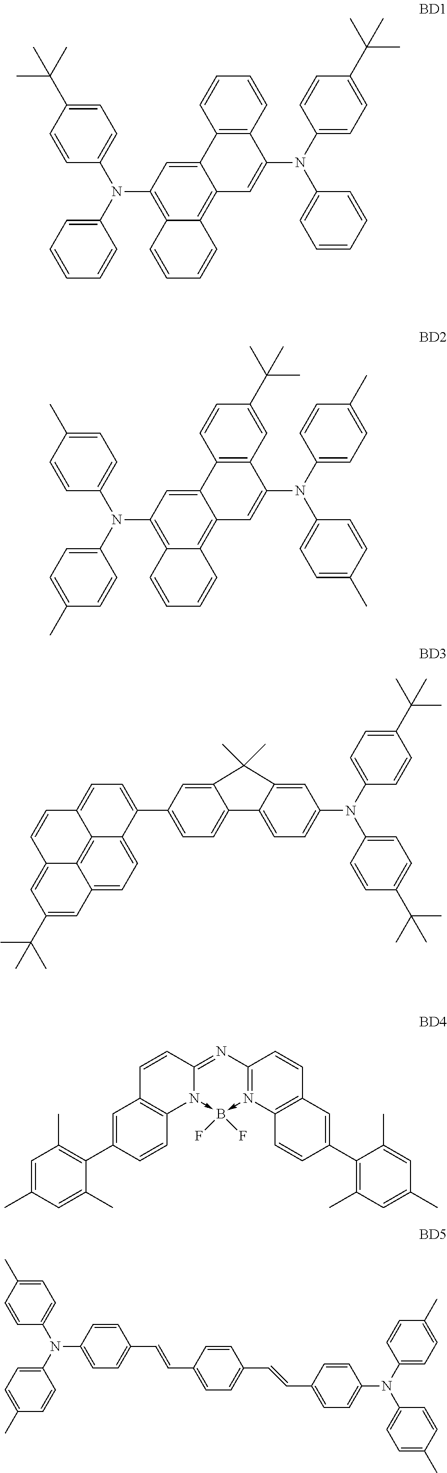

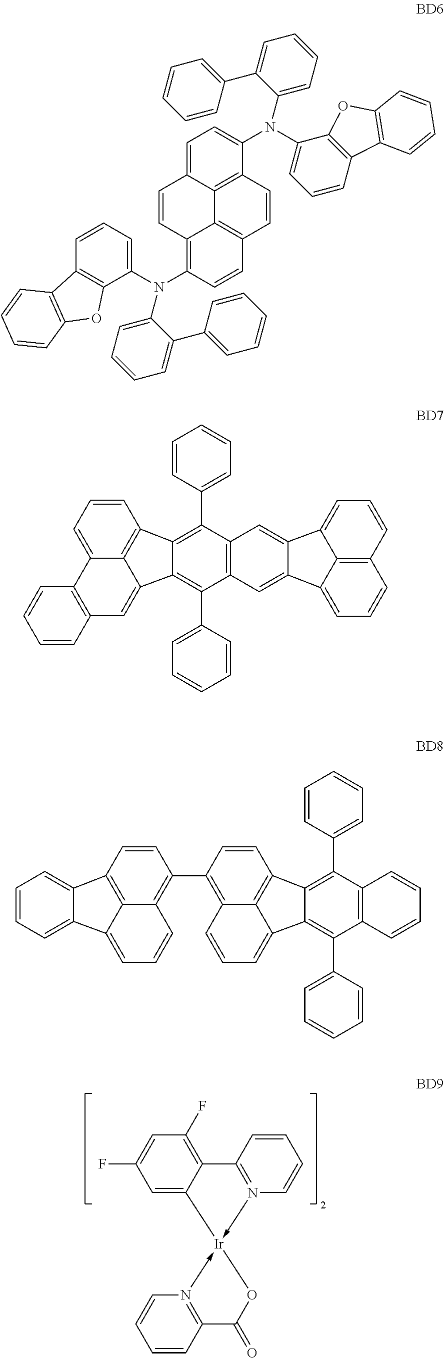

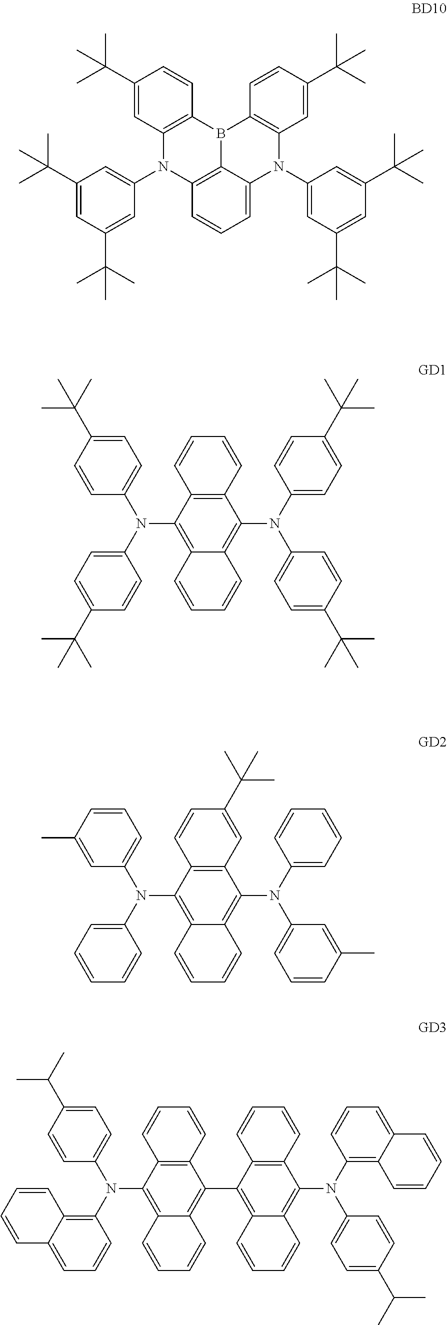

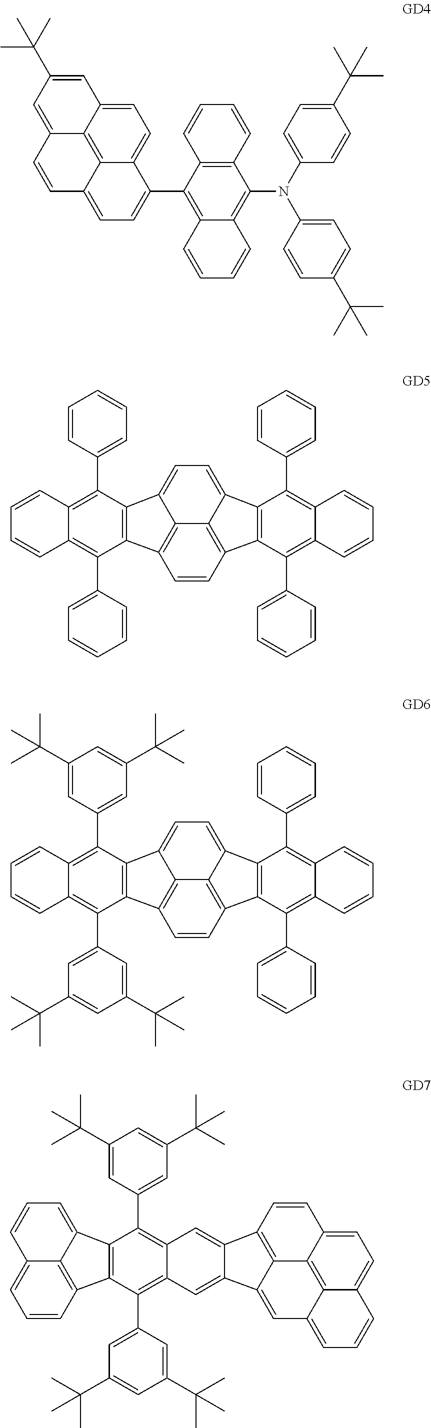

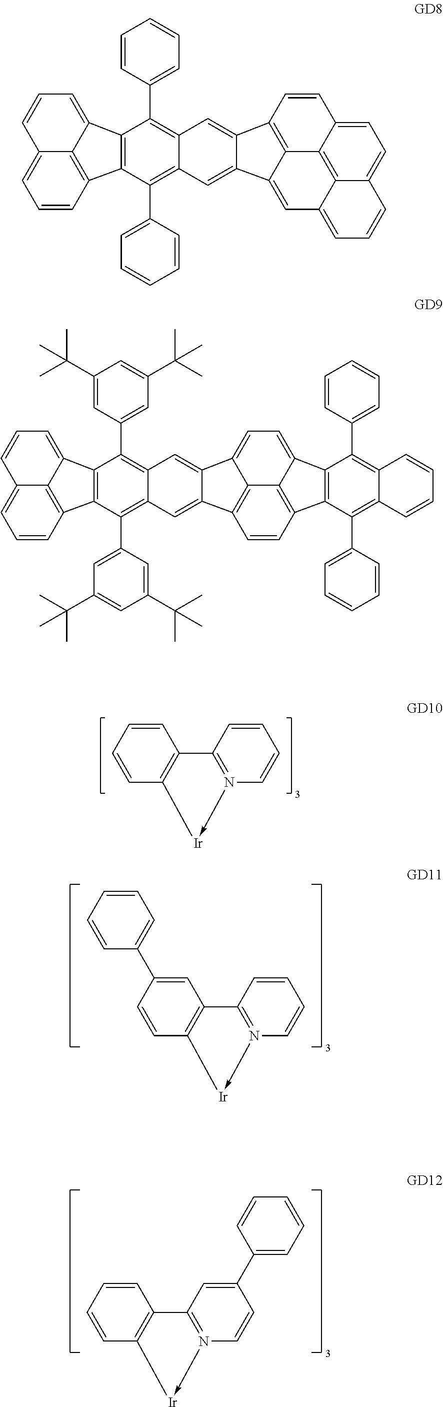

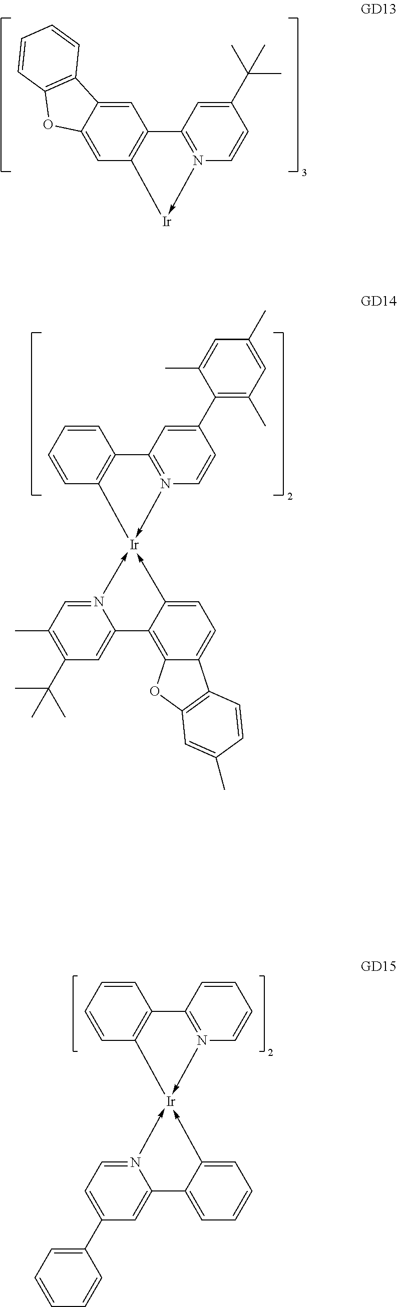

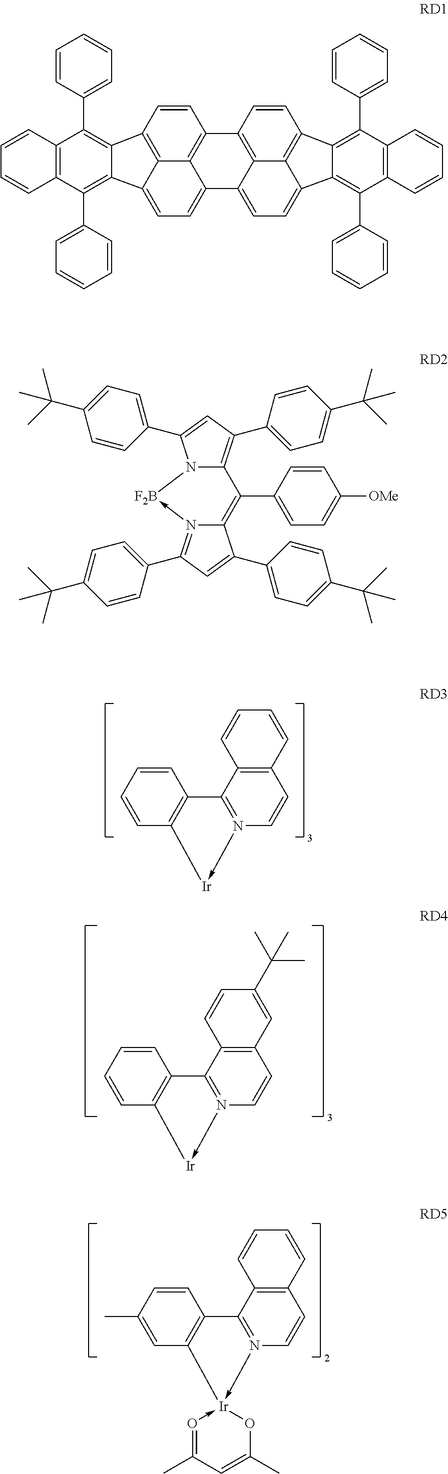

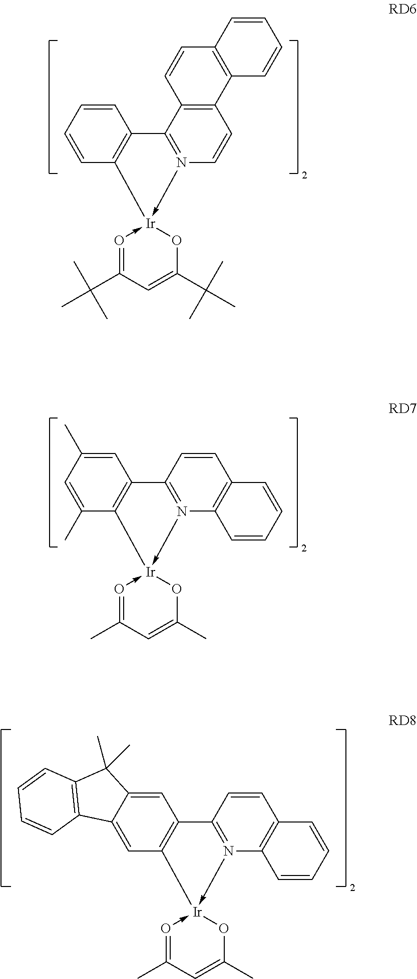

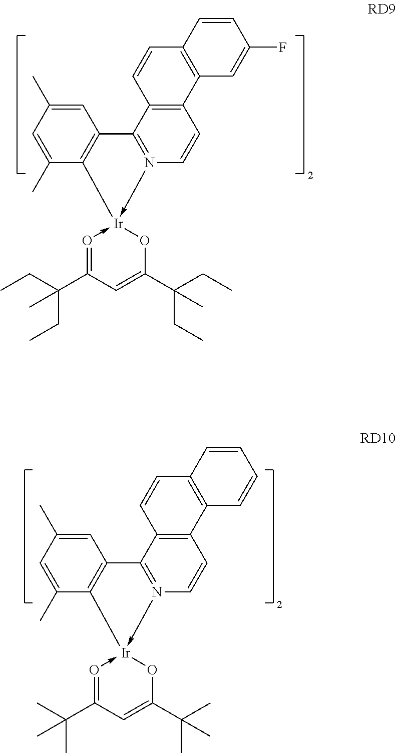

As a light-emitting layer host or a light-emission assist material contained in the light-emitting layer, a compound other than the organic compound of the present embodiment may be contained as a third component. Examples of the third component include aromatic hydrocarbon compounds and derivatives thereof, carbazole derivatives, azine derivatives, xanthone derivatives, dibenzofuran derivatives, dibenzothiophene derivatives, organoaluminum complexes such as tris(8-quinolinolato)aluminum, and organoberyllium complexes.

In particular, as the assist material, a material having a carbazole skeleton, a material having an azine ring, such as a diazine ring or a triazine ring, in its skeleton, and a material having xanthone in its skeleton are preferred. This is because these materials are high in electron-donating property and electron-withdrawing property, so that the HOMO level and the LUMO level are easily adjusted. Since the organic compound of the present embodiment has a fused-ring chalcogenophene skeleton, the band gap is widened to some extent. Therefore, a material having the above skeleton capable of adjusting the HOMO and LUMO levels is particularly preferred as the assist material. When such an assist material is combined with the organic compound of the present embodiment, a good carrier balance can be achieved.

Specific examples of a compound used as the light-emitting layer host or light-emission assist material contained in the light-emitting layer are illustrated below, but of course, the light-emitting layer host or light-emission assist material is not limited thereto. Among the specific examples below, materials having carbazole skeletons, which are preferable as assist materials, are EM32 to EM38. Materials having azine rings in their skeletons, which are preferable as assist materials, are EM35 to EM40. Materials having xanthone in their skeletons, which are preferable as assist materials, are EM28 and EM30.

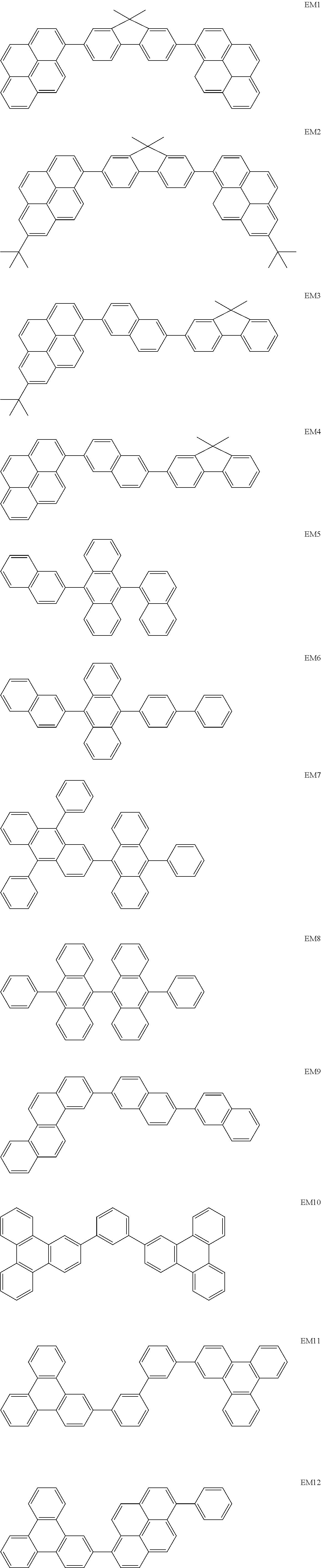

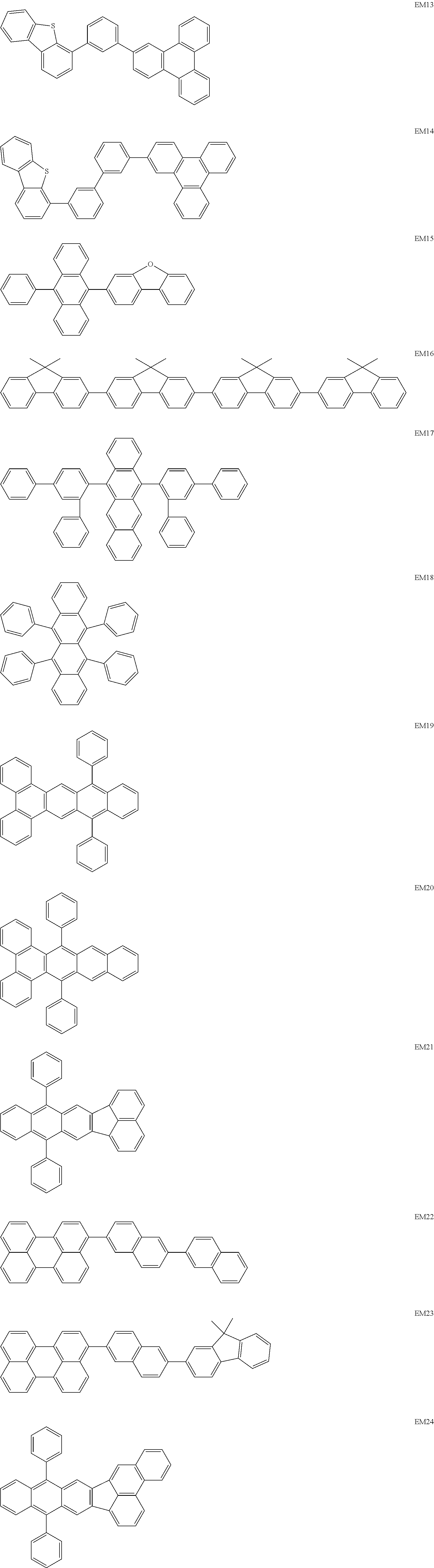

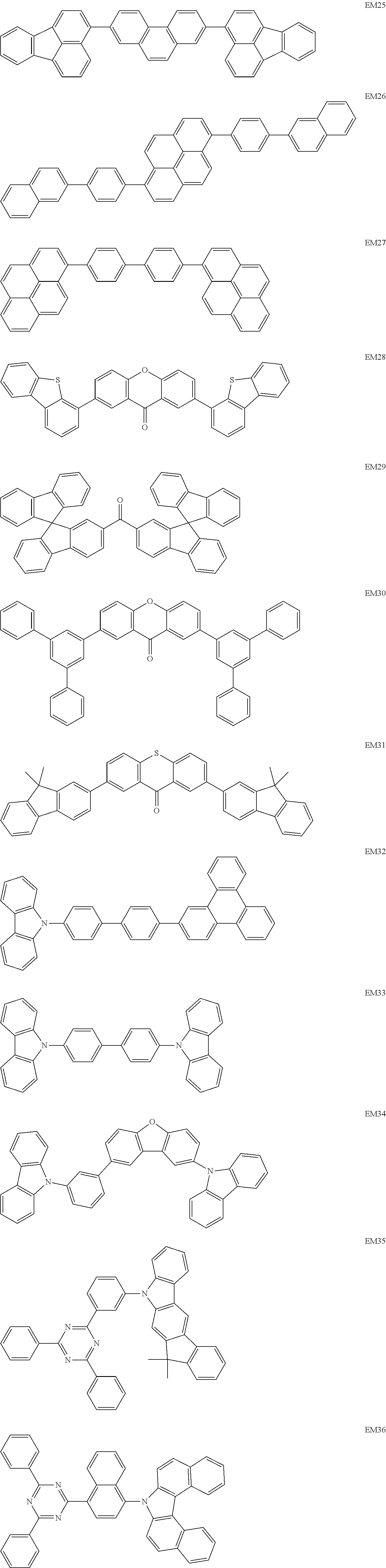

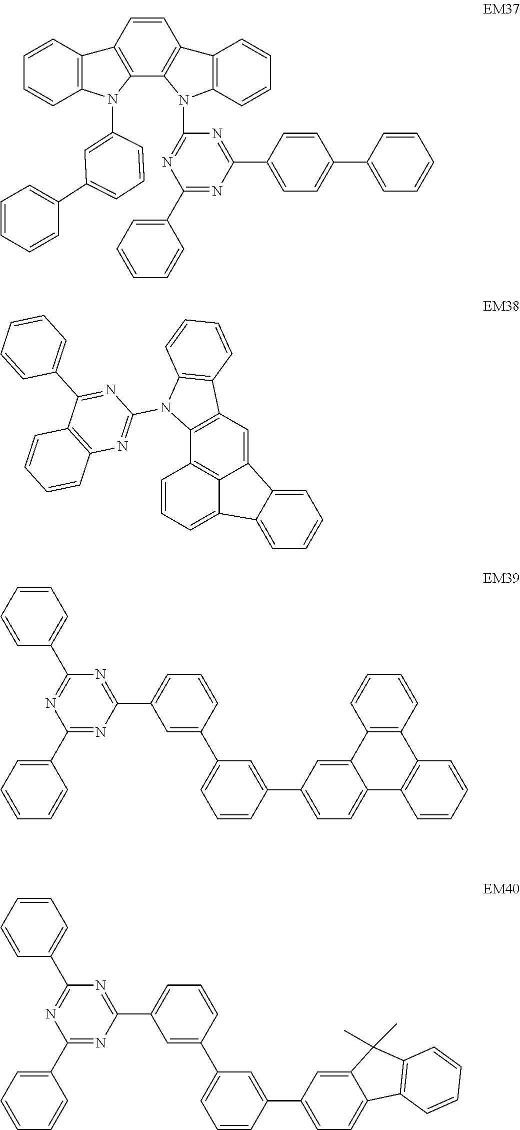

The electron transport material can be freely-selected from materials that can transport electrons injected from the cathode to the light-emitting layer, and is selected in consideration of, for example, the balance with the hole mobility of the hole transport material. Examples of a material having the ability to transport electrons include oxadiazole derivatives, oxazole derivatives, pyrazine derivatives, triazole derivatives, triazine derivatives, quinoline derivatives, quinoxaline derivatives, phenanthroline derivatives, organoaluminum complexes, and fused-ring compounds, such as fluorene derivatives, naphthalene derivatives, chrysene derivatives, and anthracene derivatives. The above-described electron transport materials are also suitably used for the hole-blocking layer. Specific examples of a compound used as the electron transport material are illustrated below, but of course, the electron transport material is not limited thereto.

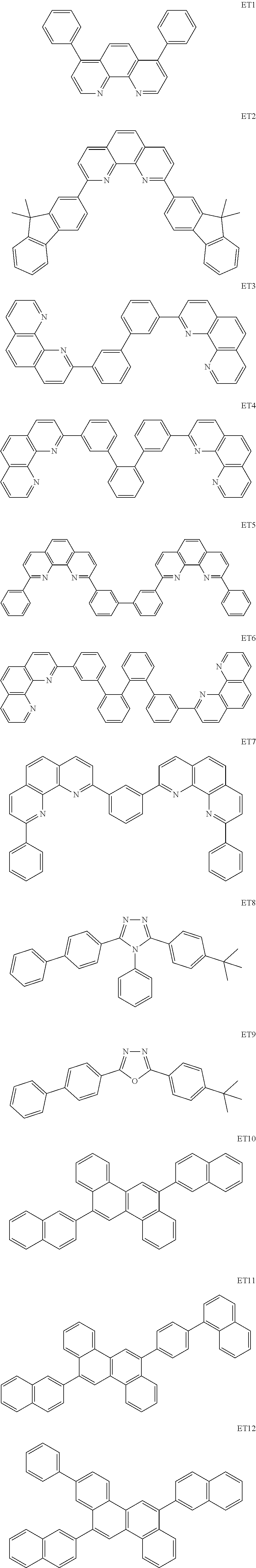

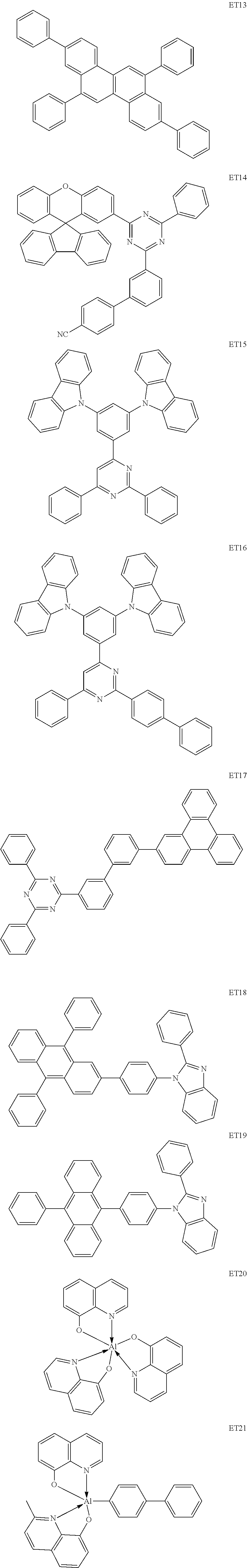

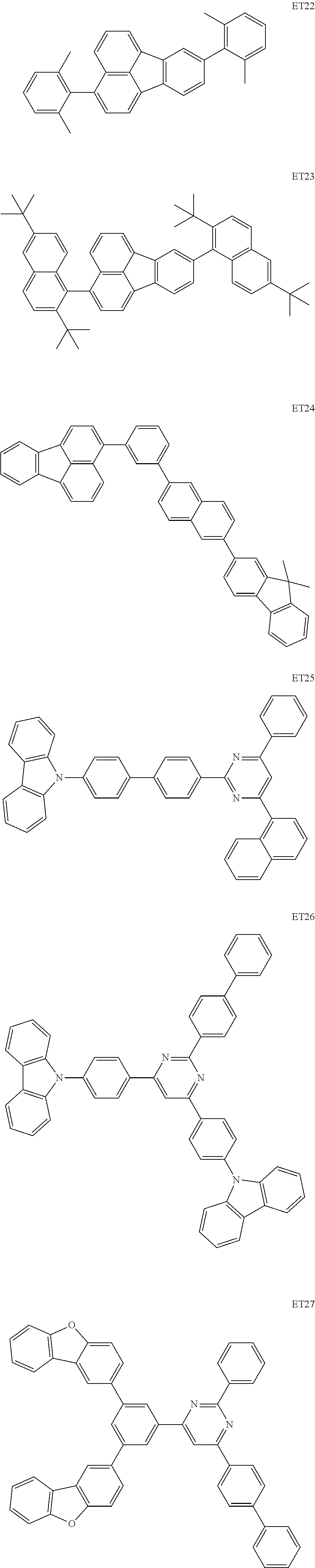

### (8) Configuration of Organic Light-Emitting Device

The organic light-emitting device includes an insulating layer, a first electrode, an organic compound layer, a second electrode over a substrate. A protective layer, a color filter, a microlens may be disposed over the second electrode. In the case of disposing the color filter, a planarization layer may be disposed between the protective layer and the color filter. The planarization layer can be composed of, for example, an acrylic resin. The same applies when a planarization layer is provided between the color filter and the microlens.

### Substrate

Examples of the substrate include silicon wafers, quartz substrates, glass substrates, resin substrates, and metal substrates. The substrate may include a switching device, such as a transistor, a line, and an insulating layer thereon. Any material can be used for the insulating layer as long as a contact hole can be formed in such a manner that a line can be coupled to the first electrode and as long as insulation with a non-connected line can be ensured. For example, a resin, such as polyimide, silicon oxide, or silicon nitride, can be used.

### Electrode

A pair of electrodes can be used. The pair of electrodes may be an anode and a cathode. When an electric field is applied in the direction in which the organic light-emitting device emits light, an electrode having a higher potential is the anode, and the other is the cathode. It can also be said that the electrode that supplies holes to the light-emitting layer is the anode and that the electrode that supplies electrons is the cathode.

As the component material of the anode, a material having a work function as high as possible can be used. Examples of the material that can be used include elemental metals, such as gold, platinum, silver, copper, nickel, palladium, cobalt, selenium, vanadium, and tungsten, mixtures thereof, alloys of combinations thereof, and metal oxides, such as tin oxide, zinc oxide, indium oxide, indium-tin oxide (ITO), and indium-zinc oxide. Additionally, conductive polymers, such as polyaniline, polypyrrole, and polythiophene, can be used.

These electrode materials may be used alone or in combination of two or more. The anode may be formed of a single layer or multiple layers.

When the anode is used as a reflective electrode, for example, chromium, aluminum, silver, titanium, tungsten, molybdenum, an alloy thereof, or a stack thereof can be used. These materials can also be used to act as a reflective film that does not have the role of an electrode. When the anode is used as a transparent electrode, a transparent conductive oxide layer composed of, for example, indium-tin oxide (ITO) or indium-zinc oxide can be used; however, the anode is not limited thereto. The electrode can be formed by photolithography.

As the component material of the cathode, a material having a lower work function can be used. Examples thereof include elemental metals such as alkali metals, e.g., lithium, alkaline-earth metals, e.g., calcium, aluminum, titanium, manganese, silver, lead, and chromium, and mixtures thereof. Alloys of combinations of these elemental metals can also be used. For example, magnesium-silver, aluminum-lithium, aluminum-magnesium, silver-copper, and zinc-silver can be used. Metal oxides, such as indium-tin oxide (ITO), can also be used. These electrode materials may be used alone or in combination of two or more. The cathode may have a single-layer structure or a multilayer structure. Among them, it is preferable to use silver. To reduce the aggregation of silver, it is more preferable to use a silver alloy. Any alloy ratio may be used as long as the aggregation of silver can be reduced. The ratio of silver to another metal may be, for example, 1:1 or 3:1.

A top emission device may be provided using the cathode formed of a conductive oxide layer composed of, for example, ITO. A bottom emission device may be provided using the cathode formed of a reflective electrode composed of, for example, aluminum (Al). Any type of cathode may be used. Any method for forming the cathode may be employed. For example, a direct-current or alternating-current sputtering technique is more preferably employed because good film coverage is obtained and thus the resistance is easily reduced.

### Organic Compound Layer

The organic compound layer may be formed of a single layer or multiple layers. When multiple layers are present, they may be referred to as a hole injection layer, a hole transport layer, an electron-blocking layer, a light-emitting layer, a hole-blocking layer, an electron transport layer, or an electron injection layer in accordance with their functions. The organic compound layer may include multiple light-emitting layers. When the multiple light-emitting layers are provided, a charge generation layer may be provided between the light-emitting layers. The charge generation layer may have a lowest unoccupied molecular orbital (LUMO) energy lower than the highest occupied molecular orbital (HOMO) energy of each of the hole transport layer and the light-emitting layer. The organic compound layer is mainly composed of an organic compound, and may contain inorganic atoms and an inorganic compound. For example, the organic compound layer may contain, for example, copper, lithium, magnesium, aluminum, iridium, platinum, molybdenum, or zinc. The organic compound layer may be disposed between the first electrode and the second electrode, and may be disposed in contact with the first electrode and the second electrode.

The organic compound layer (such as the hole injection layer, the hole transport layer, the electron-blocking layer, the light-emitting layer, the hole-blocking layer, the electron transport layer, or the electron injection layer) included in the organic light-emitting device according to an embodiment of the present invention is formed by a method described below.

For the organic compound layer included in the organic light-emitting device according to an embodiment of the present invention, a dry process, such as a vacuum evaporation method, an ionized evaporation method, sputtering, or plasma, may be employed. Alternatively, instead of the dry process, it is also possible to employ a wet process in which a material is dissolved in an appropriate solvent and then a film is formed by a known coating method (such as spin coating, dipping, a casting method, an LB technique, or an ink jet method).

When the layer is formed by, for example, the vacuum evaporation method or the solution coating method, crystallization and so forth are less likely to occur, and good stability with time is obtained. In the case of forming a film by the coating method, the film may be formed in combination with an appropriate binder resin.

Examples of the binder resin include, but are not limited to, poly(vinyl carbazole) resins, polycarbonate resins, polyester resins, ABS resins, acrylic resins, polyimide resins, phenolic resins, epoxy resins, silicone resins, and urea resins.

These binder resins may be used alone as a homopolymer or copolymer or in combination as a mixture of two or more. Furthermore, additives, such as a known plasticizer, antioxidant, and ultraviolet absorber, may be used, as needed.

### Protective Layer

A protective layer may be disposed on the second electrode. For example, a glass member provided with a moisture absorbent can be bonded to the second electrode to reduce the entry of, for example, water into the organic compound layer, thereby reducing the occurrence of display defects. In another embodiment, a passivation film composed of, for example, silicon nitride may be disposed on the second electrode to reduce the entry of, for example, water into the organic compound layer. For example, after the formation of the second electrode, the substrate may be transported to another chamber without breaking the vacuum, and a silicon nitride film having a thickness of 2 μm may be formed by a chemical vapor deposition (CVD) method to provide a protective layer. After the film deposition by the CVD method, a protective layer may be formed by an atomic layer deposition (ALD) method. Examples of the material of the layer formed by the ALD method may include, but are not limited to, silicon nitride, silicon oxide, and aluminum oxide. Silicon nitride may be deposited by the CVD method on the layer formed by the ALD method. The film formed by the ALD method may have a smaller thickness than the film formed by the CVD method. Specifically, the thickness may be 50% or less, even 10% or less.

A color filter may be disposed on the protective layer. For example, a color filter may be disposed on another substrate in consideration of the size of the organic light-emitting device and bonded to the substrate provided with the organic light-emitting device. A color filter may be formed by patterning on the protective layer using photolithography. The color filter may be composed of a polymer.

### Planarization Layer

A planarization layer may be disposed between the color filter and the protective layer. The planarization layer is provided for the purpose of reducing the unevenness of the layer underneath. The planarization layer may be referred to as a “material resin layer” without limiting its purpose. The planarization layer may be composed of an organic compound. A low- or high-molecular-weight organic compound may be used. A high-molecular-weight organic compound is preferred.

The planarization layers may be disposed above and below (or on) the color filter and may be composed of the same or different component materials. Specific examples thereof include poly(vinyl carbazole) resins, polycarbonate resins, polyester resins, ABS resins, acrylic resins, polyimide resins, phenolic resins, epoxy resins, silicone resins, and urea resins.

### Microlens

The organic light-emitting device or an organic light-emitting apparatus may include an optical component, such as a microlens, on the outgoing light side. The microlens can be composed of, for example, an acrylic resin or an epoxy resin. The microlens may be used to increase the amount of light emitted from the organic light-emitting device or the organic light-emitting apparatus and to control the direction of the light emitted. The microlens may have a hemispherical shape. In the case of a hemispherical shape, among tangents to the hemisphere, there is a tangent parallel to the insulating layer. The point of contact of the tangent with the hemisphere is the vertex of the microlens. The vertex of the microlens can be determined in the same way for any cross-sectional view. That is, among the tangents to the semicircle of the microlens in the cross-sectional view, there is a tangent parallel to the insulating layer, and the point of contact of the tangent with the semicircle is the vertex of the microlens.

The midpoint of the microlens can be defined. In the cross section of the microlens, when a segment is hypothetically drawn from the point where an arc shape ends to the point where another arc shape ends, the midpoint of the segment can be referred to as the midpoint of the microlens. The cross section to determine the vertex and midpoint may be a cross section perpendicular to the insulating layer.

### Opposite Substrate

An opposite substrate may be disposed on the planarization layer. The opposite substrate is disposed at a position corresponding to the substrate described above and thus is called an opposite substrate. The opposite substrate may be composed of the same material as the substrate described above. When the above-described substrate is referred to as a first substrate, the opposite substrate may be referred to as a second substrate.

### Pixel Circuit

An organic light-emitting apparatus including organic light-emitting devices may include pixel circuits coupled to the organic light-emitting devices. Each of the pixel circuits may be of an active matrix type, which independently controls the emission of first and second light-emitting devices. The active matrix type circuit may be voltage programming or current programming. A driving circuit includes the pixel circuit for each pixel. The pixel circuit may include a light-emitting device, a transistor to control the luminance of the light-emitting device, a transistor to control the timing of the light emission, a capacitor to retain the gate voltage of the transistor to control the luminance, and a transistor to connect to GND without using the light-emitting device.

The light-emitting apparatus includes a display area and a peripheral area disposed around the display area. The display area includes a pixel circuit, and the peripheral area includes a display control circuit. The mobility of a transistor contained in the pixel circuit may be lower than the mobility of a transistor contained in the display control circuit. The gradient of the current-voltage characteristics of the transistor contained in the pixel circuit may be smaller than the gradient of the current-voltage characteristic of the transistor contained in the display control circuit. The gradient of the current-voltage characteristics can be measured by what is called Vg-Ig characteristics. The transistor contained in the pixel circuit is a transistor coupled to a light-emitting device, such as a first light-emitting device.

### Pixel

An organic light-emitting apparatus including an organic light-emitting device may include multiple pixels. Each pixel includes subpixels configured to emit colors different from each other. The subpixels may have respective red, green, and blue (RGB) emission colors.

Light emerges from a region of the pixel, also called a pixel aperture. This region is also referred to as a first region. The pixel aperture may be 15 μm or less, and may be 5 μm or more. More specifically, the pixel aperture may be, for example, 11 μm, 9.5 μm, 7.4 μm, or 6.4 μm. The distance between subpixels may be 10 μm or less. Specifically, the distance may be 8 μm, 7.4 μm, or 6.4 μm.

The pixels may be arranged in a known pattern in plan view. For example, a stripe pattern, a delta pattern, a Pen Tile matrix pattern, or the Bayer pattern may be used. The shape of each subpixel in plan view may be any known shape. Examples of the shape of the subpixel include quadrilaterals, such as rectangles and rhombi, and hexagons. Of course, if the shape is close to a rectangle, rather than an exact shape, it is included in the rectangle. The shape of the subpixel and the pixel arrangement can be used in combination.

### (9) Apparatus Including Organic Light-Emitting Device

The organic light-emitting device according to an embodiment can be used as a component member of a display apparatus or lighting apparatus. Other applications include exposure light sources for electrophotographic image-forming apparatuses, backlights for liquid crystal displays, and light-emitting apparatuses including white-light sources and color filters.

The display apparatus may be an image information-processing unit having an image input unit that receives image information from an area CCD, a linear CCD, a memory card, or the like, an information-processing unit that processes the input information, and a display unit that displays the input image. The display apparatus includes multiple pixels, and at least one of the multiple pixels may include the organic light-emitting device of the present embodiment and a transistor coupled to the organic light-emitting device.

The display unit of an image pickup apparatus or an inkjet printer may have a touch panel function. The display unit of an image pickup apparatus or an inkjet printer may have a touch panel function. The driving mode of the touch panel function may be, but is not particularly limited to, an infrared mode, an electrostatic capacitance mode, a resistive film mode, or an electromagnetic inductive mode. The display apparatus may also be used for a display unit of a multifunction printer.

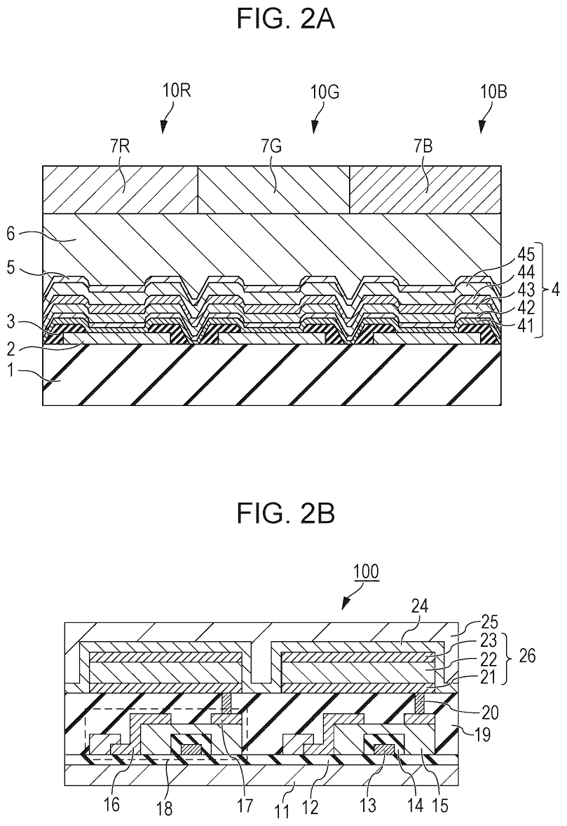

The following describes a display apparatus according to the present embodiment with reference to the attached drawings. FIGS. 2A and 2B are each a schematic cross-sectional view of an example of a display apparatus including organic light-emitting devices and transistors coupled to the respective organic light-emitting devices. Each of the transistors is an example of an active element. The transistors may be thin-film transistors (TFTs).

FIG. 2A is an example of pixels that are components of the display apparatus according to the present embodiment. Each of the pixels includes subpixels 10. The subpixels are separated into 10R, 10G, and 10B according to their light emission. The emission color may be distinguished based on the wavelength of light emitted from the light-emitting layer. Alternatively, light emitted from the subpixels may be selectively transmitted or color-converted with, for example, a color filter. Each subpixels 10 includes a reflective electrode serving as a first electrode 2, an insulating layer 3 covering the edge of the first electrode 2, an organic compound layer 4 covering the first electrode 2 and the insulating layer 3, a transparent electrode serving as a second electrode 5, a protective layer 6, and a color filter 7 over an interlayer insulating layer 1.

The transistors and capacitive elements may be disposed under or in the interlayer insulating layer 1. Each transistor may be electrically coupled to a corresponding one of the first electrodes 2 through a contact hole, which is not illustrated.

The insulating layer 3 is also called a bank or pixel separation film. The insulating layer 3 covers the edge of each first electrode 2 and surrounds the first electrode 2. Portions that are not covered with the insulating layer 3 are in contact with the organic compound layer 4 and serve as light-emitting regions.

The organic compound layer 4 includes a hole injection layer 41, a hole transport layer 42, a first light-emitting layer 43, a second light-emitting layer 44, and an electron transport layer 45.

The second electrode 5 may be a transparent electrode, a reflective electrode, or a semi-transparent electrode.

The protective layer 6 reduces the penetration of moisture into the organic compound layer 4. Although the protective layer 6 is illustrated as a single layer, the protective layer 6 may include multiple layers, and each layer may be an inorganic compound layer or an organic compound layer.

The color filter 7 is separated into 7R, 7G, and 7B according to its color. The color filter 7 may be disposed on a planarization film, which is not illustrated. A resin protective layer, not illustrated, may be disposed on the color filter 7. The color filter 7 may be disposed on the protective layer 6. Alternatively, the color filter 7 may be disposed on an opposite substrate, such as a glass substrate, and then bonded.

A display apparatus 100 illustrated in FIG. 2B includes organic light-emitting devices 26 and TFTs 18 as an example of transistors. A substrate 11 composed of a material, such as glass or silicon is provided, and an insulating layer 12 is disposed thereon. Active elements, such as the TFTs 18, are disposed on the insulating layer 12. The gate electrode 13, the gate insulating film 14, and the semiconductor layer 15 of each of the active elements are disposed thereon. Each TFT 18 further includes a drain electrode 16 and a source electrode 17. The TFTs 18 are overlaid with an insulating film 19. Anode 21 included in the organic light-emitting devices 26 is coupled to the source electrodes 17 through contact holes 20 provided in the insulating film 19.

The mode of electrical connection between the electrodes (anode 21 and cathode 23) included in each organic light-emitting device 26 and the electrodes (source electrode 17 and drain electrode 16) included in a corresponding one of the TFTs 18 is not limited to the mode illustrated in FIG. 2B. That is, it is sufficient that any one of the anode 21 and the cathode 23 is electrically coupled to any one of the source electrode 17 and the drain electrode 16 of the TFT 18. The term “TFT” refers to a thin-film transistor.

In the display apparatus 100 illustrated in FIG. 2B, although each organic compound layer 22 is illustrated as a single layer, the organic compound layer 22 may include multiple layers. To reduce the deterioration of the organic light-emitting devices 26, a first protective layer 24 and a second protective layer 25 are disposed on the cathodes 23.

In the display apparatus 100 illustrated in FIG. 2B, although the transistors are used as switching devices, other switching devices may be used instead.

The transistors used in the display apparatus 100 illustrated in FIG. 2B are not limited to transistors using a single-crystal silicon wafer, but may also be thin-film transistors including active layers on the insulating surface of a substrate. Examples of the material of the active layers include single-crystal silicon, non-single-crystal silicon, such as amorphous silicon and microcrystalline silicon; and non-single-crystal oxide semiconductors, such as indium zinc oxide and indium gallium zinc oxide. Thin-film transistors are also called TFT elements.

The transistors in the display apparatus 100 illustrated in FIG. 2B may be formed in the substrate, such as a Si substrate. The expression “formed in the substrate” indicates that the transistors are produced by processing the substrate, such as a Si substrate. In the case where the transistors are formed in the substrate, the substrate and the transistors can be deemed to be integrally formed.

In the organic light-emitting device according to the present embodiment, the luminance is controlled by the TFT devices, which are an example of switching devices; thus, an image can be displayed at respective luminance levels by arranging multiple organic light-emitting devices in the plane. The switching devices according to the present embodiment are not limited to the TFT devices and may be low-temperature polysilicon transistors or active-matrix drivers formed on a substrate such as a Si substrate. The expression “on a substrate” can also be said to be “in the substrate”. Whether transistors are formed in the substrate or TFT devices are used is selected in accordance with the size of a display unit. For example, when the display unit has a size of about 0.5 inches, organic light-emitting devices are preferably disposed on a Si substrate.

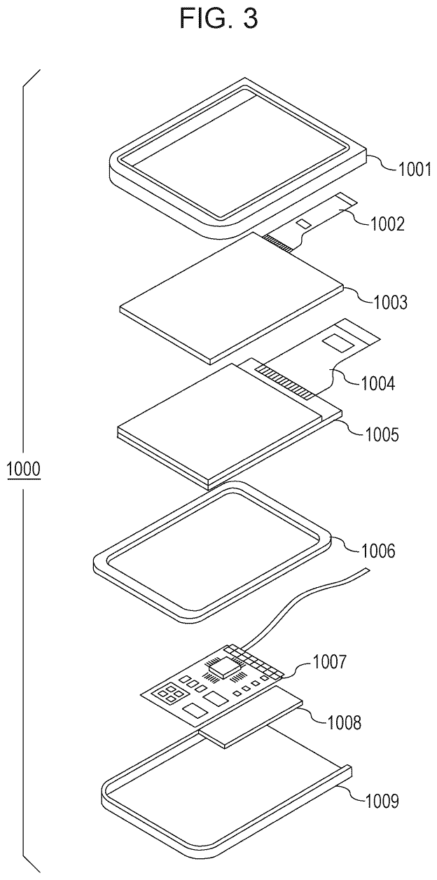

FIG. 3 is a schematic view illustrating an example of a display apparatus according to the present embodiment. A display apparatus 1000 may include a touch panel 1003, a display panel 1005, a frame 1006, a circuit substrate 1007, and a battery 1008 disposed between an upper cover 1001 and a lower cover 1009. The touch panel 1003 and the display panel 1005 are coupled to flexible printed circuits FPCs 1002 and 1004, respectively. The circuit substrate 1007 includes printed transistors. The battery 1008 need not be provided unless the display apparatus is a portable apparatus. The battery 1008 may be disposed at a different position even if the display apparatus is a portable apparatus.

The display apparatus according to the present embodiment may include a color filter having red, green, and blue portions. In the color filter, the red, green, and blue portions may be arranged in a delta arrangement.

The display apparatus according to the present embodiment may be used for the display unit of a portable terminal. In that case, the display apparatus may have both a display function and an operation function. Examples of the portable terminal include mobile phones such as smartphones, tablets, and head-mounted displays.

The display apparatus according to the present embodiment may be used for a display unit of an image pickup apparatus including an optical unit including multiple lenses and an image pickup device that receives light passing through the optical unit. The image pickup apparatus may include a display unit that displays information acquired by the image pickup device. The display unit may be a display unit exposed to the outside of the image pickup apparatus or a display unit disposed in a finder. The image pickup apparatus may be a digital camera or a digital camcorder.

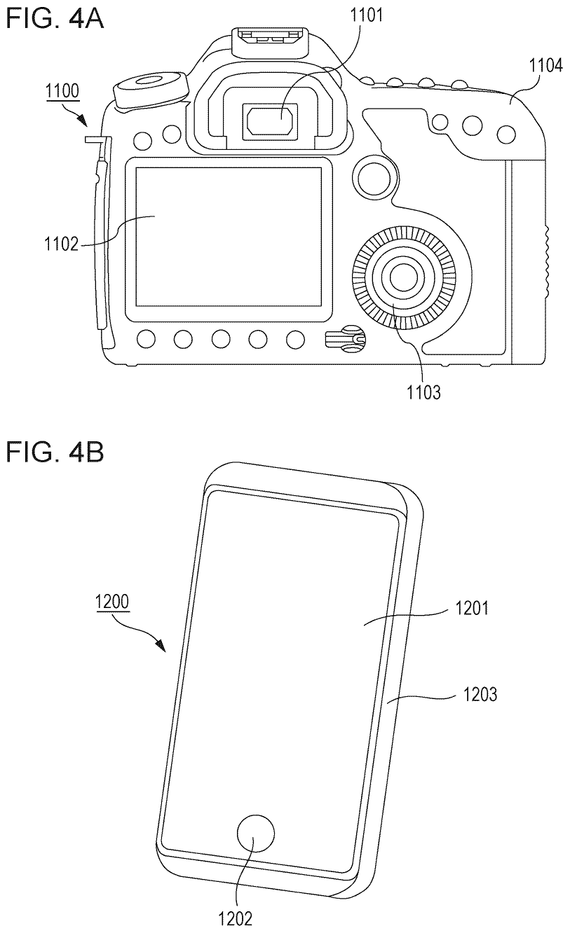

FIG. 4A is a schematic view illustrating an example of an image pickup apparatus according to the present embodiment. An image pickup apparatus 1100 may include a viewfinder 1101, a rear display 1102, an operation unit 1103, and a housing 1104. The viewfinder 1101 may include the display apparatus according to the present embodiment. In this case, the display apparatus may display environmental information, imaging instructions, and so forth in addition to an image to be captured. The environmental information may include, for example, the intensity of external light, the direction of external light, the moving speed of a subject, and the possibility that a subject is shielded by a shielding material.

The timing suitable for imaging is only for a short time; thus, the information may be displayed as soon as possible. Accordingly, it is preferable to use a display apparatus including the organic light-emitting device of the present embodiment. This is because the organic light-emitting device has a fast response time. The display apparatus including the organic light-emitting device can be used more suitably than liquid crystal displays for such apparatuses required to have a high display speed.

The image pickup apparatus 1100 includes an optical unit, which is not illustrated. The optical unit includes multiple lenses and is configured to form an image on an image pickup device in the housing 1104. The relative positions of the multiple lenses can be adjusted to adjust the focal point. This operation can also be performed automatically. The image pickup apparatus may translate to a photoelectric conversion apparatus. Examples of an image capturing method employed in the photoelectric conversion apparatus may include a method for detecting a difference from the previous image and a method of cutting out an image from images always recorded, instead of sequentially capturing images.

FIG. 4B is a schematic view illustrating an example of an electronic apparatus according to the present embodiment. An electronic apparatus 1200 includes a display unit 1201, an operation unit 1202, and a housing 1203. The housing 1203 may accommodate a circuit, a printed circuit board including the circuit, a battery, and a communication unit. The operation unit 1202 may be a button or a touch-screen-type reactive unit. The operation unit 1202 may be a biometric recognition unit that recognizes a fingerprint to release the lock or the like. An electronic apparatus having a communication unit can also be referred to as a communication apparatus. The electronic apparatus 1200 may further have a camera function by being equipped with a lens and an image pickup device. An image captured by the camera function is displayed on the display unit 1201. Examples of the electronic apparatus 1200 include smartphones and notebook computers.

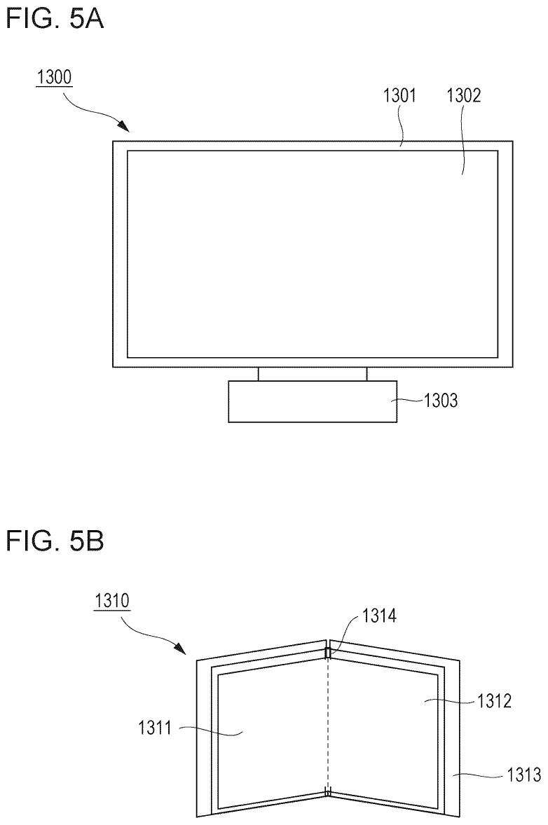

FIGS. 5A and 5B are each a schematic view illustrating an example of the display apparatus according to the present embodiment. FIG. 5A illustrates a display apparatus, such as a television monitor or a PC monitor. A display apparatus 1300 includes a frame 1301 and a display unit 1302. The light-emitting device according to the present embodiment may be used for the display unit 1302. The display apparatus 1300 includes a base 1303 that supports the frame 1301 and the display unit 1302. The base 1303 is not limited to the structure illustrated in FIG. 5A. The lower side of the frame 1301 may also serve as a base. The frame 1301 and the display unit 1302 may be curved. These may have a radius of curvature of 5,000 mm or more and 6,000 mm or less.

FIG. 5B is a schematic view illustrating another example of a display apparatus according to the present embodiment. A display apparatus 1310 illustrated in FIG. 5B can be folded and is what is called a foldable display apparatus. The display apparatus 1310 includes a first display portion 1311, a second display portion 1312, a housing 1313, and an inflection point 1314. The first display portion 1311 and the second display portion 1312 may include the light-emitting device according to the present embodiment. The first display portion 1311 and the second display portion 1312 may be a single, seamless display apparatus. The first display portion 1311 and the second display portion 1312 can be divided from each other at the inflection point. The first display portion 1311 and the second display portion 1312 may display different images. Alternatively, a single image may be displayed in the first and second display portions.

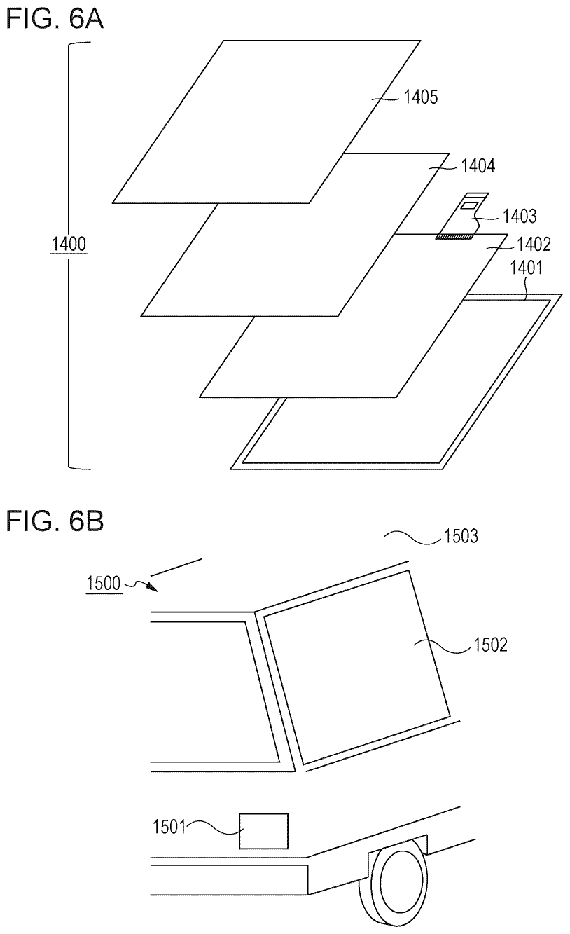

FIG. 6A is a schematic view illustrating an example of a lighting apparatus according to the present embodiment. A lighting apparatus 1400 may include a housing 1401, a light source 1402, a circuit board 1403, an optical filter 1404 that transmits light emitted from the light source 1402, and a light diffusion unit 1405. The light source 1402 may include an organic light-emitting device according to the present embodiment. The optical filter 1404 may be a filter that improves the color rendering properties of the light source. The light diffusion unit 1405 can effectively diffuse light from the light source to deliver the light to a wide range when used for illumination and so forth. The optical filter 1404 and the light diffusion unit 1405 may be disposed at the light emission side of the lighting apparatus. A cover may be disposed at the outermost portion, as needed.

The lighting apparatus is, for example, an apparatus that lights a room. The lighting apparatus may emit light of white, neutral white, or any color from blue to red. A light control circuit that controls the light may be provided. The lighting apparatus may include the organic light-emitting device of the present embodiment and a power supply circuit coupled thereto. The power supply circuit is a circuit that converts an AC voltage into a DC voltage. The color temperature of white is 4,200 K, and the color temperature of neutral white is 5,000 K. The lighting apparatus may include a color filter.

The lighting apparatus according to the present embodiment may include a heat dissipation unit. The heat dissipation unit is configured to release heat in the device to the outside of the device and is composed of, for example, a metal having a high specific heat and liquid silicone.

FIG. 6B is a schematic view illustrating an automobile as an example of a moving object according to the present embodiment. The automobile includes a tail lamp, which is an example of lighting units. An automobile 1500 includes a tail lamp 1501 and may be configured to light the tail lamp when a brake operation or the like is performed.

The tail lamp 1501 may include an organic light-emitting device according to the present embodiment. The tail lamp 1501 may include a protective member that protects the organic light-emitting device. The protective member may be composed of any transparent material with some degree of high strength and is preferably composed of polycarbonate, for example. The polycarbonate may be mixed with, for example, a furandicarboxylic acid derivative or an acrylonitrile derivative.

The automobile 1500 may include an automobile body 1503 and windows 1502 attached thereto. The windows 1502 may be transparent displays if the windows are not used to check the front and back of the automobile. The transparent displays may include an organic light-emitting device according to the present embodiment. In this case, the components, such as the electrodes, of the organic light-emitting device are formed of transparent members.

The moving object according to the present embodiment may be, for example, a ship, an aircraft, or a drone. The moving object may include a body and a lighting unit attached to the body. The lighting unit may emit light to indicate the position of the body. The lighting unit includes the organic light-emitting device according to the present embodiment.

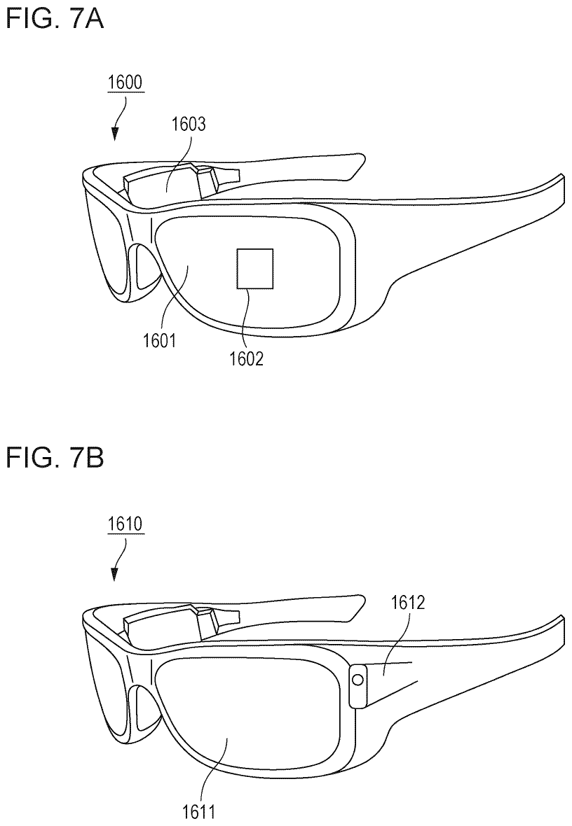

Examples of applications of the display apparatuses of the above embodiments will be described with reference to FIGS. 7A and 7B. The display apparatuses can be used for systems that can be worn as wearable devices, such as smart glasses, HMDs, and smart contacts. An image pickup and display apparatus used in such an example of the applications has an image pickup apparatus that can photoelectrically convert visible light and a display apparatus that can emit visible light.

FIG. 7A is a schematic view illustrating an example of a wearable device according to an embodiment of the present invention. Glasses 1600 (smart glasses) according to an example of applications will be described with reference to FIG. 7A. An image pickup apparatus 1602, such as a CMOS sensor or SPAD, is provided on a front side of a lens 1601 of the glasses 1600. The display apparatus according to any of the above-mentioned embodiments is provided on the back side of the lens 1601.

The glasses 1600 further include a control unit 1603. The control unit 1603 functions as a power source that supplies electric power to the image pickup apparatus 1602 and the display apparatus. The control unit 1603 controls the operation of the image pickup apparatus 1602 and the display apparatus. The lens 1601 has an optical system for focusing light on the image pickup apparatus 1602.

FIG. 7B is a schematic view illustrating another example of a wearable device according to an embodiment of the present invention. Glasses 1610 (smart glasses) according to an example of applications will be described with reference to FIG. 7B. The glasses 1610 include a control unit 1612. The control unit 1612 includes an image pickup apparatus corresponding to the image pickup apparatus 1602 illustrated in FIG. 7A and a display apparatus. A lens 1611 is provided with the image pickup apparatus in the control unit 1612 and an optical system that projects light emitted from the display apparatus. An image is projected onto the lens 1611. The control unit 1612 functions as a power source that supplies electric power to the image pickup apparatus and the display apparatus and controls the operation of the image pickup apparatus and the display apparatus.

The control unit 1612 may include a gaze detection unit that detects the gaze of a wearer. Infrared light may be used for gaze detection. An infrared light-emitting unit emits infrared light to an eyeball of a user who is gazing at a displayed image. An image of the eyeball is captured by detecting the reflected infrared light from the eyeball with an image pickup unit having light-receiving elements. The deterioration of image quality is reduced by providing a reduction unit that reduces light from the infrared light-emitting unit to the display unit when viewed in plan. The user's gaze at the displayed image is detected from the image of the eyeball captured with the infrared light. Any known method can be employed to the gaze detection using the captured image of the eyeball. As an example, a gaze detection method based on a Purkinje image of the reflection of irradiation light on a cornea can be employed. More specifically, the gaze detection process is based on a pupil-corneal reflection method. Using the pupil-corneal reflection method, the user's gaze is detected by calculating a gaze vector representing the direction (rotation angle) of the eyeball based on the image of the pupil and the Purkinje image contained in the captured image of the eyeball.

A display apparatus according to an embodiment of the present invention may include an image pickup apparatus including light-receiving elements, and may control an image displayed on the display apparatus based on the gaze information of the user from the image pickup apparatus. Specifically, in the display apparatus, a first field-of-view area at which the user gazes and a second field-of-view area other than the first field-of-view area are determined on the basis of the gaze information. The first field-of-view area and the second field-of-view area may be determined by the control unit of the display apparatus or may be determined by receiving those determined by an external control unit. In the display area of the display apparatus, the display resolution of the first field-of-view area may be controlled to be higher than the display resolution of the second field-of-view area. That is, the resolution of the second field-of-view area may be lower than that of the first field-of-view area.

The display area includes a first display area and a second display area different from the first display area. Based on the gaze information, an area of higher priority is determined from the first display area and the second display area. The first display area and the second display area may be determined by the control unit of the display apparatus or may be determined by receiving those determined by an external control unit. The resolution of an area of higher priority may be controlled to be higher than the resolution of an area other than the area of higher priority. In other words, the resolution of an area of a relatively low priority may be low.

Artificial intelligence (AI) may be used to determine the first field-of-view and the high-priority area. The AI may be a model configured to estimate the angle of gaze from the image of the eyeball and the distance to a target object located in the gaze direction, using the image of the eyeball and the actual direction of gaze of the eyeball in the image as teaching data. The AI program may be stored in the display apparatus, the image pickup apparatus, or an external apparatus. When the AI program is stored in the external apparatus, the AI program is transmitted to the display apparatus via communications.

In the case of controlling the display based on visual detection, smart glasses that further include an image pickup apparatus that captures an external image can be used. The smart glasses can display the captured external information in real time.

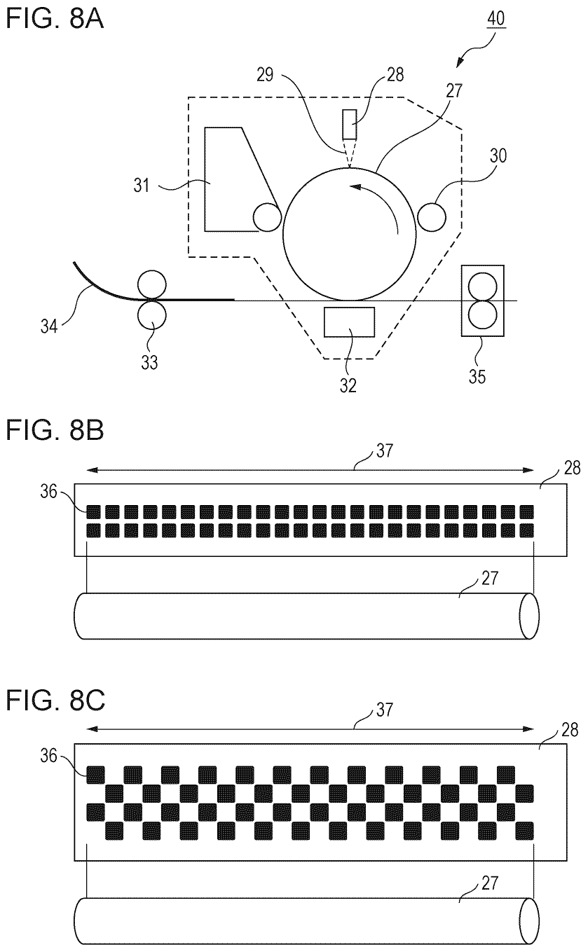

FIG. 8A is a schematic view of an example of an image-forming apparatus according to an embodiment of the present invention. An image-forming apparatus 40 is an electrophotographic image-forming apparatus and includes a photoconductor 27, an exposure light source 28, a charging unit 30, a developing unit 31, a transfer unit 32, a transport roller 33, and a fusing unit 35. The irradiation of light 29 is performed from the exposure light source 28 to form an electrostatic latent image on the surface of the photoconductor 27. The exposure light source 28 includes the organic light-emitting device according to the present embodiment. The developing unit 31 contains, for example, a toner. The charging unit 30 charges the photoconductor 27. The transfer unit 32 transfers the developed image to a recording medium 34. The transport roller 33 transports the recording medium 34. The recording medium 34 is paper, for example. The fusing unit 35 fixes the image formed on the recording medium 34.

FIGS. 8B and 8C each illustrate the exposure light source 28 and are each a schematic view illustrating multiple light-emitting portions 36 arranged on a long substrate. Arrows 37 are parallel to the axis of the photoconductor and each represent the row direction in which the organic light-emitting devices are arranged. The row direction is the same as the direction of the axis on which the photoconductor 27 rotates. This direction can also be referred to as the long-axis direction of the photoconductor 27. FIG. 8B illustrates a configuration in which the light-emitting portions 36 are arranged in the long-axis direction of the photoconductor 27. FIG. 8C is different from FIG. 8B in that the light-emitting portions 36 are arranged alternately in the row direction in a first row and a second row. The first row and the second row are located at different positions in the column direction. In the first row, the multiple light-emitting portions 36 are spaced apart. The second row has the light-emitting portions 36 at positions corresponding to the positions between the light-emitting portions 36 in the first row. In other words, the multiple light-emitting portions 36 are also spaced apart in the column direction. The arrangement in FIG. 8C can be rephrased as, for example, a lattice arrangement, a staggered arrangement, or a checkered pattern.

As described above, the use of an apparatus including the organic light-emitting device according to the present embodiment enables a stable display with good image quality even for a long time.

### EXAMPLES

Examples will be described below. However, the present invention is not limited thereto.

### Example 1 (Synthesis of Exemplified Compound A1)

Exemplified compound A1 was synthesized by the following synthetic route using a synthesis method described in Patent Literature 1.

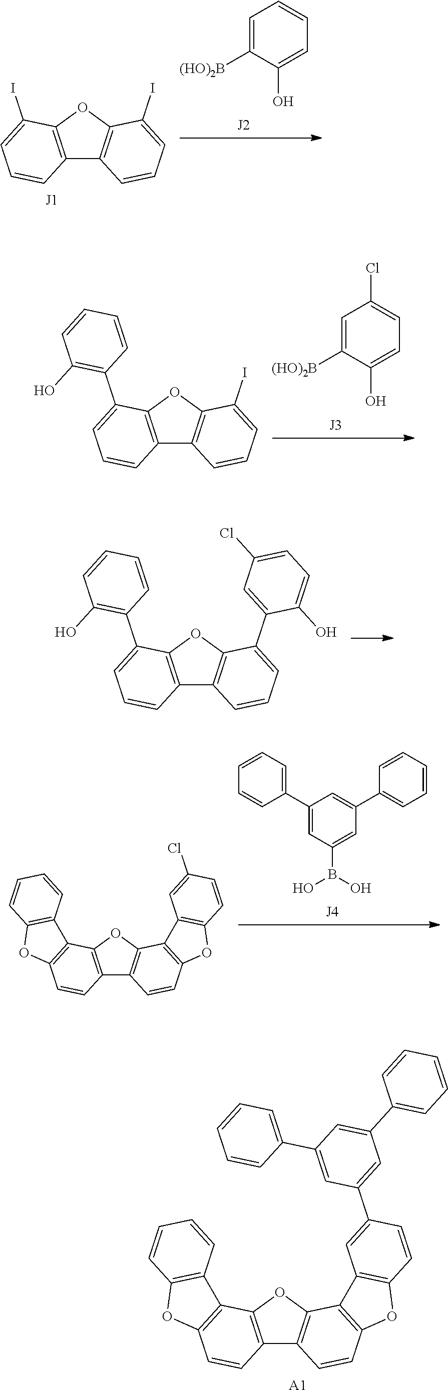

Exemplified compound A1 was subjected to mass spectrometry with MALDI-TOF-MS (Autoflex LRF, manufactured by Bruker).

### [MALDI-TOF-MS]

Measured value: m/z=577, calculated value: C₄₂H₂₄B₂N₄=577

### Examples 2 to 25 (Syntheses of Exemplified Compounds)

As presented in Tables 2 to 7, exemplified compounds of Examples 2 to 25 were synthesized as in Example 1, except that raw material J1 of Example 1 was changed to raw material 1, raw material J2 to raw material 2, raw material J3 to raw material 3, and raw material J4 to raw material 4. The resulting exemplified compounds were subjected to mass spectrometry as in Example 1, and the measured values of m/z are also presented.

TABLE 2

| | Exemplified | | | | | |
|---|---|---|---|---|---|---|
| Example | compound | Raw material 1 | Raw material 2 | Raw material 3 | Raw material 4 | m/z |
| 2 | A2 | 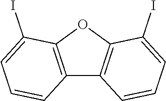 [SMILES: Ic1cccc2c1oc1c(I)cccc12] | 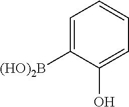 | 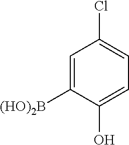 [SMILES: OB(O)c1cc(Cl)ccc1O] | 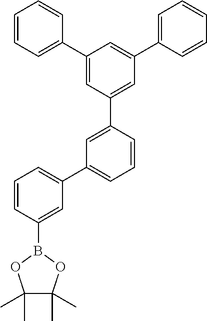 [SMILES: CC1(C)OB(c2cccc(-c3cccc(-c4cc(-c5ccccc5)cc(-c5ccccc5)c4)c3)c2)OC1(C)C] | 729 |
| 3 | A3 | 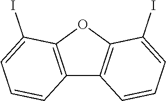 [SMILES: Ic1cccc2c1oc1c(I)cccc12] | 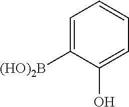 | 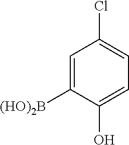 [SMILES: OB(O)c1cc(Cl)ccc1O] | 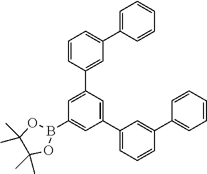 [SMILES: CC1(C)OB(c2cc(-c3cccc(-c4ccccc4)c3)cc(-c3cccc(-c4ccccc4)c3)c2)OC1(C)C] | 729 |
| 4 | A7 | 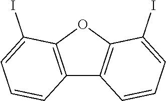 [SMILES: Ic1cccc2c1oc1c(I)cccc12] | 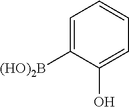 | 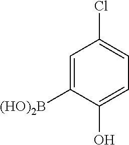 [SMILES: OB(O)c1cc(Cl)ccc1O] | 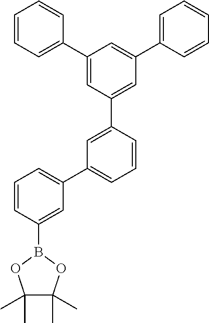 [SMILES: CC1(C)OB(c2cccc(-c3cccc(-c4cc(-c5ccccc5)cc(-c5ccccc5)c4)c3)c2)OC1(C)C] | 745 |
| 5 | A10 | 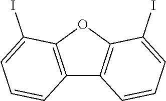 [SMILES: Ic1cccc2c1oc1c(I)cccc12] | 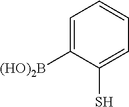 | 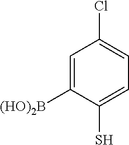 [SMILES: OB(O)c1cc(Cl)ccc1S] | 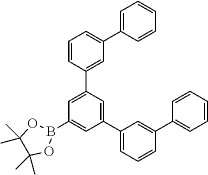 [SMILES: CC1(C)OB(c2cc(-c3cccc(-c4ccccc4)c3)cc(-c3cccc(-c4ccccc4)c3)c2)OC1(C)C] | 761 |

TABLE 3

| | Exemplified | | | | | |
|---|---|---|---|---|---|---|
| Example | compound | Raw material 1 | Raw material 2 | Raw material 3 | Raw material 4 | m/z |
| 6 | A12 | 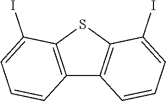 [SMILES: Ic1cccc2c1sc1c(I)cccc12] | 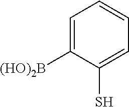 | 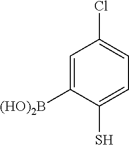 [SMILES: OB(O)c1cc(Cl)ccc1S] | 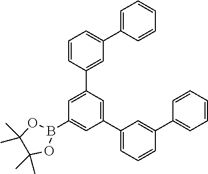 [SMILES: CC1(C)OB(c2cc(-c3cccc(-c4ccccc4)c3)cc(-c3cccc(-c4ccccc4)c3)c2)OC1(C)C] | 777 |
| 7 | A14 | 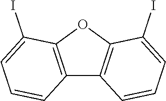 [SMILES: Ic1cccc2c1oc1c(I)cccc12] | 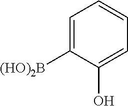 | 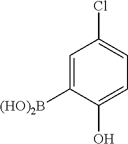 [SMILES: OB(O)c1cc(Cl)ccc1O] | 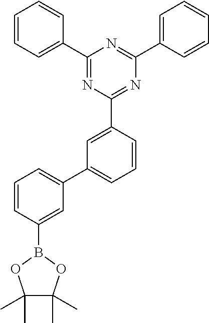 [SMILES: CC1(C)OB(c2cccc(-c3cccc(-c4nc(-c5ccccc5)nc(-c5ccccc5)n4)c3)c2)OC1(C)C] | 732 |
| 8 | A20 | 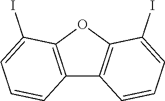 [SMILES: Ic1cccc2c1oc1c(I)cccc12] | 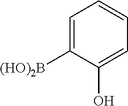 | 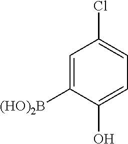 [SMILES: OB(O)c1cc(Cl)ccc1O] | 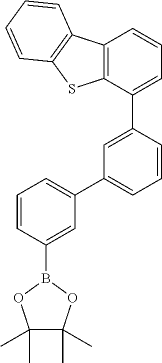 [SMILES: CC1(C)OB(c2cccc(-c3cccc(-c4cccc5c4sc4ccccc45)c3)c2)OC1(C)C] | 683 |
| 9 | A26 | 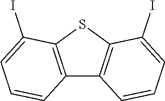 [SMILES: Ic1cccc2c1sc1c(I)cccc12] | 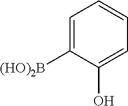 | 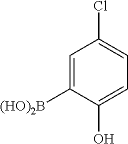 [SMILES: OB(O)c1cc(Cl)ccc1O] | 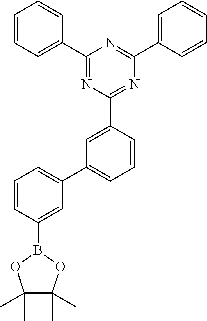 [SMILES: CC1(C)OB(c2cccc(-c3cccc(-c4nc(-c5ccccc5)nc(-c5ccccc5)n4)c3)c2)OC1(C)C] | 748 |

TABLE 4

| | Exemplified | | | | | |
|---|---|---|---|---|---|---|
| Example | compound | Raw material 1 | Raw material 2 | Raw material 3 | Raw material 4 | m/z |
| 10 | B1 | 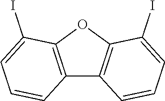 [SMILES: Ic1cccc2c1oc1c(I)cccc12] | 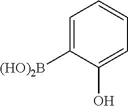 | 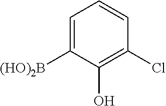 [SMILES: OB(O)c1cccc(Cl)c1O] | 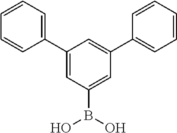 [SMILES: OB(O)c1cc(-c2ccccc2)cc(-c2ccccc2)c1] | 577 |
| 11 | B2 | 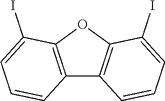 [SMILES: Ic1cccc2c1oc1c(I)cccc12] | 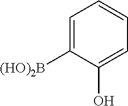 | 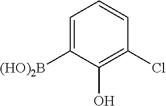 [SMILES: OB(O)c1cccc(Cl)c1O] | 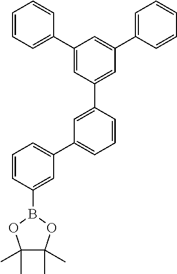 [SMILES: CC1(C)OB(c2cccc(-c3cccc(-c4cc(-c5ccccc5)cc(-c5ccccc5)c4)c3)c2)OC1(C)C] | 729 |
| 12 | B3 | 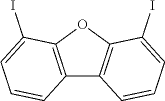 [SMILES: Ic1cccc2c1oc1c(I)cccc12] | 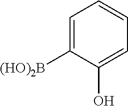 | 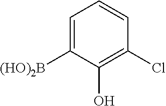 [SMILES: OB(O)c1cccc(Cl)c1O] | 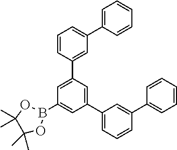 [SMILES: CC1(C)OB(c2cc(-c3cccc(-c4ccccc4)c3)cc(-c3cccc(-c4ccccc4)c3)c2)OC1(C)C] | 729 |
| 13 | B6 | 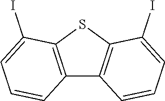 [SMILES: Ic1cccc2c1sc1c(I)cccc12] | 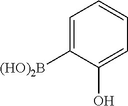 | 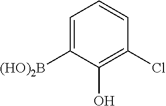 [SMILES: OB(O)c1cccc(Cl)c1O] | 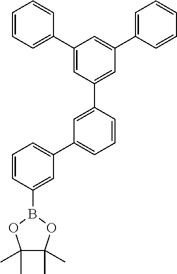 [SMILES: CC1(C)OB(c2cccc(-c3cccc(-c4cc(-c5ccccc5)cc(-c5ccccc5)c4)c3)c2)OC1(C)C] | 745 |

TABLE 5

| | Exemplified | | | | | |
|---|---|---|---|---|---|---|
| Example | compound | Raw material 1 | Raw material 2 | Raw material 3 | Raw material 4 | m/z |
| 14 | B9 | 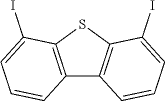 [SMILES: Ic1cccc2c1sc1c(I)cccc12] | 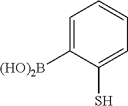 | 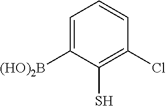 [SMILES: OB(O)c1cccc(Cl)c1S] | 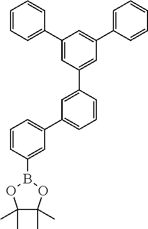 [SMILES: CC1(C)OB(c2cccc(-c3cccc(-c4cc(-c5ccccc5)cc(-c5ccccc5)c4)c3)c2)OC1(C)C] | 777 |
| 15 | B11 | 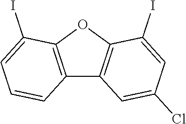 [SMILES: Clc1cc(I)c2oc3c(I)cccc3c2c1] | 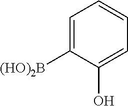 | 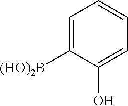 | 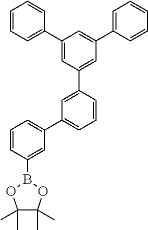 [SMILES: CC1(C)OB(c2cccc(-c3cccc(-c4cc(-c5ccccc5)cc(-c5ccccc5)c4)c3)c2)OC1(C)C] | 729 |
| 16 | B20 | 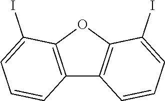 [SMILES: Ic1cccc2c1oc1c(I)cccc12] | 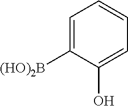 | 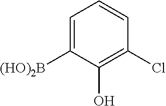 [SMILES: OB(O)c1cccc(Cl)c1O] | 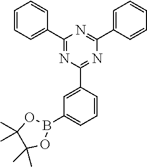 [SMILES: CC1(C)OB(c2cccc(-c3nc(-c4ccccc4)nc(-c4ccccc4)n3)c2)OC1(C)C] | 732 |
| 17 | B21 | 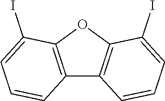 [SMILES: Ic1cccc2c1oc1c(I)cccc12] | 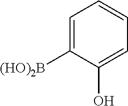 | 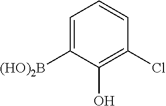 [SMILES: OB(O)c1cccc(Cl)c1O] | 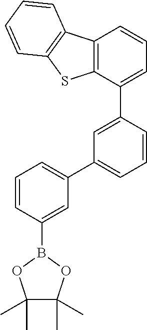 [SMILES: CC1(C)OB(c2cccc(-c3cccc(-c4cccc5c4sc4ccccc45)c3)c2)OC1(C)C] | 683 |

TABLE 6

| | Exemplified | | | | | |
|---|---|---|---|---|---|---|
| Example | compound | Raw material 1 | Raw material 2 | Raw material 3 | Raw material 4 | m/z |
| 18 | B24 | 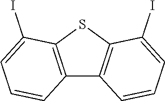 [SMILES: Ic1cccc2c1sc1c(I)cccc12] | 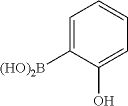 | 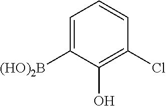 [SMILES: OB(O)c1cccc(Cl)c1O] | 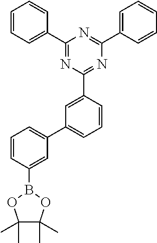 [SMILES: CC1(C)OB(c2cccc(-c3cccc(-c4nc(-c5ccccc5)nc(-c5ccccc5)n4)c3)c2)OC1(C)C] | 748 |
| 19 | B27 | 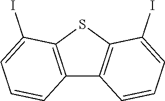 [SMILES: Ic1cccc2c1sc1c(I)cccc12] | 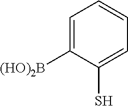 | 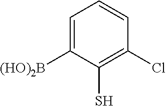 [SMILES: OB(O)c1cccc(Cl)c1S] | 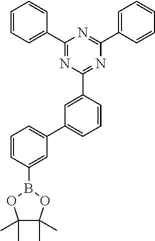 [SMILES: CC1(C)OB(c2cccc(-c3cccc(-c4nc(-c5ccccc5)nc(-c5ccccc5)n4)c3)c2)OC1(C)C] | 780 |
| 20 | B30 | 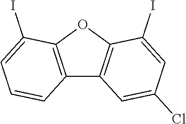 [SMILES: Clc1cc(I)c2oc3c(I)cccc3c2c1] | 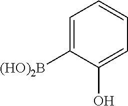 | 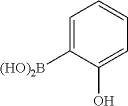 | 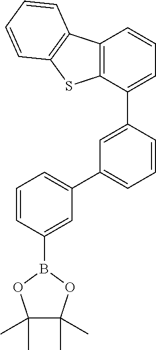 [SMILES: CC1(C)OB(c2cccc(-c3cccc(-c4cccc5c4sc4ccccc45)c3)c2)OC1(C)C] | 683 |

TABLE 7

| | Exemplified | | | | | |
|---|---|---|---|---|---|---|
| Example | compound | Raw material 1 | Raw material 2 | Raw material 3 | Raw material 4 | m/z |
| 21 | C1 | 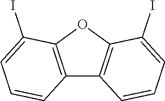 [SMILES: Ic1cccc2c1oc1c(I)cccc12] | 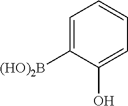 | 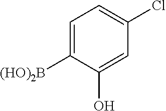 [SMILES: OB(O)c1ccc(Cl)cc1O] | 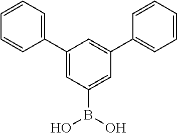 [SMILES: OB(O)c1cc(-c2ccccc2)cc(-c2ccccc2)c1] | 577 |
| 22 | C3 | 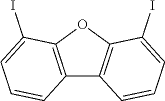 [SMILES: Ic1cccc2c1oc1c(I)cccc12] | 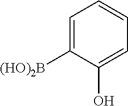 | 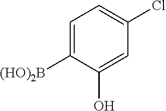 [SMILES: OB(O)c1ccc(Cl)cc1O] | 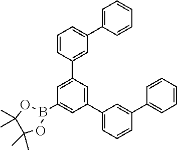 [SMILES: CC1(C)OB(c2cc(-c3cccc(-c4ccccc4)c3)cc(-c3cccc(-c4ccccc4)c3)c2)OC1(C)C] | 729 |
| 23 | C11 | 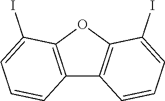 [SMILES: Ic1cccc2c1oc1c(I)cccc12] | 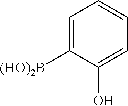 | 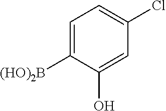 [SMILES: OB(O)c1ccc(Cl)cc1O] | 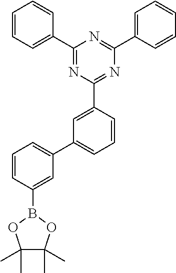 [SMILES: CC1(C)OB(c2cccc(-c3cccc(-c4nc(-c5ccccc5)nc(-c5ccccc5)n4)c3)c2)OC1(C)C] | 732 |
| 24 | D2 | 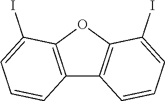 [SMILES: Ic1cccc2c1oc1c(I)cccc12] | 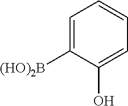 | 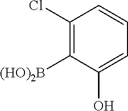 [SMILES: OB(O)c1c(O)cccc1Cl] | 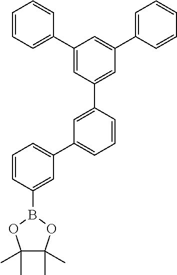 [SMILES: CC1(C)OB(c2cccc(-c3cccc(-c4cc(-c5ccccc5)cc(-c5ccccc5)c4)c3)c2)OC1(C)C] | 729 |
| 25 | D7 | 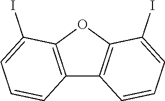 [SMILES: Ic1cccc2c1oc1c(I)cccc12] | 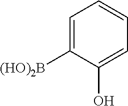 | 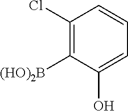 [SMILES: OB(O)c1c(O)cccc1Cl] | 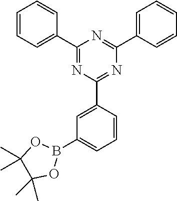 [SMILES: CC1(C)OB(c2cccc(-c3nc(-c4ccccc4)nc(-c4ccccc4)n3)c2)OC1(C)C] | 656 |

### Example 26

An organic light-emitting device having a bottom-emission structure was produced in which an anode, a hole injection layer, a hole transport layer, an electron-blocking layer, a light-emitting layer, a hole-blocking layer, an electron transport layer, an electron injection layer, and a cathode were sequentially formed on a substrate.

An ITO film was formed on a glass substrate and subjected to desired patterning to form an ITO electrode (anode). The ITO electrode had a thickness of 100 nm. The substrate on which the ITO electrode had been formed in this way was used as an ITO substrate in the following steps. Next, vacuum deposition was performed by resistance heating in a vacuum chamber at 1.33×10⁻⁴ Pa to successively form organic compound layers and an electrode layer presented in Table 8 on the ITO substrate. Here, the opposing electrode (metal electrode layer, cathode) had an electrode area of 3 mm².

TABLE 8

| | | | | Thick- |
|---|---|---|---|---|
| | | | | ness |
| | Material | | | (nm) |
| Cathode | Al | | | 100 |
| Electron injection layer (EIL) | LiF | | | 1 |
| Electron transport layer (ETL) | ET2 | | | 20 |
| Hole-blocking layer (HBL) | ET11 | | | 20 |
| Light-emitting layer (EML) | Host | A1 | Ratio by mass | 20 |
| | Guest | AA2 | A1:AA2 = | |
| | | | 90:10 | |

| | | |
|---|---|---|
| Electron-blocking layer (EBL) | HT19 | 15 |
| Hole transport layer (HTL) | HT3 | 30 |
| Hole injection layer (HIL) | HT16 | 5 |

The characteristics of the resulting device were measured and evaluated. The light-emitting device had a maximum external quantum efficiency (E.Q.E.) of 15%. The device was subjected to a continuous operation test at a current density of 100 mA/cm². The time when the percentage of luminance degradation reached 5% was measured. When the time when the percentage of luminance degradation of Comparative example 1 reached 5% was defined as 1.0, the percentage ratio of luminance degradation in this example was 1.3.

With regard to measurement instruments, in this example, the current-voltage characteristics were measured with a Hewlett-Packard 4140B microammeter, and the luminance was measured with a Topcon BM7.

### Examples 27 to 45 and Comparative Examples 1 to 3

Organic light-emitting devices were produced in the same manner as in Example 26, except that the compounds were changed to compounds given in Table 9 as appropriate. The characteristics of the resulting devices were measured and evaluated as in Example 26. Table 9 presents the measurement results. The host material used in Comparative Examples 1 and 2 is compound 1-a described in Patent Literature 1.

TABLE 9

| | | | | | | | | | Ratio of |
|---|---|---|---|---|---|---|---|---|---|
| | | | | | | | | | percentage of |
| | | | | EML | | | | E.Q.E | luminance |
| | HIL | HTL | EBL | Host | Guest | HBL | ETL | [%] | degradation |
| Example 27 | HT16 | HT3 | HT19 | A2 | AA26 | ET12 | ET15 | 15 | 1.3 |
| Example 28 | HT16 | HT2 | HT15 | A3 | AA27 | ET12 | ET2 | 15 | 1.3 |
| Example 29 | HT16 | HT2 | HT15 | A7 | AA30 | ET11 | ET2 | 15 | 1.3 |
| Example 30 | HT16 | HT3 | HT19 | A12 | CC17 | ET11 | ET2 | 15 | 1.3 |
| Example 31 | HT16 | HT3 | HT19 | A14 | GD11 | ET11 | ET2 | 15 | 1.4 |
| Example 32 | HT16 | HT3 | HT19 | A20 | HH1 | ET11 | ET15 | 15 | 1.4 |
| Example 33 | HT16 | HT3 | HT19 | A26 | BB24 | ET12 | ET2 | 15 | 1.4 |
| Example 34 | HT16 | HT2 | HT15 | B2 | BB25 | ET12 | ET15 | 14 | 1.4 |
| Example 35 | HT16 | HT3 | HT19 | B3 | GD11 | ET12 | ET15 | 14 | 1.4 |
| Example 36 | HT16 | HT2 | HT15 | B6 | DD5 | ET11 | ET2 | 14 | 1.4 |
| Example 37 | HT16 | HT3 | HT19 | B9 | DD31 | ET12 | ET15 | 14 | 1.4 |
| Example 38 | HT16 | HT2 | HT15 | B11 | DD27 | ET12 | ET2 | 14 | 1.4 |
| Example 39 | HT16 | HT2 | HT15 | B20 | EE1 | ET11 | ET2 | 14 | 1.5 |
| Example 40 | HT16 | HT3 | HT19 | B21 | EE2 | ET12 | ET15 | 14 | 1.5 |
| Example 41 | HT16 | HT3 | HT19 | B24 | FF29 | ET12 | ET15 | 14 | 1.5 |
| Example 42 | HT16 | HT3 | HT19 | C3 | HH21 | ET11 | ET15 | 13 | 1.3 |
| Example 43 | HT16 | HT3 | HT19 | C11 | FF1 | ET12 | ET15 | 13 | 1.3 |
| Example 44 | HT16 | HT3 | HT19 | D2 | GG4 | ET11 | ET15 | 13 | 1.2 |
| Example 45 | HT16 | HT3 | HT19 | D7 | HH27 | ET12 | ET2 | 13 | 1.2 |
| Comparative | HT16 | HT3 | HT19 | Comparative | Ir(ppy)3 | ET11 | ET2 | 8 | 1.0 |
| Example 1 | | | | compound 1-a | | | | | |
| Comparative | HT16 | HT3 | HT19 | Comparative | AA2 | ET11 | ET2 | 9 | 1.0 |
| Example 2 | | | | compound 1-a | | | | | |
| Comparative | HT16 | HT3 | HT19 | B20 | Ir(ppy)3 | ET11 | ET2 | 9 | 1.1 |
| Example 3 | | | | | | | | | |

Table 9 indicates that the maximum external quantum efficiencies (E.Q.E.) in Comparative Examples 1 to 3 were 8, 9, and 9, respectively, while the light-emitting devices according to Examples had higher luminous efficiencies. This is attributed to the fact that each of the host material and the guest material has a highly planar skeleton.

In addition, the light-emitting devices according to Examples had longer lifetimes. This is attributed to the fact that each of the host material and the guest material has a highly planar skeleton and that the host material has no SP³ carbon atoms or amino groups and thus has high bond stability.

Furthermore, it was possible to provide a light-emitting device with particularly high efficiency and a long life by selecting a phosphorescent material having a ligand containing a tricyclic or higher cyclic fused ring, which is suitable for combination with the organic compound of the present embodiment.

As described above, the use of the organic compound according to the present embodiment can provide a device having high efficiency and excellent durability characteristics.

### Example 46

An organic light-emitting device was produced in the same manner as in Example 26, except that organic compound layers and an electrode layer given in Table 10 were continuously formed.

TABLE 10

| | | | | Thickness |
|---|---|---|---|---|
| | Material | | | (nm) |
| Cathode | Al | | | 100 |
| Electron injection layer (EIL) | LiF | | | 1 |
| Electron transport layer (ETL) | ET2 | | | 20 |
| Hole-blocking layer (HBL) | ET11 | | | 20 |
| Light-emitting layer (EML) | Host | A1 | Ratio by mass | 20 |
| | Guest | AA2 | A1:AA2:EM30 = | |
| | Assist | EM30 | 60:10:30 | |

| | | |
|---|---|---|
| Electron-blocking layer (EBL) | HT19 | 15 |
| Hole transport layer (HTL) | HT3 | 30 |
| Hole injection layer (HIL) | HT16 | 5 |

The characteristics of the resulting device were measured and evaluated. The emission color of the light-emitting device was green, and the maximum external quantum efficiency (E.Q.E.) was 19%.

### Examples 47 to 65

Organic light-emitting devices were produced in the same manner as in Example 46, except that the compounds were changed to compounds given in Table 11 as appropriate. The characteristics of the resulting devices were measured and evaluated as in Example 46. Table 11 presents the measurement results.

TABLE 11

| | | | | EML | | | | | E.Q.E |
|---|---|---|---|---|---|---|---|---|---|
| | HIL | HTL | EBL | Host | Guest | Assist | HBL | ETL | [%] |
| Example 47 | HT16 | HT3 | HT19 | A2 | BB24 | EM29 | ET26 | ET3 | 19 |
| Example 48 | HT16 | HT2 | HT15 | A3 | BB21 | EM35 | ET13 | ET2 | 19 |
| Example 49 | HT16 | HT2 | HT15 | A7 | CC17 | EM37 | ET13 | ET2 | 19 |
| Example 50 | HT16 | HT3 | HT19 | A12 | DD5 | EM13 | ET16 | ET15 | 19 |
| Example 51 | HT16 | HT3 | HT19 | A14 | DD31 | EM30 | ET16 | ET15 | 19 |
| Example 52 | HT16 | HT3 | HT19 | A20 | DD27 | EM28 | ET17 | ET15 | 19 |
| Example 53 | HT16 | HT3 | HT19 | A26 | EE1 | EM39 | ET13 | ET2 | 19 |
| Example 54 | HT16 | HT2 | HT15 | B2 | EE2 | GD10 | ET15 | ET3 | 18 |
| Example 55 | HT16 | HT3 | HT19 | B3 | FF2 | ET15 | ET15 | ET15 | 18 |
| Example 56 | HT16 | HT2 | HT15 | B6 | FF23 | ET16 | ET2 | ET2 | 18 |
| Example 57 | HT16 | HT3 | HT19 | B9 | FF1 | EM16 | ET26 | ET3 | 18 |
| Example 58 | HT16 | HT2 | HT15 | B11 | GG3 | EM16 | ET13 | ET2 | 18 |
| Example 59 | HT16 | HT2 | HT15 | B20 | HH25 | EM34 | ET13 | ET2 | 18 |
| Example 60 | HT16 | HT3 | HT19 | B21 | GC21 | EM35 | ET16 | ET15 | 18 |
| Example 61 | HT16 | HT3 | HT19 | B24 | DD46 | EM37 | ET16 | ET15 | 18 |
| Example 62 | HT16 | HT2 | HT15 | C3 | DD35 | EM13 | ET15 | ET3 | 17 |
| Example 63 | HT16 | HT3 | HT19 | C11 | DD31 | EM30 | ET15 | ET15 | 17 |
| Example 64 | HT16 | HT2 | HT15 | D2 | DD9 | EM28 | ET2 | ET2 | 17 |
| Example 65 | HT16 | HT3 | HT19 | D7 | DD8 | EM28 | ET26 | ET3 | 17 |

According to the present invention, the use of a light-emitting layer containing an organic compound having a highly planar fused-ring chalcogenophene skeleton and a highly planar organometallic complex provides an organic light-emitting device having excellent luminous efficiency and durability characteristics.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. An organic light-emitting device, comprising:
a pair of electrodes, and a light-emitting layer disposed between the pair of electrodes,
wherein the light-emitting layer contains at least a guest molecule and a host molecule,
the host molecule is an organic compound represented by the following general formula [1], and
the guest molecule is an organometallic complex represented by the following general formula [2]: 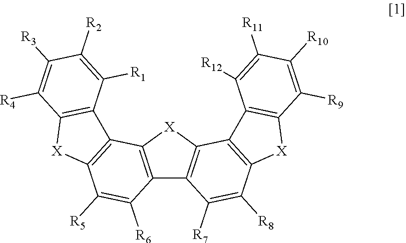
M(L)m(L′)n(L″)p [2]
where in formula [1], R₁ to R₁₂ are each independently selected from the group consisting of a hydrogen atom, a deuterium atom, a substituted or unsubstituted aryl group, and a substituted or unsubstituted heterocyclic group, provided that at least one of R₁ to R₁₂ is selected from the group consisting of a substituted or unsubstituted aryl group and a substituted or unsubstituted heterocyclic group,
each X is selected from the group consisting of an oxygen atom, a sulfur atom, a selenium atom, and a tellurium atom,
in formula [2], M is iridium or platinum,
L, L′, and L″ are each a different bidentate ligand,
m is an integer of 1 or more and 3 or less, and each of n and p is an integer of 0 or more and 2 or less, provided that m+n+p=3,
a partial structure M(L)m is represented by the following general formula [2-1]: 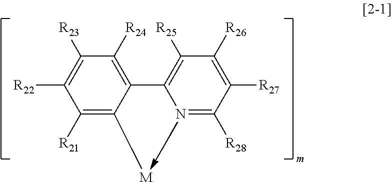
where in formula [2-1], R₂₁ to R₂₈ are each independently selected from the group consisting of a hydrogen atom, a deuterium atom, a halogen atom, a substituted or unsubstituted alkyl group, a substituted or unsubstituted alkoxy group, a substituted or unsubstituted silyl group, a substituted or unsubstituted aryl group, a substituted or unsubstituted heterocyclic group, a substituted or unsubstituted amino group, a substituted or unsubstituted aryloxy group, a substituted or unsubstituted heteroaryloxy group, and a cyano group, provided that at least one of R₂₁ to R₂₈ is selected from the group consisting of a substituted or unsubstituted aryl group and a substituted or unsubstituted heterocyclic group, adjacent groups of R₂₁ to R₂₈ are optionally taken together to form a ring,
a partial structure M (L′)n is represented by the following general formula [2-2]: 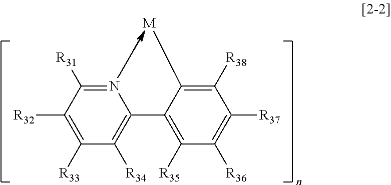
where in formula [2-2], R₃₁ to R₃₈ are each independently selected from the group consisting of a hydrogen atom, a deuterium atom, a halogen atom, a substituted or unsubstituted alkyl group, a substituted or unsubstituted alkoxy group, a substituted or unsubstituted silyl group, a substituted or unsubstituted aryl group, a substituted or unsubstituted heterocyclic group, a substituted or unsubstituted amino group, a substituted or unsubstituted aryloxy group, a substituted or unsubstituted heteroaryloxy group, and a cyano group, adjacent groups of R₃₁ to R₃₈ are optionally taken together to form a ring, and
a partial structure M(L″)p is represented by the following general formula [2-3]: 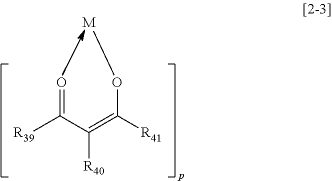
where in formula [2-3], R₃₉ to R₄₁ are each independently selected from the group consisting of a hydrogen atom, a deuterium atom, a halogen atom, a substituted or unsubstituted alkyl group, a substituted or unsubstituted alkoxy group, a substituted or unsubstituted silyl group, a substituted or unsubstituted aryl group, a substituted or unsubstituted heterocyclic group, a substituted or unsubstituted amino group, a substituted or unsubstituted aryloxy group, a substituted or unsubstituted heteroaryloxy group, and a cyano group.

2. The organic light-emitting device according to claim 1, wherein the host molecule is an organic compound represented by the following general formula [3]:

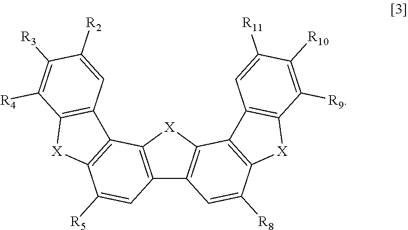

3. The organic light-emitting device according to claim 1, wherein one or two of R₁ to R₁₂ are selected from the group consisting of a substituted or unsubstituted aryl group and a substituted or unsubstituted heterocyclic group.

4. The organic light-emitting device according to claim 1, wherein at least one of R₁ to R₁₂ is selected from the group consisting of a substituted or unsubstituted phenyl group and a substituted or unsubstituted triazinyl group.

5. The organic light-emitting device according to claim 1, wherein M is iridium.

6. The organic light-emitting device according to claim 1, wherein the partial structure M(L)m has a tricyclic or higher cyclic fused ring.

7. The organic light-emitting device according to claim 6, wherein the tricyclic or higher cyclic fused ring is one of a phenanthrene ring, a triphenylene ring, a benzofluorene ring, a dibenzofuran ring, a dibenzothiophene ring, a benzoaphthofuran ring, a benzoaphthothiophene ring, a benzoisoquinoline ring, and a naphthoisoquinoline ring.

8. The organic light-emitting device according to claim 1, wherein the light-emitting layer further contains a third component.

9. The organic light-emitting device according to claim 8, wherein the third component has at least a carbazole skeleton.

10. The organic light-emitting device according to claim 8, wherein the third component has a skeleton containing at least an azine ring.

11. The organic light-emitting device according to claim 8, wherein the third component has a skeleton containing at least a xanthone.

12. The organic light-emitting device according to claim 1, further comprising another light-emitting layer stacked on the light-emitting layer, wherein the other light-emitting layer emits light of a color different from a color of light emitted from the light-emitting layer.

13. The organic light-emitting device according to claim 12, wherein the organic light-emitting device emits white light.

14. A display apparatus, comprising multiple pixels, at least one of the multiple pixels including the organic light-emitting device according to claim 1 and a transistor coupled to the organic light-emitting device.

15. A photoelectric conversion apparatus, comprising an optical unit including multiple lenses, an image pickup device configured to receive light passing through the optical unit, and a display unit configured to display an image captured by the image pickup device,
wherein the display unit includes the organic light-emitting device according to claim 1.

16. An electronic apparatus, comprising a display unit including the organic light-emitting device according to claim 1, a housing provided with the display unit, and a communication unit disposed in the housing and configured to communicate with an outside.

17. A lighting apparatus, comprising a light source including the organic light-emitting device according to claim 1, and a light diffusion unit or an optical filter configured to transmit light emitted from the light source.

18. A moving object, comprising a lighting unit including the organic light-emitting device according to claim 1, and a body provided with the lighting unit.

19. An exposure light source for an electrophotographic image-forming apparatus, comprising the organic light-emitting device according to claim 1.
